(19) United States
(12) Patent Application Publication
(10) Pub. No.: US 2022/0285646 A1
(43) Pub. Date: Sep. 8, 2022

(54) LIGHT EMITTING ELEMENT AND LIGHT EMITTING DEVICE

(71) Applicant: SHARP KABUSHIKI KAISHA, Sakai City, Osaka (JP)

(72) Inventor: KENJI KIMOTO, Sakai City, Osaka (JP)

(21) Appl. No.: 17/634,712

(22) PCT Filed: Aug. 13, 2019
(86) PCT No.: PCT/JP2019/031805

§ 371 Date: Feb. 11, 2022

(51) Int. Cl. H01L 51/50

(52) U.S. Cl. CPC H01L 51/5088; H01L 51/5056; H01L 51/5004; H01L 51/5072; H01L 27/3246

(57) ABSTRACT

A light-emitting element includes: a first electrode which is an anode, a hole transport layer, a light-emitting layer, an electron transport layer, and a second electrode which is a cathode in this order; and an oxide layer which is a first oxide layer and an oxide layer which is a second oxide layer disposed in this order from the first electrode side between the first electrode and the hole transport layer or between the electron transport layer and the second electrode, wherein a density of oxygen atoms in the second oxide layer is different from a density of oxygen atoms in the first oxide layer.

### TECHNICAL FIELD

The present disclosure relates to a light-emitting element and a light-emitting device, such as a display device or an illumination device, that includes the light-emitting element.

### BACKGROUND ART

In recent years, various display devices have been developed. Particularly, a display device including an Organic Light Emitting Diode (OLED) and a display device including an inorganic light-emitting diode or a Quantum dot Light Emitting Diode (QLED) have drawn a great deal of attention because the devices are capable of achieving lower power consumption, smaller thickness, higher picture quality, and the like.

However, in a light-emitting element, such as an OLED, QLED, and the like, for reasons described below, there is a problem in that the luminous efficiency is poor because the injection of carriers (holes and/or electrons) to the light-emitting layer does not easily occur.

FIG. 29 is an energy band diagram for describing the reason as to why, in a conventional light-emitting element 101, such as an OLED, QLED, and like, the injection of carriers (holes and/or electrons) to a light-emitting layer 103 does not easily occur.

As illustrated in FIG. 29, the light-emitting element 101 includes a first electrode (hole injection layer: anode (anode electrode)) and a second electrode (electron injection layer: cathode (cathode electrode)). A hole transport layer 102, a light-emitting layer 103, and an electron transport layer 104 are layered in this order from the first electrode side between the first electrode and the second electrode.

In the light-emitting element 101, the height of a hole injection barrier Eh1 from the first electrode to the hole transport layer 102 is the energy difference between the Fermi level of the first electrode and the upper end of the valence band (HTL valence band) of the hole transport layer 102, and the height of a hole injection barrier Eh2 from the hole transport layer 102 to the light-emitting layer 103 is the energy difference between the upper end of the valence band (HTL valence band) of the hole transport layer 102 and the upper end of the valence band of the light-emitting layer 103.

Furthermore, in the light-emitting element 101, a height of the electron injection barrier Ee1 from the second electrode to the electron transport layer 104 is an energy difference between the upper end of the valence band (ETL valence band) of the electron transport layer 104 and the Fermi level of the second electrode, and the height of an electron injection barrier Ee2 from the electron transport layer 104 to the light-emitting layer 103 is the energy difference between the lower end of the conduction band of the light-emitting layer 103 and the lower end of the conduction band (ETL conduction band) of the electron transport layer 104.

However, there are only a small number of materials with long-term reliability that can be used as the light-emitting material for an OLED or the light-emitting material for a QLED forming the light-emitting layer 103, the material for the hole transport layer 102, and the electron transport layer 104. In addition, the material of the first electrode and the material of the second electrode are generally selected taking into consideration light extraction from the light-emitting element 101, with one of the materials being a light-transmissive material, and the other being a light-reflective material. Furthermore, the material of the first electrode and the material of the second electrode must be selected taking into consideration reactivity, band alignment, and the like with the hole transport layer 102 and the electron transport layer 104. Thus, in the case of the hole transport layer 102, the electron transport layer 104, the first electrode, the second electrode, and the light-emitting layer 103, the choice of the material is limited.

When the material of the hole transport layer 102, the material of the electron transport layer 104, the material of the first electrode, the material of the second electrode, and the material of the light-emitting layer 103 are selected from among the small number of materials, because at least one of the height of the hole injection barrier Eh1 or the height of the electron injection barrier Ee1 increases, it becomes difficult to efficiently inject holes from the first electrode to the hole transport layer 102 and/or inject electrons from the second electrode to the electron transport layer 104.

As described in PTL 1, the band level of a light-emitting layer can be adjusted by forming a light-emitting layer having an organic ligand distribution in which the surface contacting the hole transport layer and the surface contacting the electron transport layer are different from each other. Specifically, it is described that by adjusting the band level of the light-emitting layer so that the energy difference between the valence band level of the light-emitting layer and the valence band level of the hole transport layer can be reduced, a light-emitting element having a low turn-on voltage and a low drive voltage and superior brightness and luminous efficiency can be achieved.

### CITATION LIST

### Patent Literature

PTL 1: JP 2010-114079 A (published on May 20, 2010)

### SUMMARY OF INVENTION

### Technical Problem

However, as described above, in PTL 1, the band level of the light-emitting layer is adjusted, and this cannot be applied to adjusting the height of the hole injection barrier Eh1 between the first electrode and the hole injection layer 102. Similarly, the method for adjusting the band level described in PTL 1 cannot be applied to adjusting the height of the electron injection barrier Ee1 between the second electrode and the electron transport layer 104. Thus, the amount of hole injection and the amount of electron injection to the light-emitting layer 103 cannot be effectively controlled.

In addition, the light-emitting element of PTL 1 has a small difference in ionization potential between the light-emitting layer with no band level adjustment and the light-emitting layer with an adjusted band level. Thus, even if the method described in PTL 1 can be applied to adjusting the height of the hole injection barrier Eh1 and to adjusting the height of the electron injection barrier Ee1 a sufficient effect cannot be obtained. That is, in the method of PTL 1, effective band level adjustment cannot be achieved.

Thus, there is still a problem in that the luminous efficiency is poor for a light-emitting element because the hole injection amount and the electron injection amount to the light-emitting layer 103 cannot be effectively controlled.

An aspect of the present disclosure has been made in view of the above-mentioned issue, and an object of the present disclosure is to provide a light-emitting element and a light-emitting device capable of achieving high luminous efficiency.

### Solution to Problem

In order to solve the issue described above, a light-emitting element according to an aspect of the present disclosure includes: an anode, a hole transport layer, a light-emitting layer, an electron transport layer, and a cathode in this order; and a first oxide layer and a second oxide layer that is in contact with the first oxide layer disposed in this order from a side closer to the anode between the anode and the hole transport layer or between the electron transport layer and the cathode, wherein a density of oxygen atoms in the second oxide layer is different from a density of oxygen atoms in the first oxide layer.

In order to solve the problem described above, a light-emitting device according to an aspect of the present disclosure includes the light-emitting element according to an aspect of the present disclosure.

### Advantageous Effects of Invention

According to an aspect of the present disclosure, a light-emitting element and a light-emitting device capable of achieving high luminous efficiency can be provided.

### BRIEF DESCRIPTION OF DRAWINGS

FIG. 1 is a cross-sectional view illustrating a schematic configuration of a display device including a light-emitting element according to a first embodiment.

FIG. 2 is a cross-sectional view schematically illustrating a schematic configuration of the light-emitting element according to the first embodiment.

(a) of FIG. 3 is an energy band diagram for describing a hole injection barrier between an anode and a hole transport layer in a light-emitting element according to a comparative example. (b) of FIG. 3 is an energy band diagram for describing a hole injection barrier between an anode and a hole transport layer in the light-emitting element of the first embodiment.

(a) of FIG. 4 is a diagram illustrating the mechanism by which oxygen atoms move at the interface between a first oxide layer and a second oxide layer in the light-emitting element according to the first embodiment. (b) of FIG. 4 is a diagram illustrating a state in which an electric dipole is formed by movement of oxygen atoms at the interface between the first oxide layer and the second oxide layer in the light-emitting element according to the first embodiment.

FIG. 5 is a diagram listing the oxygen atom density of inorganic oxides which are examples of an oxide for forming the first oxide layer and the second oxide layer in the light-emitting element according to the first embodiment.

FIG. 6 is a diagram listing examples of combinations of oxides forming the first oxide layer and oxides forming the second oxide layer in the light-emitting element according to the first embodiment.

FIG. 7 is an energy band diagram for describing a hole injection barrier in the light-emitting element according a first modified example of the first embodiment.

FIG. 8 is a cross-sectional view schematically illustrating a schematic configuration of the light-emitting element of a second modified example of the first embodiment.

FIG. 9 is a cross-sectional view schematically illustrating a schematic configuration of the light-emitting element of a third modified example of the first embodiment.

FIG. 10 is an energy band diagram for describing a hole injection barrier between an anode and a hole transport layer in a light-emitting element according to a second embodiment.

FIG. 11 is a diagram listing the oxygen atom density of inorganic oxides which are examples of an oxide for forming the hole transport layer in the light-emitting element according to the second embodiment.

FIG. 12 is a diagram listing examples of combinations of oxides forming the hole transport layer and oxides forming the second oxide layer in the light-emitting element according to the second embodiment.

FIG. 13 is a cross-sectional view schematically illustrating a schematic configuration of a light-emitting element according to a third embodiment.

(a) of FIG. 14 is an energy band diagram for describing an electron injection barrier in a light-emitting element according to a comparative example. (b) of FIG. 14 is an energy band diagram for describing an electron injection barrier in the light-emitting element of the third embodiment.

FIG. 15 is a diagram listing examples of combinations of oxides forming the first oxide layer and oxides forming the second oxide layer in the light-emitting element according to the third embodiment.

FIG. 16 is an energy band diagram for describing an electron injection barrier between a cathode and an electron transport layer in a light-emitting element according to a fourth embodiment.

FIG. 17 is a diagram listing the oxygen atom density of inorganic oxides which are examples of an oxide for forming the electron transport layer in the light-emitting element according to the fourth embodiment.

FIG. 18 is a diagram listing examples of combinations of oxides forming the electron transport layer and oxides forming the first oxide layer in the light-emitting element according to the fourth embodiment.

FIG. 19 is a cross-sectional view schematically illustrating an example of a schematic configuration of a light-emitting element according to a fifth embodiment.

FIG. 20 is an energy band diagram for describing a hole injection barrier between an anode and a hole transport layer and a hole injection barrier between the hole transport layer and a light-emitting layer in a light-emitting element according to a comparative example.

FIG. 21 is an energy band diagram for describing a hole injection barrier between an anode and a hole transport layer and a hole injection barrier between the hole transport layer and a light-emitting layer in the light-emitting element according to the fifth embodiment.

FIG. 22 is an energy band diagram for describing a hole injection barrier between an anode and a hole transport layer and a hole injection barrier between the hole transport layer and a light-emitting layer in a light-emitting element according to a sixth embodiment.

FIG. 23 is a cross-sectional view schematically illustrating an example of a schematic configuration of a light-emitting element according to a seventh embodiment.

FIG. 24 is an energy band diagram for describing an electron injection barrier between a cathode and an electron transport layer and an electron injection barrier between the electron transport layer and a light-emitting layer in a light-emitting element according to a comparative example.

FIG. 25 is an energy band diagram for describing an electron injection barrier between a cathode and an electron transport layer and an electron injection barrier between the electron transport layer and a light-emitting layer in the light-emitting element according to the seventh embodiment.

FIG. 26 is an energy band diagram for describing an electron injection barrier between a cathode and an electron transport layer and an electron injection barrier between the electron transport layer and a light-emitting layer in a light-emitting element according to an eighth embodiment.

FIG. 27 is a cross-sectional view schematically illustrating an example of a schematic configuration of a light-emitting element according to a ninth embodiment.

FIG. 28 is a cross-sectional view schematically illustrating an example of a schematic configuration of another light-emitting element according to the ninth embodiment.

FIG. 29 is an energy band diagram for describing the reason as to why, in a conventional light-emitting element, the injection of carriers (holes and/or electrons) to a light-emitting layer does not easily occur.

### DESCRIPTION OF EMBODIMENTS

Hereinafter, an embodiment of the present disclosure will be described in detail. Note that members having the same functions as those of members described earlier in each embodiment below will be denoted by the same reference numerals and signs, and the description thereof will not be repeated. In the second embodiment and those following, differences from the embodiment described first will be described. Note that it should be obvious that even in a case where not specified, in the second embodiment and those following, the same modifications as those of the embodiment described first may also be applied.

### First Embodiment

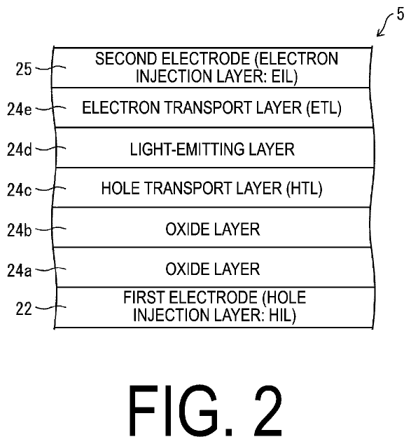

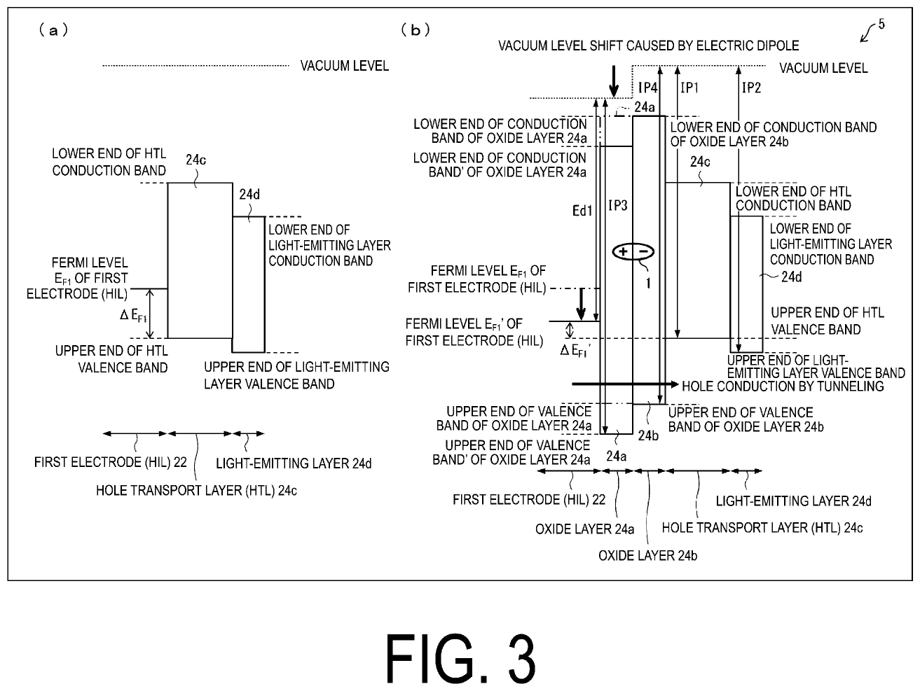

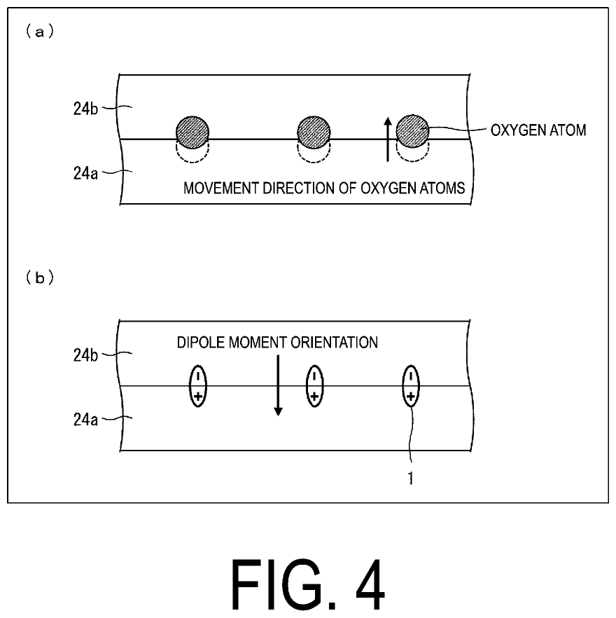

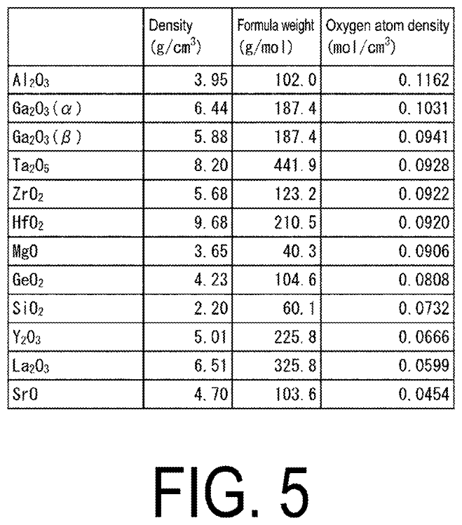

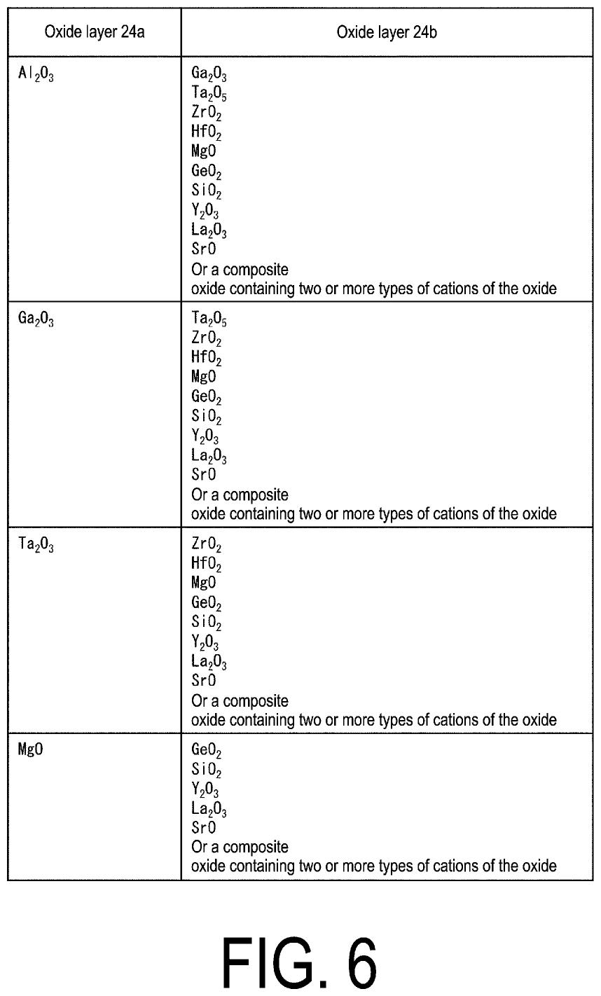

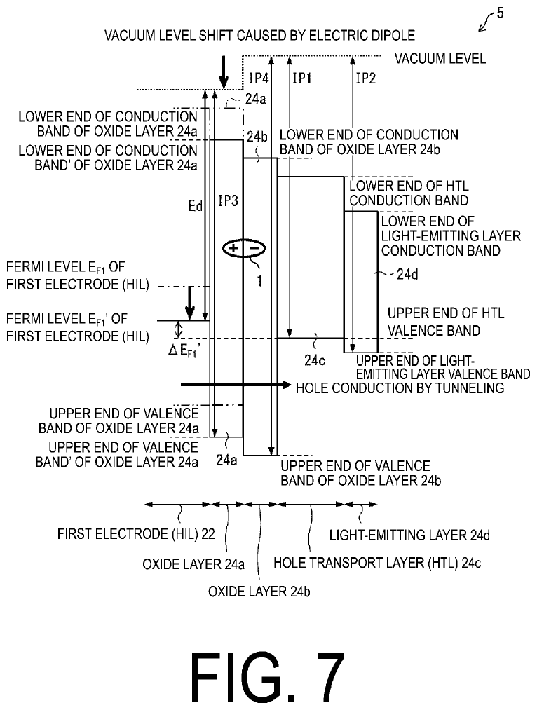

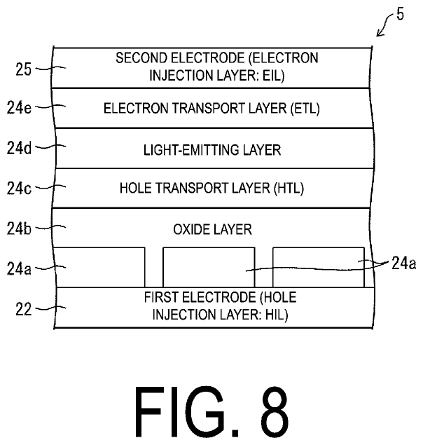

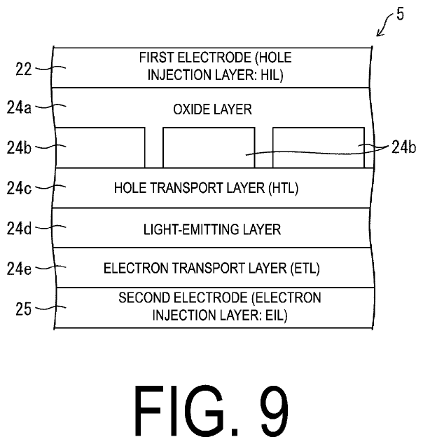

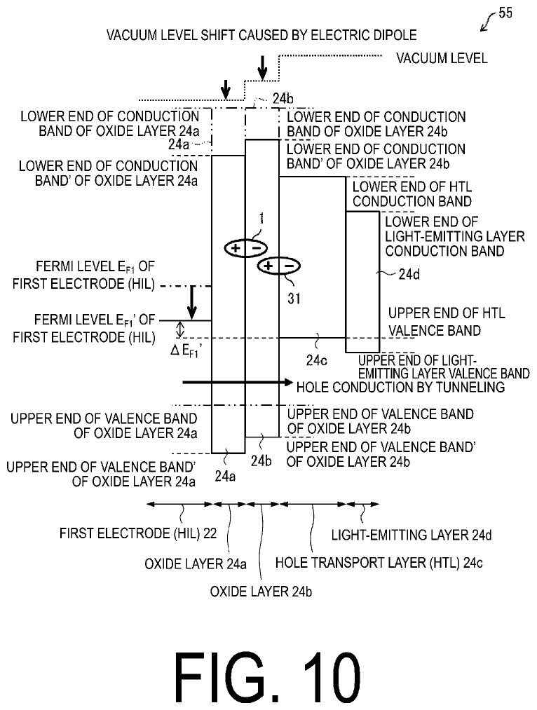

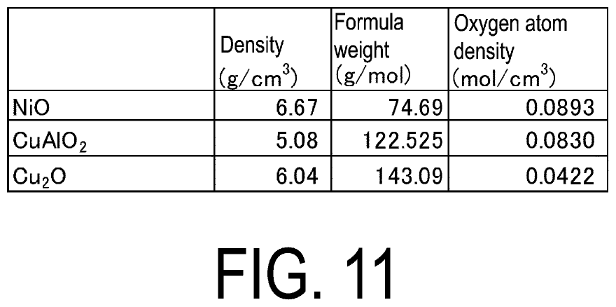

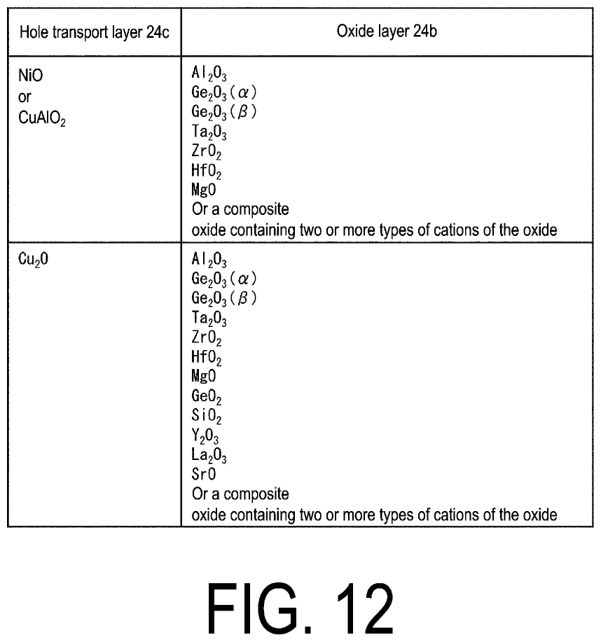

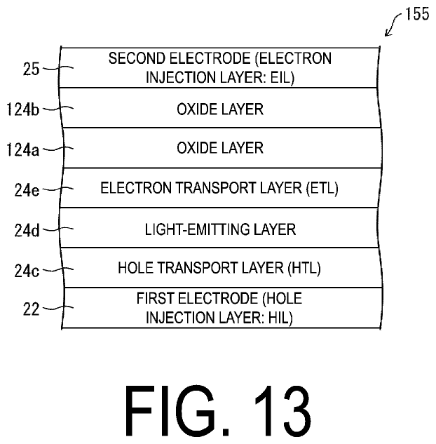

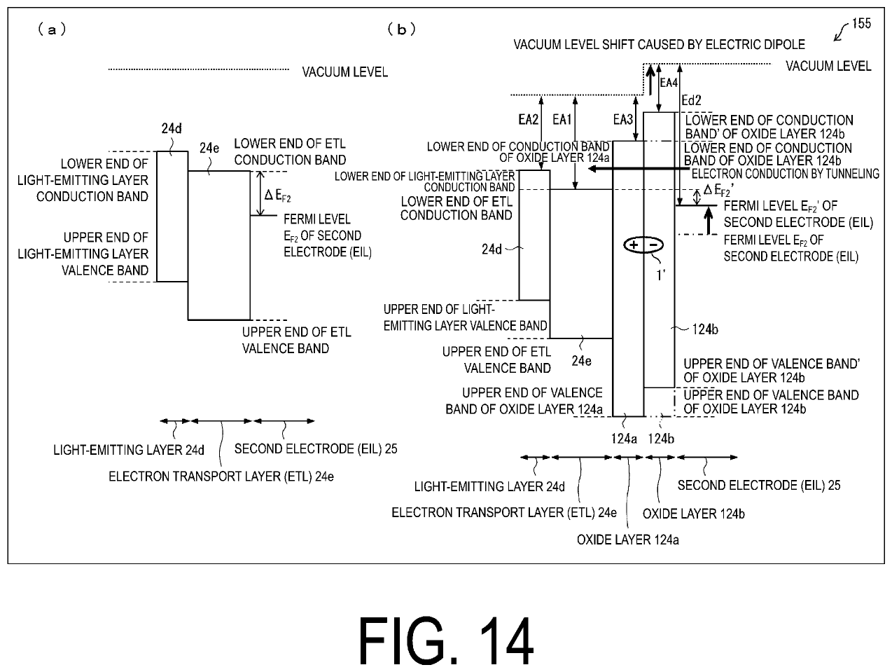

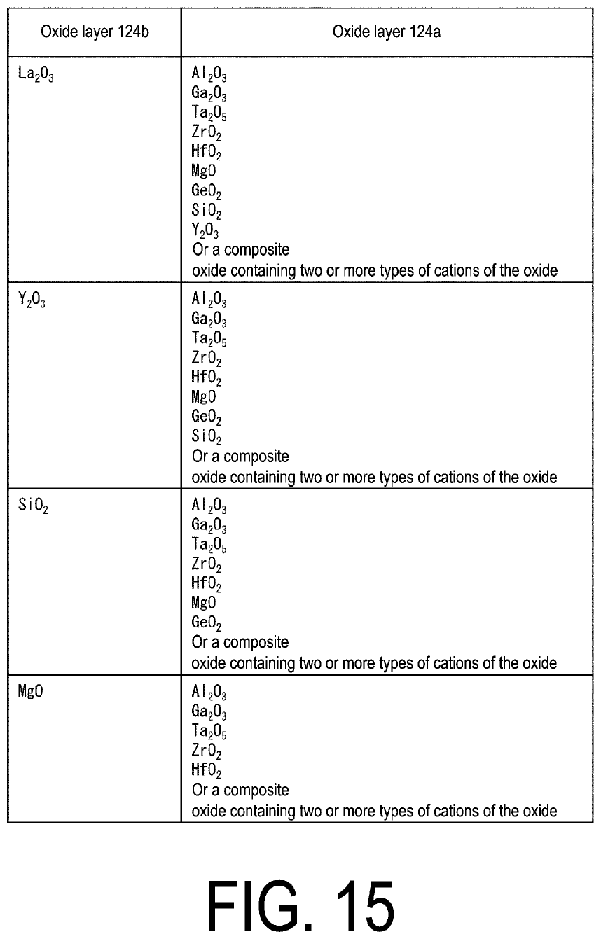

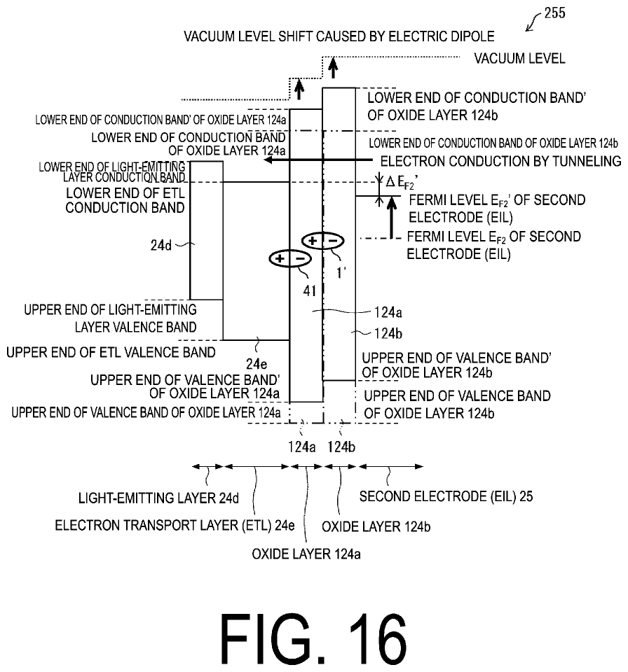

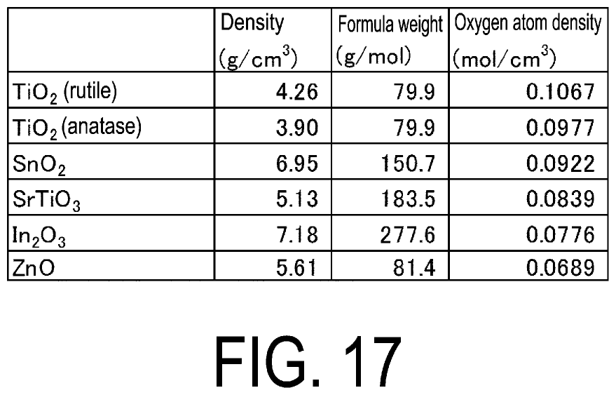

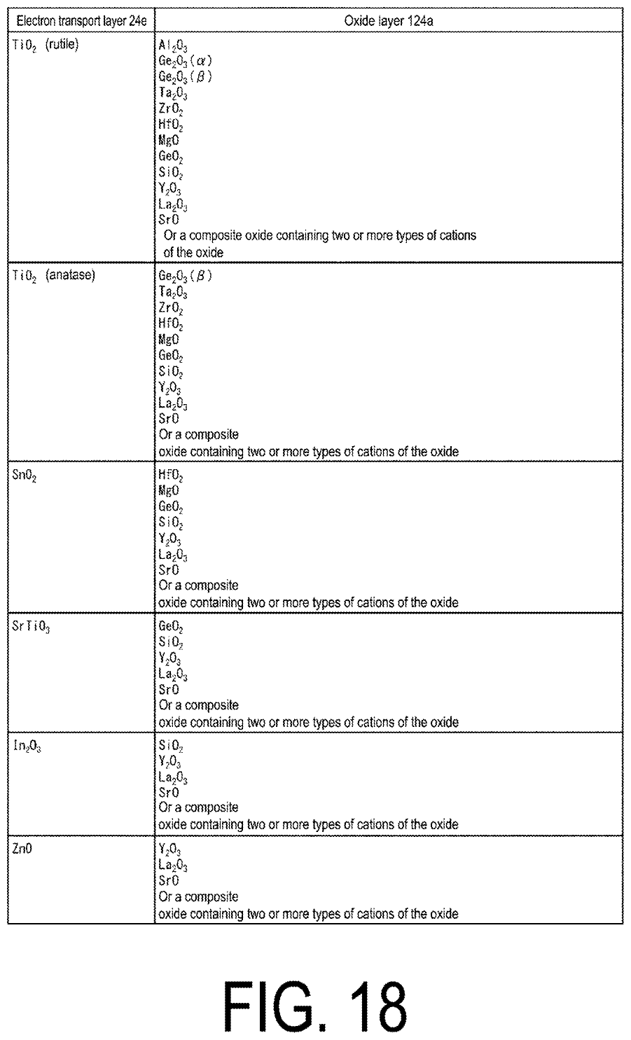

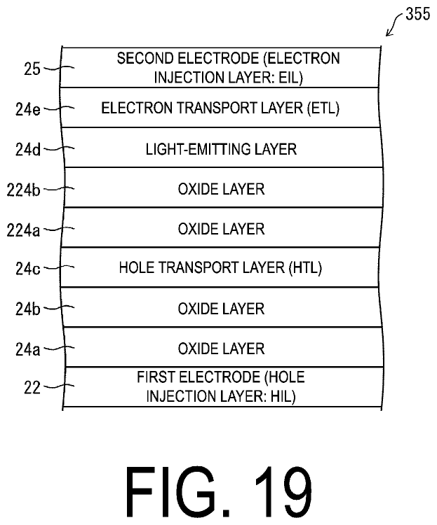

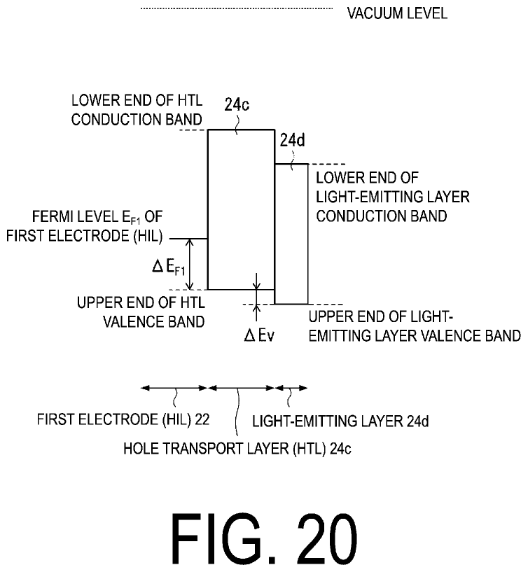

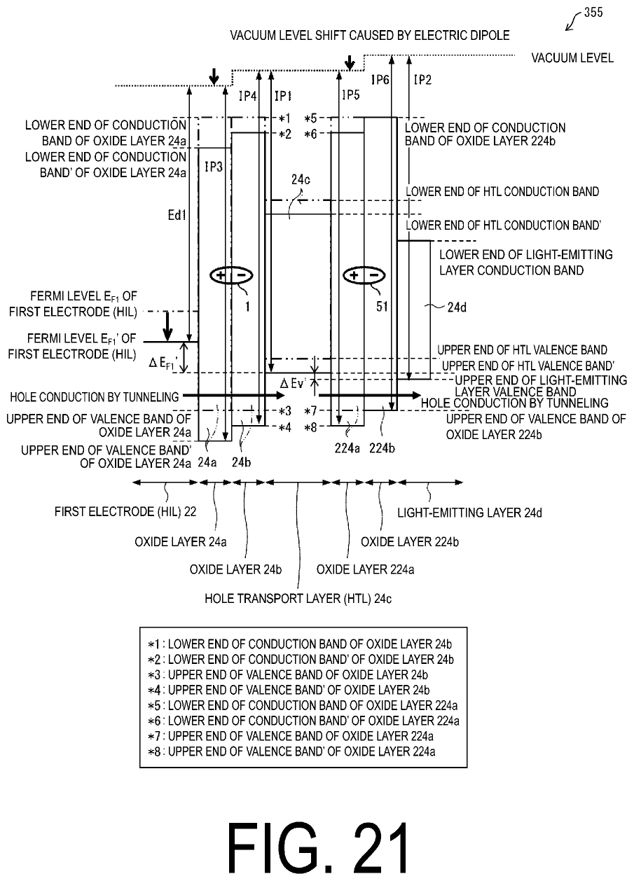

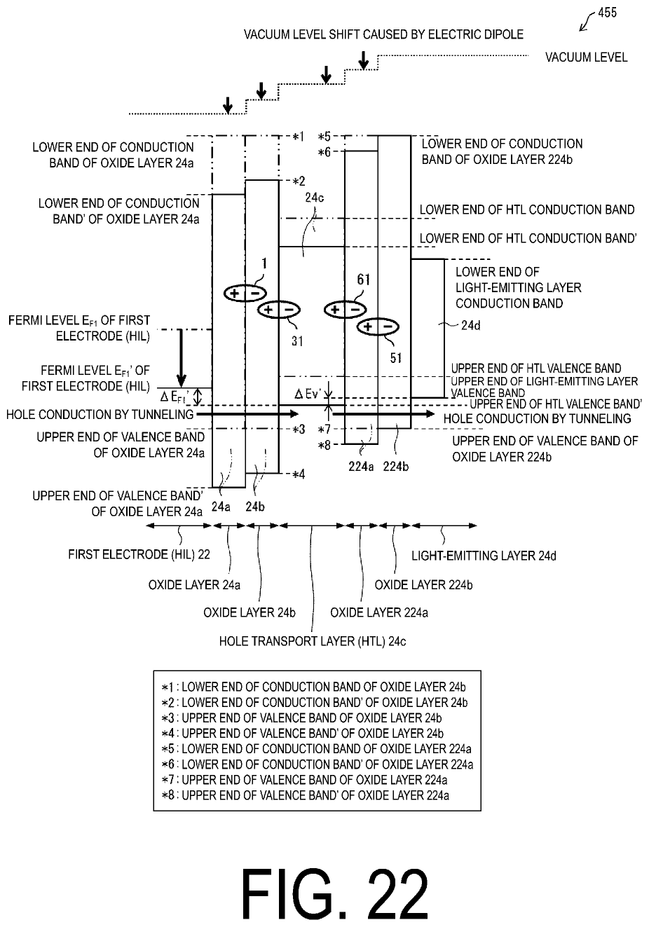

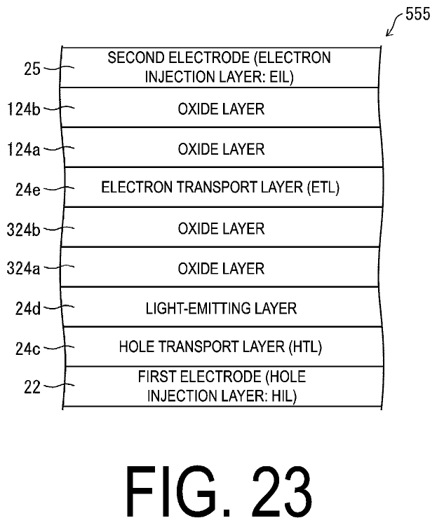

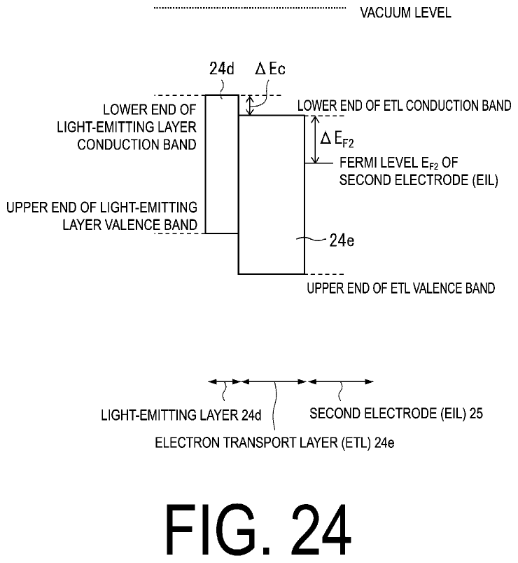

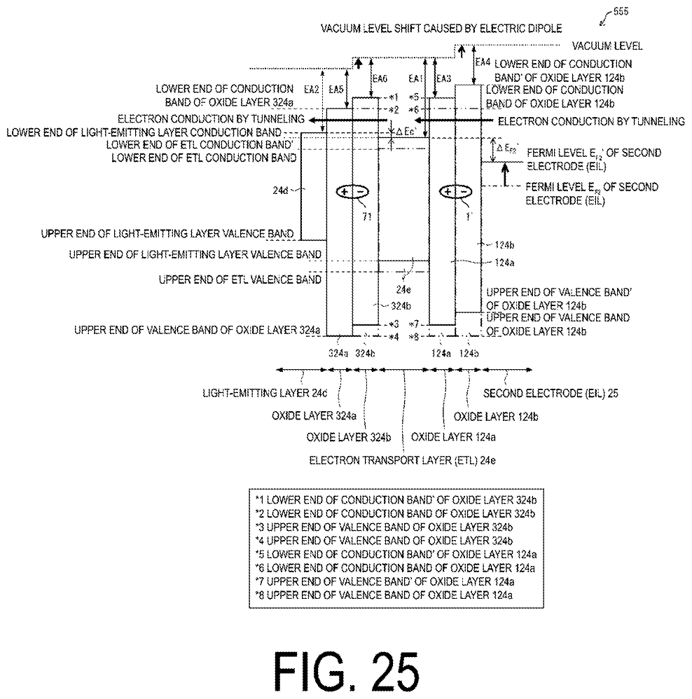

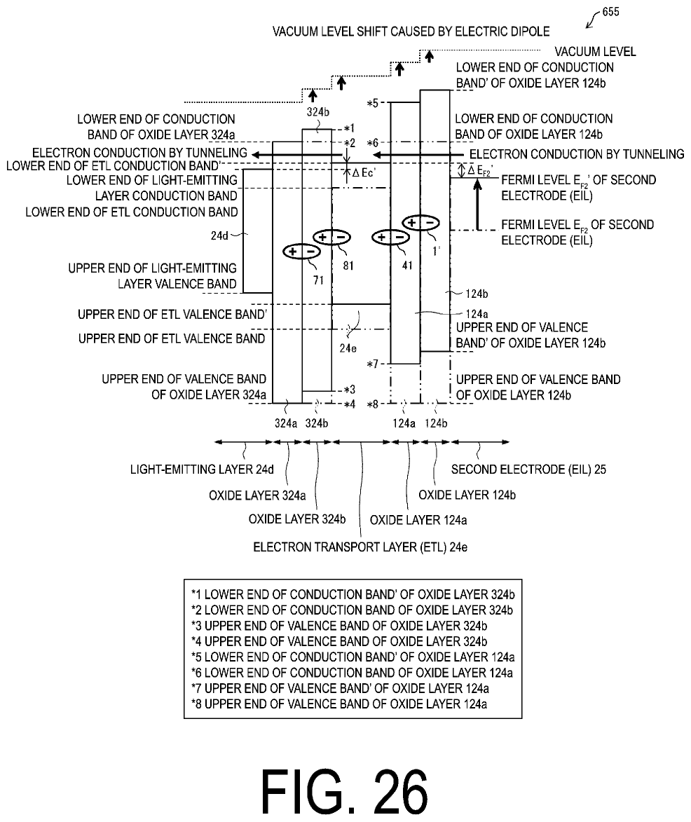

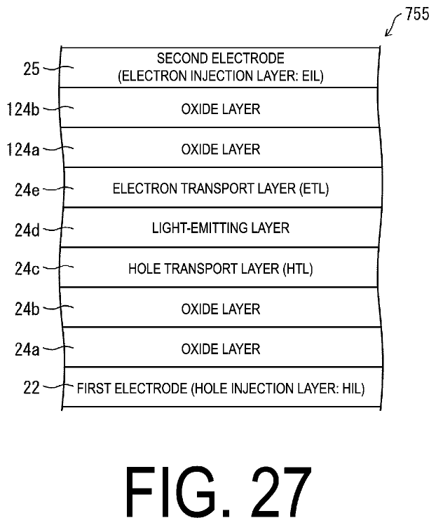

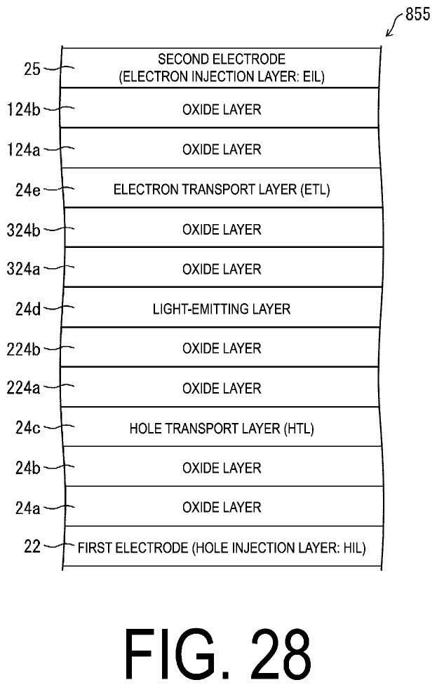

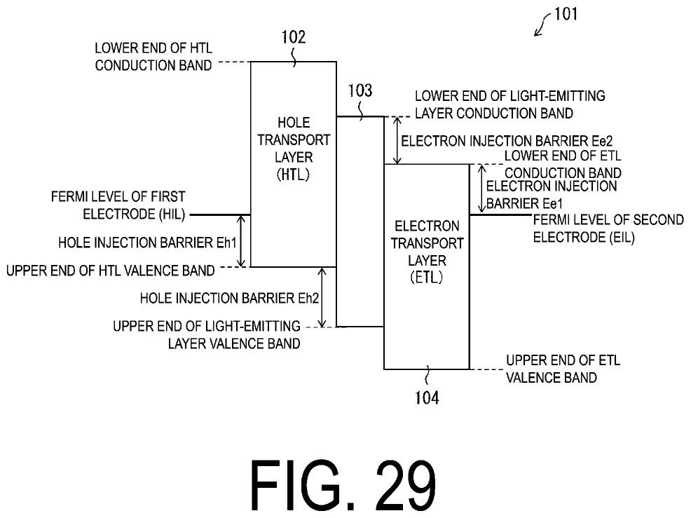

FIG. 2 is a cross-sectional view schematically illustrating a schematic configuration of a light-emitting element 5 according to the present embodiment.

As illustrated in FIG. 2, the light-emitting element 5 includes a first electrode (hole injection layer: HIL) 22, a second electrode (electron injection layer: EIL) 25, and a light-emitting layer 24d provided between the first electrode 22 and the second electrode 25. In other words, the first electrode 22 is an anode, and the second electrode 25 is a cathode. An oxide layer 24a (first oxide layer), an oxide layer 24b (second oxide layer), and a hole transport layer (HTL) 24c are layered in this order, for example, between the first electrode 22 and the light-emitting layer 24d from the first electrode 22 side (in other words, the side closer to the first electrode 22). Note that the density of the oxygen atoms in the oxide layer 24a and the density of the oxygen atoms in the oxide layer 24b are different. An electron transport layer (ETL) 24e is provided between the light-emitting layer 24d and the second electrode 25.

Accordingly, the light-emitting element 5 includes, for example, the first electrode 22 (anode), the hole transport layer 24c, the light-emitting layer 24d, the electron transport layer 24e, and the second electrode 25 (cathode) from the lower layer side in this order and includes the oxide layer 24a and the oxide layer 24b in contact with the oxide layer 24b between the first electrode 22 and the hole transport layer 24c in this order from the first electrode 22 side.

Note that as described below, the order of the layers in the light-emitting element 5 may be reversed, and the light-emitting element 5 may include, for example, the first electrode 22 (anode), the hole transport layer 24c, the light-emitting layer 24d, the electron transport layer 24e, and the second electrode 25 (cathode) from the upper layer side in this order and include the oxide layer 24a the oxide layer 24b in contact with the oxide layer 24a between the first electrode 22 and the hole transport layer 24c in this order from the first electrode 22 side.

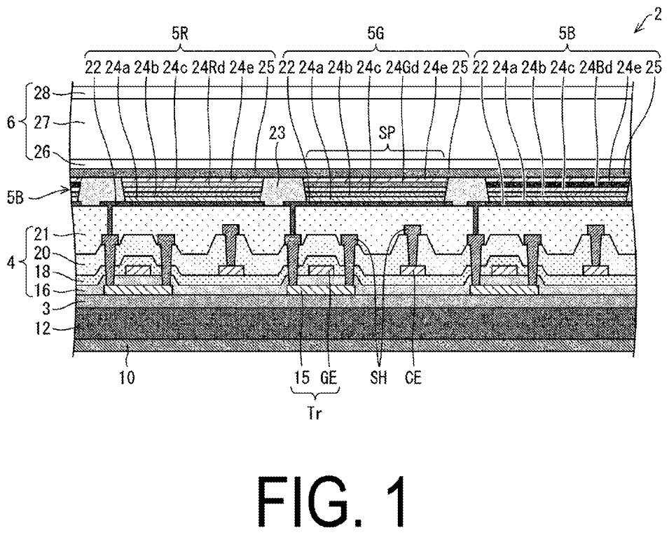

Note that in the present embodiment, a “lower layer” refers to a layer formed in a process before the layer being compared, and an “upper layer” refers to a layer formed in a process after the layer being compared. More specifically, the lower layer side refers to the substrate side, for example. Accordingly, “the light-emitting element 5 includes, for example, the first electrode 22, the hole transport layer 24c, the light-emitting layer 24d, the electron transport layer 24e, and the second electrode 25 in this order from the lower layer side” means that “the light-emitting element 5 includes each of the layers above a substrate (for example, in the example illustrated in FIG. 1 described later, an array substrate on which the first electrode 22 is formed and a layered body including a substrate 10, a resin layer 12, a barrier layer 3, and a TFT layer 4) functioning as a support body from the substrate side in this order”. Note that the light-emitting element 5 may include the substrate described above.

(a) of FIG. 4 is a diagram for describing the mechanism by which oxygen atoms move at the interface between the oxide layer 34a on the first electrode 22 side and the oxide layer 24b on the second electrode 25 side (in other words, the hole transport layer 24c side), the oxide layer 34a and the oxide layer 24b being adjacent to one another in the light-emitting element 5 of the present embodiment. (b) of FIG. 4 is a diagram illustrating the interface between the oxide layer 24a and the oxide layer 24b with an electric dipole 1 formed by the movement of oxygen atoms.

In the present embodiment, the density of the oxygen atoms in the oxide layer 24b, which is the oxide layer (second oxide layer) farther from the first electrode 22 of the oxide layer 24a and the oxide layer 24b adjacent to one another provided between the first electrode 22 and the carrier transport layer (the hole transport layer 24c in the present embodiment), is preferably less than the density of the oxygen atoms in the oxide layer 24a, which is the oxide layer (first oxide layer) closer to the first electrode 22. Note that the density of the oxygen atoms in the oxide layer 24a may be referred to as the “oxygen atom density of the oxide layer 24a”. Also, the density of the oxygen atoms in the oxide layer 24b may be referred to as the “oxygen atom density of the oxide layer 24b”.

Thus, as illustrated in (a) of FIG. 4, when the oxide layer 24b is formed above the oxide layer 24a in contact with the oxide layer 24a, oxygen atoms easily move at the interface between the oxide layer 24a and the oxide layer 24b from the oxide layer 24a toward the oxide layer 24b. As oxygen atoms move, the oxygen holes become positively charged and the moving oxygen atoms become negatively charged.

Accordingly, as illustrated in (b) of FIG. 4, at the interface between the oxide layer 24a and the oxide layer 24b, the electric dipole 1 having a dipole moment including a component orientated in the direction from the oxide layer 24b to the oxide layer 24a is formed.

FIG. 1 is a cross-sectional view illustrating a schematic configuration of a display device 2 including light-emitting elements 5R, 5G, and 5B as the light-emitting element 5.

Note that the following description is based on a case where the light-emitting device according to the present embodiment is the display device 2 including a plurality of the light-emitting elements 5. However, the present disclosure is not limited thereto, and the light-emitting device may be a display device, an illumination device, or the like including one or more of the light-emitting elements 5.

As illustrated in FIG. 1, above the substrate 10 of the display device 2, the resin layer 12, the barrier layer 3, the TFT layer 4, the light-emitting elements 5R, 5G, 5B, and a sealing layer 6 are layered.

Examples of the material of the substrate 10 include polyethylene terephthalate (PET), a glass substrate, and the like, but the material is not limited thereto. In the present embodiment, in order for the display device 2 to be a flexible display device, PET is used as the material of the substrate 10, but if the display device 2 is a non-flexible display device, a glass substrate or the like may be used.

Examples of the material of the resin layer 12 include a polyimide resin, an epoxy resin, and a polyamide resin, but are not limited thereto. In the present embodiment, the display device 2 is made as a flexible display device by radiating the resin layer 12 through a support substrate (not illustrated) with laser light and lowering the bonding strength between the support substrate (not illustrated) and the resin layer 12, peeling (laser lift off (LLO) process) the support substrate (not illustrated) from the resin layer 12, and adhering the substrate 10 made of PET to the surface of the resin layer 12 where the support substrate (not illustrated) was peeled off from. However, in a case where the display device 2 is a non-flexible display device or when the display device 2 is a flexible display device made by a method other than the LLO process, the resin layer 12 is not necessary.

The barrier layer 3 is a layer that inhibits moisture and impurities from reaching the TFT layer 4 and the light-emitting elements 5R, 5G, 5B when the display device 2 is used and can be formed, for example, by a silicon oxide film, a silicon nitride film, or a silicon oxynitride film, or by a layered film of these, formed by chemical vapor deposition (CVD).

The TFT layer 4 includes a semiconductor film 15, an inorganic insulating film 16 (a gate insulating film) above the semiconductor film 15, a gate electrode GE above the inorganic insulating film 16, an inorganic insulating film 18 above the gate electrode GE, a capacitance wiring line CE above the inorganic insulating film 18, an inorganic insulating film 20 above the capacitance wiring line CE, a source-drain wiring line SH including a source-drain electrode above the inorganic insulating film 20, and a flattening film 21 above the source-drain wiring line SH.

A thin film transistor element Tr (TFT element) as an active element is configured so as to include the semiconductor film 15, the inorganic insulating film 16 (gate insulating film), the gate electrode GE, the inorganic insulating film 18, the inorganic insulating film 20, and the source-drain wiring line SH.

The semiconductor film 15 is formed of low-temperature polysilicon (LTPS) or an oxide semiconductor, for example. Note that FIG. 1 illustrates the TFT that has a top gate structure including the semiconductor film 15 as a channel, but the TFT may have a bottom gate structure.

Each of the gate electrodes GE, the capacitance electrodes CE, the source-drain wiring line SH, the wiring lines TW, and the terminals TM is formed of, for example, a monolayer film or a layered film of metal containing at least one of aluminum (Al), tungsten (W), molybdenum (Mo), tantalum (Ta), chromium (Cr), titanium (Ti), and copper (Cu).

The inorganic insulating films 16, 18, and 20 may be formed of, for example, a silicon oxide (SiOx) film, a silicon nitride (SiNx) film, or a silicon oxynitride film, or of a layered film of these, formed by CVD.

The flattening film (interlayer insulating film) 21 may be formed, for example, of a coatable photosensitive organic material, such as a polyimide resin and an acrylic resin.

The light-emitting element 5R includes a light-emitting layer 24Rd in a first wavelength region as the light-emitting layer 24d. The light-emitting element 5G includes a light-emitting layer 24Gd in a second wavelength region as the light-emitting layer 24d. The light-emitting element 5B includes a light-emitting layer 24Bd in a third wavelength region as the light-emitting layer 24d.

The light-emitting layer 24Rd of the first wavelength region, the light-emitting layer 24Gd of the second wavelength region, and the light-emitting layer 24Bd of the third wavelength region have different center wavelengths of the light emitted. In the present embodiment, a case is described where the light-emitting layer 24Rd of the first wavelength region emits a red color, the light-emitting layer 24Gd of the second wavelength region emits a green color, and the light-emitting layer 24Bd of the third wavelength region emits a blue color, but no such limitation is intended.

Also, in the present embodiment, a case is described where the display device 2 includes the three types of light-emitting elements 5R, 5G, 5B that emit red, green, and blue light. However, no such limitation is intended, and four types of light-emitting elements may be provided that emit light of different color. Alternatively, the display device may be provided with one type or two types of light-emitting elements.

The light-emitting layer 24d (specifically, the light-emitting layers 24Rd, 24Gd, and 24Bd) is a light-emitting layer including nanosized quantum dots (nanoparticles). The light-emitting layer 24d may include, for example, quantum dot phosphors. As the material of the quantum dots, for example, any of CdSe/CdS, CdSe/ZnS, InP/ZnS, and CIGS/ZnS may be used. Also, the particle size of the quantum dots is approximately from 3 to 10 nm. In order to configure the light-emitting layers 24Rd, 24Gd, and 24Bd with different center wavelengths of emitted light, the light-emitting layers 24Rd, 24Gd, and 24Bd may use quantum dots with different particle sizes or may use quantum dots of different types.

In the present embodiment, a case is described where a light-emitting layer including quantum dots (nanoparticles) is used as the light-emitting layer 24d. However, the present embodiment is not limited to this configuration, and a light-emitting layer for an OLED may be used as the light-emitting layer 24d.

In a case where the light-emitting element 5 (specifically, the light-emitting elements 5R, 5G, 5B) is a QLED, positive holes and electrons recombine inside the light-emitting layer 24d in response to a drive current between the first electrode 22 and the second electrode 25, and light (fluoresce) is emitted when the excitons generated in this manner transition from a conduction band to a valence band of the quantum dot.

In a case where light-emitting element 5 (specifically, the light-emitting elements 5R, 5G, 5B) is an OLED, positive holes and electrons recombine inside the light-emitting layer 24d in response to a drive current between the first electrode 22 and the second electrode 25, and light is emitted when the excitons generated in this manner transition to a ground state.

A light-emitting element other than the OLED or the QLED (such as an inorganic light-emitting diode) may be formed as the light-emitting element 5.

Each of the light-emitting elements 5R, 5G, and 5B has a configuration in which the first electrode 22, the oxide layer 24a, the oxide layer 24b, the hole transport layer 24c, the light-emitting layers 24d (any one of the light-emitting layer 24Rd, the light-emitting layer 24Gd, or the light-emitting layer 24Bd) with different wavelength regions, the electron transport layer 24e, and the second electrode 25 are layered in this order. Note that the layering order from the first electrode 22 to the second electrode 25 may be reversed. Also, although the materials of the hole transport layer 24c and the electron transport layer 24e of the light-emitting elements 5R, 5G, and 5B are as described later, the hole transport layer 24c and the electron transport layer 24e of the light-emitting elements 5R, 5G, and 5B are not necessarily formed of common materials and may be formed of different materials.

Note that each of the light-emitting elements 5R, 5G, and 5B is a subpixel SP of the display device 2.

The bank 23 that covers the edge of the first electrode 22 may be formed of, for example, a coatable photosensitive organic material such as a polyimide resin or an acrylic resin.

In the present embodiment, a case is described where the first electrode 22, the oxide layer 24a, the oxide layer 24b, the hole transport layer 24c, the light-emitting layer 24d, and the electron transport layer 24e are formed into island shapes for each subpixel SP, with the second electrode 25 formed as a solid-like common layer, but no such limitation is intended. For example, the oxide layer 24a, the oxide layer 24b, the hole transport layer 24c, the electron transport layer 24e, and the second electrode 25, excluding the first electrode 22 and the light-emitting layer 24d, may be formed as a solid-like common layer. Note that in this case, the bank 23 need not be provided.

The first electrode 22 is formed of a conductive material and has a function as a hole injection layer (HIL) for injecting a positive hole in the hole transport layer 24c via the oxide layer 24a and the oxide layer 24b. The second electrode 25 is formed of a conductive material and has a function as an electron injection layer (EIL) for injecting an electron in the electron transport layer 24e.

At least one of the first electrode 22 or the second electrode 25 is made of a light-transmissive material. Note that one of the first electrode 22 or the second electrode 25 may be formed from a light-reflective material. In a case where the display device 2 is a top-emitting display device, the second electrode 25 being an upper layer is formed of a light-transmissive material, and the first electrode 22 being a lower layer is formed of a light-reflective material. In a case where the display device 2 is a bottom-emitting display device, the second electrode 25 being an upper layer is formed of a light-reflective material, and the first electrode 22 being a lower layer is formed of a light-transmissive material. In a case where the layering order from the first electrode 22 to the second electrode 25 is reversed, the display device 2 can be formed as a top-emitting display device by the first electrode 22, being an upper layer, being formed of a light-transmissive material and the second electrode 25, being a lower layer, being formed of a light-reflective material. Also, the display device 2 can be formed as a bottom-emitting display device by the first electrode 22, being an upper layer, being formed of a light-reflective material and the second electrode 25, being a lower layer, being formed of a light-transmissive material.

As the light-transmissive material, a transparent conductive film material can be used, for example. Specifically, Indium Tin Oxide (ITO), Indium Zinc Oxide (IZO), ZnO, aluminum-doped zinc oxide (AZO), boron-doped zinc oxide (BZO), or the like may be used. These materials have a high transmittance of visible light, and thus luminous efficiency is improved.

As the light-reflective material, a material with high visible light reflectivity such as a metal material is preferably used. Specifically, for example, Al, Cu, Au, Ag, or the like may be used. These materials have a high reflectivity of visible light, and thus luminous efficiency is improved.

In addition, an electrode with light reflectivity obtained by making either one of the first electrode 22 or the second electrode 25 a layered body including a light-transmissive material and a light-reflective material may be used.

Note that in the present embodiment, because the display device 2 is a top-emitting type, the second electrode 25 being an upper layer is formed of a light-transmissive material, and the first electrode 22 being a lower layer is formed of a light-reflective material.

The hole transport layer 24c is a layer that transports holes and inhibits the movement of electrons. The material of the hole transport layer 24c is not particularly limited as long as it is a hole transport material, and a known hole transport material can be used. Among these, a p-type semiconductor, for example, is preferably used as the hole transport material. Examples of the hole transport material include NiO (nickel oxide), CuAlO₂ (copper aluminate), PEDOT:PSS (poly(3,4-ethylenedioxythiophene)-poly(4-styrenesulfonate)), PVK (polyvinyl carbazole), and the like. Nanoparticles may be used for the hole transport material.

Also, the hole transport layer 24c may be formed from an oxide containing at least one of Ni or Cu. In addition, the hole transport layer 24c may include an oxide in which the most abundant elements other than oxygen are one of Ni or Cu. In this case, the hole transport layer 24c has good hole conductivity.

The hole transport material may be an oxide or a material other than an oxide. Accordingly, the hole transport layer 24c may or may not contain an oxygen atom within the hole transport layer 24c. In a case where the hole transport material is an oxide (in other words, when the hole transport layer 24c is formed from an oxide), the oxygen atom density of the hole transport layer 24c (that is, the density of the oxygen atoms in the hole transport layer 24c) is preferably less than the oxygen atom density of the oxide layer 24b adjacent to the hole transport layer 24c, as illustrated in the second embodiment described below. In other words, the oxygen atom density of the oxide layer 24b is preferably greater than the oxygen atom density of the hole transport layer 24c. However, the oxygen atom density of the oxide layer 24b may be the same as the oxygen atom density of the hole transport layer 24c or may be less than the oxygen atom density of the hole transport layer 24c.

Because the oxide layer 24a and the oxide layer 24b are provided separately from the hole transport layer 24c, the electric dipole can be freely formed without reducing the flexibility in the selection of the material of the hole transport layer 24c. Accordingly, the amount of hole injection from the first electrode 22 to the hole transport layer 24c can be freely controlled. As a result, the amount of hole injection to the light-emitting layer 24d can be freely controlled.

The oxide layer 24a is preferably formed from an inorganic oxide. The oxide layer 24a is preferably formed from an insulator (insulating material). Furthermore, the oxide layer 24a is preferably formed from an inorganic oxide insulator. In these cases, the long-term reliability is enhanced. That is, the luminous efficiency after aging is enhanced.

The oxide layer 24b is preferably formed from an inorganic oxide, for example. The oxide layer 24b is preferably formed from an insulator (insulating material). Furthermore, the oxide layer 24b is preferably formed from an inorganic oxide insulator. In these cases, the long-term reliability is enhanced. That is, the luminous efficiency after aging is enhanced.

Furthermore, the oxide layer 24a and the oxide layer 24b are further preferably both formed from an inorganic oxide. Furthermore, the oxide layer 24a and the oxide layer 24b are further preferably both formed from an insulator (inorganic insulator). In these cases, the long-term reliability is further enhanced. That is, the luminous efficiency after aging is further enhanced.

The oxide layer 24a and the oxide layer 24b may be, independent of one another, formed from an oxide with a main component of at least one element from Al (aluminum), Ga (gallium), Ta (tantalum), Zr (zirconium), Hf (hafnium), Mg (magnesium), Ge (germanium), Si (silicon), Y (yttrium), La (lanthanum), and Sr (strontium). In other words, the oxide layer 24a and the oxide layer 24b may be oxides containing the same element as the at least one main component or may be an oxides containing different elements as the main component. In addition, the oxide layer 24a and the oxide layer 24b may be formed from oxides in which the most abundant element other than oxygen is any one of Al, Ga, Ta, Zr, Hf, Mg, Ge, Si, Y, La, or Sr.

More specifically, the oxide layer 24a and the oxide layer 24b may contain at least one of, for example, aluminum oxide (for example, Al₂O₃), gallium oxide (for example, Ga₂O₃ having a crystal structure such as an α-structure or β-structure), tantalum oxide (for example, Ta₂O₅), zirconium oxide (for example, ZrO₂), hafnium oxide (for example, HfO₂), magnesium oxide (for example, MgO), germanium oxide (for example, ZeO₂), silicon oxide (for example, SiO₂), yttrium oxide (for example, Y₂O₃), lanthanum oxide (for example, La₂O₃), strontium oxide (for example, SrO), or a composite oxide containing two or more types of cations of these oxides, or may be formed from any one of the composite oxides described above. The composite oxide is not particularly limited, and examples thereof include oxides containing Si and Al. Note that the oxide layer 24a and the oxide layer 24b are described in more detail below.

The electron transport layer 24e is a layer that transports electrons and inhibits the movement of holes. The material of the electron transport layer 24e is not particularly limited as long as it is an electron transport material, and a known electron transport material can be used. The electron transport material may be an oxide or a material other than an oxide. As the electron transport material, ZnO, TiO₂, SrTiO₃, and the like can be used. Also, nanoparticles may be used for the electron transport material. An n-type semiconductor, for example, is preferably used as the electron transport material. Also, as the electron transport material, an organic material, such as TPBi (1,3,5-tris(1-phenyl-1-H-benzimidazol-2-yl)benzene), Alq3 (tris(8-hydroxy-quinolinate)aluminum), BCP (2,9-dimethyl-4,7-diphenyl-1,10-phenanthroline), and the like, may be used.

Also, the electron transport layer 24e may be formed from an oxide containing at least one of Ti, Zn, Sn, or In. Furthermore, the electron transport layer 24e may include an oxide in which the most abundant elements other than oxygen are one of Ti, Zn, Sn, or In. In this case, the electron transport layer 24e has good electron conductivity.

The sealing layer 6 is a light transmissive layer, and includes a first inorganic sealing film 26 that covers the second electrode 25, an organic sealing film 27 that is formed on a side above the first inorganic sealing film 26, and a second inorganic sealing film 28 that covers the organic sealing film 27. The sealing layer 6 covering the light-emitting elements 5R, 5G, 5B inhibits foreign matters such as water and oxygen from penetrating into the light-emitting elements 5R, 5G, 5B.

Each of the first inorganic sealing film 26 and the second inorganic sealing film 28 may be formed of, for example, a silicon oxide film, a silicon nitride film, or a silicon oxynitride film, or of a layered film of these, formed through the CVD method. The organic sealing film 27 is a light transmissive organic film which is thicker than the first inorganic sealing film 26 and the second inorganic sealing film 28, and can be formed of a coatable photosensitive organic material such as a polyimide resin or an acrylic resin.

(a) of FIG. 3 is an energy band diagram for describing a hole injection barrier between the first electrode 22 (anode) and the hole transport layer 24c in the light-emitting element according to a comparative example. (b) of FIG. 3 is an energy band diagram for describing a hole injection barrier between the first electrode 22 (anode) and the hole transport layer 24c in the light-emitting element 5.

As illustrated in (a) of FIG. 3, in the light-emitting element according to a comparative example in which the first electrode 22 and the hole transport layer 24c come into direct contact, the energy difference ΔE_{F1} between the Fermi level E_{F1} of the first electrode 22 and the upper end of the valence band (HTL valence band) of the hole transport layer 24c is large. Because the energy difference ΔE_{F1} is the height of the hole injection barrier from the first electrode 22 to the hole transport layer 24c, efficient hole injection from the first electrode 22 to the hole transport layer 24c cannot be achieved in the light-emitting element illustrated in (a) of FIG. 3. Thus, efficient hole injection to the light-emitting layer 24d cannot be achieved.

On the other hand, as illustrated in (b) of FIG. 3, the light-emitting element 5 according to the present embodiment includes, between the first electrode 22 and the hole transport layer 24c, the oxide layer 24a and the oxide layer 24b layered adjacent to one another in this order from the first electrode 22 side, and as described above, the oxygen atom density of the oxide layer 24b is less than the oxygen atom density of the oxide layer 24a. Thus, the oxygen atoms can easily move from the oxide layer 24a toward the oxide layer 24b at the interface between the oxide layer 24a and the oxide layer 24b, and, at the interface, the electric dipole 1 having a dipole moment including a component orientated in the direction from the oxide layer 24b to the oxide layer 24a is formed.

When the electric dipole 1 is formed in this manner, as illustrated in (b) of FIG. 3, a vacuum level shift caused by the electric dipole 1 occurs at the interface between the oxide layer 24a and the oxide layer 24b, which is the interface where the electric dipole 1 is formed. As a result, as illustrated in (b) of FIG. 3, at the interface between the oxide layer 24a and the oxide layer 24b, the position of the band on the first electrode 22 side (the position of the lower end of the conduction band and the upper end of the valence band) moves downward with respect to the position of the band on the second electrode 25 side. In other words, in the example illustrated in (b) of FIG. 3, the position of the band of the first electrode 22 and the position of the band of the oxide layer 24a move downward (band shift) with respect to the position of the band of the oxide layer 24b, the position of the band of the hole transport layer 24c, and the position of the band of the light-emitting layer 24d. Although not illustrated, at this time, obviously the position of the band on the second electrode 25 side includes the position of the band of the layer on the second electrode 25 side of the light-emitting layer 24d. Note that in (b) of FIG. 3, the position of the band of the Fermi level E_{F1} of the first electrode 22 before the vacuum level shift due to the electric dipole 1 is indicated by a dot-dash line, and the position of the band of the oxide layer 24a before the vacuum level shift due to the electric dipole 1 is indicated by a two-dot chain line. Also, the vacuum level after the vacuum level shift due to the electric dipole 1 is indicated by a dotted line.

Specifically, when the electric dipole 1 is formed, the Fermi level E_{F1} of the first electrode 22 moves to the Fermi level E_{F1}′ of the first electrode 22, the valence band of the oxide layer 24a moves to the valence band′ of the oxide layer 24a, and the conduction band of the oxide layer 24a moves to the conduction band′ of the oxide layer 24a. By this movement, the energy difference ΔE_{F1} between the Fermi level E_{F1} of the first electrode 22 and the upper end of the valence band of the hole transport layer 24c (upper end of the HTL valence band) becomes the energy difference ΔE_{F1}′ between the Fermi level E_{F1}′ of the first electrode 22 and the upper end of the valence band of the hole transport layer 24c (upper end of the HTL valence band). As a result, the energy difference ΔE_{F1}′ after formation of the electric dipole 1 (in other words, the hole injection barrier height from the first electrode 22 to the hole transport layer 24c after formation of the electric dipole 1) is less than the energy difference ΔE_{F1} (in other words, the hole injection barrier height from the first electrode 22 to the hole transport layer 24c in a case where the oxide layer 24a and the oxide layer 24b are not formed).

In a case where the film thickness of the oxide layer 24a and the oxide layer 24b is sufficiently thin in the light-emitting element 5, because the holes have conductivity via tunneling of the oxide layer 24a and oxide layer 24b, the hole injection barrier height between the first electrode 22 and the hole transport layer 24c is effectively the energy difference ΔE_{F1}′ between the Fermi level E_{F1}′ of the first electrode 22 and the upper end of the valence band of the hole transport layer 24c (upper end of the HTL valence band). According to the present embodiment, by forming the oxide layer 24a and the oxide layer 24b in this manner, efficient hole injection from the first electrode 22 to the hole transport layer 24c can be achieved. As a result, the efficiency of hole injection from the first electrode 22 to the light-emitting layer 24d (via the hole transport layer 24c) is improved, and the luminous efficiency of the light-emitting element 5 is improved.

Note that in the present disclosure, the energy difference ΔE_{F1}′ indicates “the energy difference between the Fermi level of the first electrode 22 and the upper end of the valence band of the hole transport layer 24c after electric dipole formation”. Thus, in the present embodiment, “after electric dipole formation” refers to “after formation of the electric dipole 1”, and “the energy difference between the Fermi level of the first electrode 22 and the upper end of the valence band of the hole transport layer 24c after electric dipole formation” refers to “the energy difference between the Fermi level E_{F1}′ of the first electrode 22 and the upper end of the HTL valence band after formation of the electric dipole 1” as described above. Also in the present disclosure, the reference sign of the energy difference ΔE_{F1}′ is positive (ΔE_{F1}′>0) in a case where, after electric dipole formation, the Fermi level of the first electrode 22 (in the present embodiment, the Fermi level ΔE_{F1}′ of the first electrode 22) is on a higher energy side (on the upper side in the band diagram) than the upper end of the valence band of the hole transport layer 24c (in the present embodiment, the upper end of the HTL valence band), and is negative (ΔE_{F1}′ <0) in a case where, after electric dipole formation, the Fermi level of the first electrode 22 (in the present embodiment, the Fermi level ΔE_{F1}′ of the first electrode 22) is on a lower energy side (on the lower side in the band diagram) than the upper end of the valence band of the hole transport layer 24c (in the present embodiment, the upper end of the HTL valence band).

In a similar manner, in the present disclosure, the energy difference ΔE_{F1} indicates “the energy difference between the Fermi level of the first electrode 22 (in other words, the Fermi level E_{F1} of the first electrode 22) and the upper end of the valence band of the hole transport layer 24c (in other words, the upper end of the HTL valence band) after electric dipole formation (in other words, in a state where there is no vacuum level shift)”. Thus, in the present embodiment, “before electric dipole formation” refers to “before forming the electric dipole 1”. Also in the present disclosure, the reference sign of the energy difference ΔE_{F1} is positive (ΔE_{F1}>0) in a case where, before electric dipole formation, the Fermi level of the first electrode 22 (in other words, the Fermi level ΔE_{F1} of the first electrode 22) is on a higher energy side (on the upper side in the band diagram) than the upper end of the valence band of the hole transport layer 24c (the upper end of the HTL valence band), and is negative (ΔE_{F1}<0) in a case where, before electric dipole formation, the Fermi level of the first electrode 22 (in other words, the Fermi level ΔE_{F1} of the first electrode 22) is on a lower energy side (on the lower side in the band diagram) than the upper end of the valence band of the hole transport layer 24c (in other words, the upper end of the HTL valence band).

In a case where the hole injection barrier height is negative, it means that there is no hole injection barrier present.

Note that in (b) of FIG. 3, an example is given of a case in which the position (position of the lower end of the conduction band and the upper end of the valence band) of the band of the oxide layer 24a and the position (position of the lower end of the conduction band and the upper end of the valence band) of the band of the oxide layer 24b before the vacuum level shift is caused by the electric dipole 1, indicated by the two-dot chain line, are the same. However, the position of the bands of oxide layer 24a and oxide layer 24b are determined by the material selected for the oxide layer 24a and oxide layer 24b, and thus the positions are not limited to those in example illustrated in (b) of FIG. 3. In the example illustrated in (b) of FIG. 3, an example is given of a case in which the Fermi level E_{F1}′ of the first electrode 22 after a band shift has been caused by formation of the electric dipole 1 is positioned above the upper end of the HTL valence band. However, the Fermi level E_{F1}′ of the first electrode 22 after the band shift may be positioned below the upper end of the HTL valence band and is more preferably positioned below.

The film thickness of the oxide layer 24a is preferably is from 0.2 nm to 5 nm. By setting the film thickness of the oxide layer 24a to be 5 nm or less, hole tunneling can be efficient. Additionally, by setting the film thickness of the oxide layer 24a to be 0.2 nm or greater, a sufficiently large dipole moment can be obtained. The film thickness of the oxide layer 24a is more preferably is from 0.8 nm to 3 nm or less. In this case, more efficient hole injection is possible.

In a similar manner, the film thickness of the oxide layer 24b is preferably is from 0.2 nm to 5 nm. By setting the film thickness of the oxide layer 24b to be 5 nm or less, hole tunneling can be efficient. Additionally, by setting the film thickness of the oxide layer 24b to be 0.2 nm or greater, a sufficiently large dipole moment can be obtained. The film thickness of the oxide layer 24b is also more preferably is from 0.8 nm to 3 nm or less, and in this case, more efficient hole injection is possible.

The total film thickness of the oxide layer 24a and the oxide layer 24b is preferably is from 0.4 nm to 5 nm. By setting the total film thickness to be 5 nm or less, hole tunneling can be efficient. Additionally, by setting the total film thickness to be 0.4 nm or greater, a sufficiently large dipole moment can be obtained. The total film thickness is more preferably is from 1.6 nm to 4 nm or less. In this case, more efficient hole injection is possible.

The oxide layer 24a may be formed of an amorphous oxide or may be formed with at least a portion of the contact surface with oxide layer 24b formed of a polycrystalline oxide. Also, the oxide layer 24b may also be formed of an amorphous oxide or may be formed with at least a portion of the contact surface with oxide layer 24a formed of a polycrystalline oxide.

Note that only the contact surface of the oxide layer 24a with the oxide layer 24b may be polycrystalline, or the entire oxide layer 24a may be formed of a polycrystalline oxide. Also, only the contact surface of the oxide layer 24b with the oxide layer 24a may be polycrystalline, or the entire oxide layer 24b may be formed of a polycrystalline oxide. In other words, at least at the contact surface between the oxide layer 24a and the oxide layer 24b, at least one of the oxide layer 24a or the oxide layer 24b may include a polycrystalline oxide.

In the present embodiment, in a case where the oxygen atom density of the oxide layer 24b is less than the oxygen atom density of the oxide layer 24a, the method of making the oxide layer 24a and the oxide layer 24b polycrystalline is not particularly limited. Also, in a case where the oxygen atom density of the oxide layer 24b is less than the oxygen atom density of the oxide layer 24a, the type of polycrystalline oxide forming the oxide layer 24a and the oxide layer 24b is not particularly limited. Note that, an example of the above-described method for polycrystallization includes a heat treatment using laser light.

As described above, at least of a portion of the contact surface of the oxide layer 24a with the oxide layer 24b and at least a portion of the contact surface of the oxide layer 24b with the oxide layer 24a may be polycrystalline, but particularly preferably, the oxide layer 24a and the oxide layer 24b are each formed of an amorphous oxide. By forming the oxide layer 24a and the oxide layer 24b of an amorphous oxide, the film thickness uniformity of the oxide layer 24a and the oxide layer 24b can be improved, and the flatness of each surface can be improved (in other words, the surface roughness of the interface surface (interface) of the oxide layer 24a and the oxide layer 24b can be reduced). In this case, the electric dipole 1 can be easily uniformly formed within the interface, and the in-plane distribution of the energy difference ΔE_{F1}′ between the Fermi level E_{F1}′ of the first electrode 22 and the upper end of the HTL valence band can be made uniform across the entire contact surface between the oxide layer 24a and the oxide layer 24b. Thus, the uniformity of hole conductivity due to tunneling is improved, and the luminous efficiency is improved.

On the other hand, in a case where at least a portion of the contact surface of the oxide layer 24a with oxide layer 24b is polycrystalline, at least a portion of the contact surface of the oxide layer 24a with oxide layer 24b may include grains. Also, in a case where at least a portion of the contact surface of the oxide layer 24b with oxide layer 24a is polycrystalline, at least a portion of the contact surface of the oxide layer 24b with oxide layer 24a may include grains.

At least at the contact surface between the oxide layer 24a and the oxide layer 24b, by at least one of the oxide layer 24a or the oxide layer 24b including grains in this manner, the area of the interface between the oxide layer 24a and the oxide layer 24b is increased, allowing the electric dipole 1 to be more efficiently formed. Thus, efficient hole injection in the light-emitting element 5 is possible.

As described above, in the light-emitting element 5, at least at the contact surface between the oxide layer 24a and the oxide layer 24b, at least one of the oxide layer 24a or the oxide layer 24b may include a polycrystalline oxide.

Also, in the light-emitting element 5, at least at the contact surface between the oxide layer 24a and the oxide layer 24b, one of the oxide layer 24a or the oxide layer 24b may include a polycrystalline oxide, and the other may be formed of an amorphous oxide. For example, of the oxide layer 24a and the oxide layer 24b, the layer on the upper layer side may be formed of an amorphous oxide, and at least a portion of the top surface of the layer on the lower layer side may be polycrystalline. In this case, the upper surface of the layer on the lower layer side may include grains. The surface roughness of the upper surface of the layer on the lower layer side is also reflected in the contact surface (interface) of the layer on the upper layer side with the layer on the lower layer side.

Thus, for example, as illustrated in FIG. 2, in a case where the first electrode 22 is a layer on the lower layer side of the light-emitting layer 24d and the second electrode 25 is a layer on the upper layer side of the light-emitting layer 24d, the oxide layer 24b, which is the layer from among the oxide layer 24a and the oxide layer 24b on the upper layer side, may be formed of an amorphous oxide. The upper surface of the oxide layer 24a, which is the layer from among the oxide layer 24a and the oxide layer 24b on the lower layer side, may include grains. In this case, by the oxide layer 24b being an amorphous oxide, good coverage with respect to the oxide layer 24a including grains can be obtained. Thus, the electric dipole 1 can be easily formed, and the film thickness uniformity of the oxide layer 24b can be improved. This allows the uniformity of hole conductivity due to tunneling of the oxide layer 24b to be improved. By the upper surface of the oxide layer 24a including grains, the area of the interface between the upper surface of the oxide layer 24a and the oxide layer 24b is increased, allowing the electric dipole 1 to be more efficiently formed. As a result, in the light-emitting element 5, efficient hole injection to the hole transport layer 24c is possible, and thus efficient hole injection to the light-emitting layer 24d is possible.

Note that in the present embodiment, a case is described where grains are formed by polycrystallizing at least one of the contact surfaces described above. However, the present embodiment is not limited thereto, and, for example, grains may be formed in at least a portion of at least one of the contact surfaces by spontaneous nucleation using a sputtering method, a CVD method, or the like. Note that obviously the entire oxide layer 24a may include grains, and the entire oxide layer 24b may include grains.

In addition, at at least the contact surface of the oxide layer 24a with oxide layer 24b or at at least the contact surface of the oxide layer 24b with the oxide layer 24a, grains may be distributed discretely. Grains may also be crystal grains containing crystals or may include an amorphous phase.

When the hole injection barrier is large, hole injection is hindered, and when the hole injection barrier is small, hole injection is facilitated. By forming the oxide layer 24a and the oxide layer 24b of an amorphous oxide, the in-plane density variations of the electric dipole 1 formed between the two layers, i.e., the oxide layer 24a and the oxide layer 24b, can be reduced, in-plane variations in the hole injection barrier height can be suppressed, and in-plane variation in the efficiency of hole injection can be suppressed. As a result, the holes can easily uniformly tunnel the oxide layer 24a and the oxide layer 24b, the in-plane uniformity of the light emission in the light-emitting element 5 is improved, and the luminous efficiency is improved.

In addition, at least one layer of the oxide layer 24a or the oxide layer 24b is preferably a continuous film, and at least the layer, from among the oxide layer 24a and the oxide layer 24b, on the upper layer side is more preferably a continuous film. That is, of the oxide layer 24a and the oxide layer 24b, the film that is to be formed second may be a film formed over the entire surface of the entire substrate functioning as a support body (for example, in the example illustrated in FIG. 1, a layered body including the substrate 10, the resin layer 12, the barrier layer 3, and the TFT layer 4 that is an array substrate on which the first electrode 22 is formed). Note that in this example, the continuous film is a dense film having a porosity of less than 1%. In other words, the continuous film is a film with substantially no voids.

In other words, as illustrated in FIG. 2, in a case where the first electrode 22 is a layer on the lower layer side of the light-emitting layer 24d and the second electrode 25 is a layer on the upper layer side of the light-emitting layer 24d, of the oxide layer 24a and the oxide layer 24b, at least the oxide layer 24b positioned on the second electrode 25 side (in other words, the upper layer side) is preferably a continuous film. Also, in a case where the first electrode 22 is a layer on the upper layer side of the light-emitting layer 24d and the second electrode 25 is a layer on the lower layer side of the light-emitting layer 24d, of the oxide layer 24a and the oxide layer 24b, at least the oxide layer 24a positioned on the first electrode 22 side (in other words, the upper layer side) is preferably a continuous film.

In this case, of the oxide layer 24a and the oxide layer 24b, at least the layer on the upper layer side is preferably formed as a film by, for example, a sputtering method, a vapor deposition method, a CVD method (chemical vapor deposition method), a PVD method (physical vapor deposition method), or the like. In this case, a continuous film is formed. The oxide layer 24a and the oxide layer 24b formed in this manner have a large contact area, and the electric dipole 1 tends to be densely formed. Note that a film made by applying microparticles such as nanoparticles cannot be a continuous film because of the porous nature due to a large number of voids being formed between the microparticles.

As illustrated in (b) of FIG. 3, the energy difference Ed1 (i.e., the work function of the first electrode 22) between the vacuum level and the Fermi level E_{F1}′ of the first electrode 22 is less than an ionization potential IP1 of the hole transport layer 24c, and the ionization potential IP1 of the hole transport layer 24c is less than an ionization potential IP3 of the oxide layer 24a and an ionization potential IP4 of the oxide layer 24b. In the example of (b) of FIG. 3, (the energy difference Ed1 between the vacuum level and the Fermi level E_{F1}′ of the first electrode 22=the work function of the first electrode 22)<(the ionization potential IP1 of the hole transport layer 24c)<(the ionization potential IP3 of the oxide layer 24a)=(the ionization potential IP4 of the oxide layer 24b) holds true. In the example of (b) of FIG. 3, the ionization potential IP3 of the oxide layer 24a and the ionization potential IP4 of the oxide layer 24b are equal, however no such limitation is intended. In the present embodiment, it is only required that (i) the work function of the first electrode 22 (=the energy difference Ed1 between the vacuum level and the Fermi level E_{F1}′ of the first electrode 22), (ii) the ionization potential IP1 of the hole transport layer 24c, and (iii) the ionization potential IP3 of the oxide layer 24a and the ionization potential IP4 of the oxide layer 24b are smaller in this order.

The ionization potential IP3 of oxide layer 24a and the ionization potential IP4 of oxide layer 24b may be different because the location of the bands of the oxide layer 24a and the oxide layer 24b is determined by the selection of the material of the oxide layer 24a and the oxide layer 24b. For example, the work function of the first electrode 22 (=the energy difference Ed1 between the vacuum level and the Fermi level E_{F1}′ of the first electrode 22), the ionization potential IP1 of the hole transport layer 24c, the ionization potential IP3 of the oxide layer 24a, and the ionization potential IP4 of the oxide layer 24b may be smaller in this order, or the work function of the first electrode 22 (=the energy difference Ed1 between the vacuum level and the Fermi level E_{F1}′ of the first electrode 22), the ionization potential IP1 of the hole transport layer 24c, the ionization potential IP4 of the oxide layer 24b may be smaller in this order, and the ionization potential IP3 of the oxide layer 24a may be smaller in this order. In either case, the electric dipole 1 can reduce the hole injection barrier height between the first electrode 22 and the hole transport layer 24c from the energy difference ΔE_{F1} to the energy difference ΔE_{F1}′.

Also, as illustrated in (b) of FIG. 3, the energy difference between the lower end of the conduction band and the upper end of the valence band in the oxide layer 24a and the oxide layer 24b is greater than the energy difference between the lower end of the HTL conduction band and the upper end of the HTL valence band in the hole transport layer 24c. Thus, the carrier density (hole density) of the oxide layer 24a and the oxide layer 24b is less than the carrier density (hole density) of the hole transport layer 24c, and the oxide layer 24a and the oxide layer 24b are better at insulating than the hole transport layer 24c. Note that herein, the energy difference between the lower end of the conduction band and the upper end of the valence band in the oxide layer 24a and the oxide layer 24b refers to the energy difference between the lower end of the conduction band and the upper end of the valence band in the oxide layer 24a and the energy difference between the lower end of the conduction band and the upper end of the valence band in the oxide layer 24b. Note that, in the example illustrated in (b) of FIG. 3, the energy difference between the lower end of the conduction band and the upper end of the valence band in the oxide layer 24a is equal to the energy difference between the lower end of the conduction band′ and the upper end of the valence band′ of the oxide layer 24a. However, no such limitation is intended. Also, as described above, the carrier density (hole density) of the oxide layer 24a and the oxide layer 24b is less than the carrier density (hole density) of the hole transport layer 24c. Accordingly, hole conduction by tunneling occurs in the oxide layer 24a and the oxide layer 24b. Note that the carrier density (hole density) of the hole transport layer 24c is preferably 1/10¹⁵ cm⁻³ or greater, for example. In this case, the hole transport layer 24c has good electrical conductivity. The carrier density (hole density) of the hole transport layer 24c is preferably 3×10¹⁷ cm³ or less, for example. In this case, non-emission recombination is suppressed, and the luminous efficiency is improved.

As described above, in the present embodiment, the oxygen atom density of the oxide layer 24b is less than the oxygen atom density of the oxide layer 24a.

FIG. 5 is a diagram listing the oxygen atom density of inorganic oxides which are examples of the oxide for forming the oxide layer 24a and the oxide layer 24b.

For the oxides forming the oxide layer 24a and the oxide layer 24b, for example, of the two oxides selected from the inorganic oxides listed in FIG. 5, the oxide with the larger oxygen atom density should be selected as the oxide to form the oxide layer 24a, and the oxide with the smaller oxygen atom density should be selected as the oxide to form the oxide layer 24b.

As described above, a composite oxide containing multiple cations of the oxides listed in FIG. 5 can be used as the oxides for forming the oxide layer 24a and the oxide layer 24b.

By the oxygen atom density of the oxide layer 24b being less than the oxygen atom density of the oxide layer 24a, the electric dipole 1 having a dipole moment including a component oriented in the direction of the oxide layer 24a from the oxide layer 24b is more easily formed, and efficient hole injection from the first electrode 22 into the hole transport layer 24c is possible. As a result, efficient hole injection to the light-emitting layer 24d is possible, and the luminous efficiency is improved.

The oxygen atom density of the oxide layer 24b is preferably 95% or less, more preferably 90% or less, even more preferably 85% or less, even more preferably 80% or less, even more preferably 75% or less, and even more preferably 70% or less of the oxygen atom density of the oxide layer 24a. The smaller the oxygen atom density of the oxide layer 24b relative to the oxygen atom density of the oxide layer 24a, the more easily the oxygen atoms can move from the oxide layer 24a toward the oxide layer 24b, and the electric dipole 1 having a dipole moment including a component orientated in the direction from the oxide layer 24b to the oxide layer 24a is more efficiently formed. This allows for more efficient hole injection to the light-emitting layer 24d.

Also, the oxygen atom density of the oxide layer 24b is preferably 50% or less of the oxygen atom density of the oxide layer 24a. In this case, it is possible to suppress the formation of recombination centers due to dangling bonds and the like at the interface between the oxide layer 24a and the oxide layer 24b.

Note that the oxygen atom density in the present disclosure is a unique value for the oxide layer 24a and for the oxide layer 24b and applies to the oxygen atom bulk density of the material forming the oxide layer 24a or oxide layer 24b.

FIG. 6 is a diagram listing examples of combinations of oxides forming the oxide layer 24a and oxides forming the oxide layer 24b.

In the combinations listed in FIG. 6, because the oxygen atom density of the oxide layer 24b is less than the oxygen atom density of the oxide layer 24a, the electric dipole 1 is formed as illustrated in (b) of FIG. 3 and efficient hole injection from the first electrode 22 to the hole transport layer 24c is possible. As a result, efficient hole injection to the light-emitting layer 24d is possible and the luminous efficiency is improved.

Note that the combinations of oxides forming the oxide layer 24a and the oxide layer 24b listed in FIG. 6 are merely examples. As long as the oxygen atom density of the oxide layer 24b is less than the oxygen atom density of the oxide layer 24a, the present disclosure is not limited to these combinations.

Note that in the examples of FIG. 6, the oxide layer 24a is formed of only one type of oxide. However, the oxide layer 24a and the oxide layer 24b may each be formed of one type of oxide, or may be formed of a plurality of oxides. That is, the oxide layer 24a may be formed of a composition formed by mixing a plurality of oxides, or as described above, may be formed of a composite oxide or the like containing two or more types of cations of the exemplified oxide. In a similar manner, the oxide layer 24b may be formed of a composition formed by mixing a plurality of oxides, or as described above, may be formed of a composite oxide or the like containing two or more types of cations of the exemplified oxide.

Also, the oxide layer 24b (more precisely, the oxide forming the oxide layer 24b) may include cations contained in the oxide layer 24a (in other words, cations contained in the oxide forming the oxide layer 24a). Also, the oxide layer 24a (more precisely, the oxide forming the oxide layer 24a) may include cations contained in the oxide layer 24b (in other words, cations contained in the oxide forming the oxide layer 24b). In either case, by the oxide layer 24a and the oxide layer 24b including a common cation, a structure that alleviates lattice mismatch between the oxide layer 24a and the oxide layer 24b can be obtained. As a result, defects due to lattice mismatch can be minimized or prevented and the electric dipole 1 having a dipole moment including a component orientated in the direction from the oxide layer 24b to the oxide layer 24a can be more efficiently formed. This allows for more efficient hole injection from the hole transport layer 24c to the light-emitting layer 24d.

Note that the oxide layer 24a (more precisely, the oxide forming the oxide layer 24a) may contain at least one of Ni, Cu, Ti, Zn, Sn, In, W, or Mo, but contained content is preferably small. In the oxide layer 24a, the ratio of the total number density of Ni, Cu, Ti, Zn, Sn, In, W, Mo to the total number density of all cations contained in the oxide layer 24a is preferably less than 50%, more preferably 20% or less, preferably 10% or less, more preferably 4% or less, more preferably 1% or less, more preferably 0.4% or less, and more preferably less than 0.1%. In this case, the carrier density in the oxide layer 24a can be prevented from increasing, so the luminous efficiency is improved. Furthermore, the oxide layer 24a (more precisely, the oxide forming the oxide layer 24a) is further preferably free of any of Ni, Cu, Ti, Zn, Sn, In, W, and Mo.

Also, the oxide layer 24b (more precisely, the oxide forming the oxide layer 24b) may contain at least one of Ni, Cu, Ti, Zn, Sn, In, W, or Mo, but contained content is preferably small. In the oxide layer 24b, the ratio of the total number density of Ni, Cu, Ti, Zn, Sn, In, W, Mo to the total number density of all cations contained in the oxide layer 24b is preferably less than 50%, more preferably 20% or less, preferably 10% or less, more preferably 4% or less, more preferably 1% or less, more preferably 0.4% or less, and more preferably less than 0.1%. In this case, the carrier density in the oxide layer 24b can be prevented from increasing, so the luminous efficiency is improved. Furthermore, the oxide layer 24b (more precisely, the oxide forming the oxide layer 24b) is further preferably free of any of Ni, Cu, Ti, Zn, Sn, In, W, and Mo.

### Modification Example 1

FIG. 7 is an energy band diagram for describing a hole injection barrier in the light-emitting element 5 according to the present modified example.

In the example of (b) of FIG. 3, as described above, regarding the work function and the ionization potential, (i) the work function of the first electrode 22 (the energy difference Ed1 between the vacuum level and the Fermi level E_{F1}′ of the first electrode 22), (ii) the ionization potential IP1 of the hole transport layer 24c, and (iii) the ionization potential IP3 of the oxide layer 24a and the ionization potential IP4 of the oxide layer 24b are smaller in this order.

However, regarding the work function and the ionization potential, it is only required that the work function of the first electrode 22 (=the energy difference Ed1 between the vacuum level and the Fermi level E_{F1} of the first electrode 22) is less than an ionization potential IP1 of the hole transport layer 24c, the ionization potential IP1 of the hole transport layer 24c is less than the ionization potential IP3 of the oxide layer 24a, and the ionization potential IP4 of the oxide layer 24b is less than the ionization potential IP2 of the light-emitting layer 24d. The relationship between ionization potential IP3 of the oxide layer 24a and ionization potential IP4 of the oxide layer 24b varies depending on the material selected. Thus, there is no particular constraint on the relationship between the ionization potential IP3 of the oxide layer 24a and the ionization potential IP4 of the oxide layer 24b. Accordingly, regarding the work function and the ionization potential, as illustrated in FIG. 7, (i) the work function of the first electrode 22 (the energy difference Ed1 between the vacuum level and the Fermi level E_{F1}′ of the first electrode 22), (ii) the ionization potential IP1 of the hole transport layer 24c, (iii) the ionization potential IP3 of the oxide layer 24a, and (iv) the ionization potential IP4 of the oxide layer 24b may be smaller in this order. Also, regarding the work function and the ionization potential, (i) the work function of the first electrode 22 (the energy difference Ed1 between the vacuum level and the Fermi level E_{F1}′ of the first electrode 22), (ii) the ionization potential IP3 of the hole transport layer 24c, (iii) the ionization potential IP4 of the oxide layer 24b, and (iv) the ionization potential IP3 of the oxide layer 24a may be smaller in this order. In either case, the electric dipole 1 can reduce the hole injection barrier height between the first electrode 22 and the hole transport layer 24c from the energy difference ΔE_{F1} to the energy difference ΔE_{F1}′.

### Modification Example 2

FIG. 8 is a cross-sectional view schematically illustrating a schematic configuration of a light-emitting element 5 according to the present modified example.

At least one of the oxide layer 24a or the oxide layer 24b may be formed into island shapes.

In the example illustrated in FIG. 8, of the oxide layer 24a and the oxide layer 24b, the oxide layer 24a that is the lower layer is formed into island shapes. The oxide layer 24a can be formed into island shapes using spontaneous nucleation using a sputtering method, a CVD method, or the like. Furthermore, after forming the thin film, the thin film may be processed into island shapes by etching or the like.

In the example illustrated in FIG. 8, because the oxide layer 24a is formed into a plurality of island shapes, the area of the interface between the oxide layer 24a and the oxide layer 24b is increased. Thus, in this case as well, the electric dipole 1 can be formed more efficiently, and thus efficient hole injection from the first electrode 22 to the hole transport layer 24c is possible in the light-emitting element 5. As a result, efficient hole injection to the light-emitting layer 24d is possible.

Note that in the example illustrated in FIG. 8, the first electrode 22, which is the lower layer, is formed from a light-reflective material, and the second electrode 25, which is the upper layer, is formed from a light-transmissive material. In this manner, a top-emitting display device including the light-emitting element 5 can be realized. Note that in the display device including the light-emitting element 5, the second electrode 25 is formed as a solid-like common layer, and the first electrode 22 electrically connected to the thin film transistor element Tr (TFT element) is formed for each subpixel.

Also, in the example illustrated in FIG. 8, the first electrode 22, which is the lower layer, may be formed from a light-transmissive material, and the second electrode 25, which is the upper layer, may be formed from a light-reflective material. In this manner, a bottom-emitting display device including the light-emitting element 5 can be realized.

### Modification Example 3

FIG. 9 is a cross-sectional view schematically illustrating a schematic configuration of a light-emitting element 5 according to the present modified example.

In Modification Example 2, the first electrode 22 is positioned below the light-emitting layer 24d, and the second electrode 25 is positioned above the light-emitting layer 24d. However, as described above, the layering order of the layers in the light-emitting element 5 may be reversed. In the example illustrated in FIG. 9, the first electrode 22 is positioned above the light-emitting layer 24d, and the second electrode 25 is positioned below the light-emitting layer 24d. In the present modified example, of the oxide layer 24a and the oxide layer 24b, the oxide layer 24b that is the lower layer is formed into island shapes. The oxide layer 24b can be formed into island shapes using spontaneous nucleation using a sputtering method, a CVD method, or the like. Furthermore, after forming the thin film, the thin film may be processed into island shapes by etching or the like.

In the example illustrated in FIG. 9, because the oxide layer 24b is formed into a plurality of island shapes, the area of the interface between the oxide layer 24a and the oxide layer 24b is increased. Thus, in this case, the electric dipole 1 can be formed more efficiently, and thus efficient hole injection to the light-emitting layer 24d in the light-emitting element 5 is possible.

Note that in the example illustrated in FIG. 9, the first electrode 22, which is the upper layer, is formed from a light-reflective material, and the second electrode 25, which is the lower layer, is formed from a light-transmissive material. In this manner, a bottom-emitting display device including the light-emitting element 5 can be realized. Note that in the display device including the light-emitting element 5, the first electrode 22 is formed as a solid-like common layer, and the second electrode 25 electrically connected to the thin film transistor element Tr (TFT element) is formed for each subpixel.

Also, in the example illustrated in FIG. 9, the first electrode 22, which is the upper layer, may be formed from a light-transmissive material, and the second electrode 25, which is the lower layer, may be formed from a light-reflective material. In this manner, a top-emitting display device including the light-emitting element 5 can be realized.

### Second Embodiment

FIG. 10 is an energy band diagram for describing a hole injection barrier between the first electrode 22 (anode) and the hole transport layer 24c in a light-emitting element 55 according to the present embodiment.

A light-emitting device according to the present embodiment includes the light-emitting element 55 illustrated in FIG. 10 as a light-emitting element in the light-emitting device (for example, the display device 2) according to the first embodiment. The light-emitting element 55 according to the present embodiment has the same configuration as the light-emitting element 5 according to the first embodiment except that the hole transport layer 24c is formed of an oxide.

In the example described below, the light-emitting element 55 has the same layered structure as the layered structure illustrated in FIG. 2. As illustrated in FIG. 10, the oxide layer 24a and the oxide layer 24b are layered in this order from the first electrode 22 side between the first electrode 22 and the hole transport layer 24c. Note that the oxide layer 24a, the oxide layer 24b, and the hole transport layer 24c are layered in this order and in contact with each other. As described above, the oxygen atom density of the oxide layer 24a and the oxygen atom density of the oxide layer 24b are different. Additionally, the density of the oxygen atoms in the hole transport layer 24c (also referred to as the “oxygen atom density of the hole transport layer 24c” below) is different from the oxygen atom density of the oxide layer 24b adjacent to the hole transport layer 24c. In this case, oxygen atom movement occurs not only at the interface between the oxide layer 24a and the oxide layer 24b, but also at the interface between the hole transport layer 24c and the oxide layer 24b, and the electric dipole is easily formed.

In the present embodiment, the oxygen atom density of the hole transport layer 24c is preferably less than the oxygen atom density of the oxide layer 24b. In this case, the aforementioned energy difference ΔE_{F1}′ becomes even smaller, and more efficient hole injection from the first electrode 22 to the hole transport layer 24c is possible. As a result, more efficient hole injection to the light-emitting layer 24d is possible. In the present embodiment described below, the oxygen atom density of the hole transport layer 24c is less than the oxygen atom density of the oxide layer 24b, and the oxygen atom density of the oxide layer 24b is less than the oxygen atom density of the oxide layer 24a. In this case, as in the first embodiment, oxygen atoms easily move at the interface between the oxide layer 24a and the oxide layer 24b from the oxide layer 24a toward the oxide layer 24b. Also, oxygen atoms easily move at the interface between the oxide layer 24b and the hole transport layer 24c from the oxide layer 24b toward the hole transport layer 24c. Accordingly, as illustrated in FIG. 10, as in the first embodiment, at the interface between the oxide layer 24a and the oxide layer 24b, the electric dipole 1 having a dipole moment including a component orientated in the direction from the oxide layer 24b to the oxide layer 24a is formed. Also, at the interface between the oxide layer 24b and the hole transport layer 24c, an electric dipole 31 having a dipole moment including a component orientated in the direction from the hole transport layer 24c to the oxide layer 24b is formed.

Note that in the light-emitting element 55 of the present embodiment, the mechanism by which the oxygen atoms move at the interface between the oxide layer 24b and the hole transport layer 24c adjacent to one another is the same as the mechanism by which the oxygen atoms move at the interface between the oxide layer 24a and the oxide layer 24b as illustrated in (a) of FIG. 4. Thus, in (a) and (b) of FIG. 4, “24a”, “24b”, and “1” can, in this order, be read as “24b”, “24c”, and “31”.

When the electric dipoles 1 and 31 are formed in this manner, as illustrated in FIG. 10, a vacuum level shift caused by the electric dipole 1 and the electric dipole 31 occurs at the interface between the oxide layer 24a and the oxide layer 24b, which is the interface where the electric dipole 1 is formed, and at the interface between the oxide layer 24b and the hole transport layer 24c, which is the interface where the electric dipole 31 is formed. As a result, as illustrated in FIG. 10, at the interface between the hole transport layer 24c and the oxide layer 24b, the position of the band on the first electrode 22 side moves downward with respect to the position of the band on the second electrode 25 side, and at the interface between the oxide layer 24b and the oxide layer 24a, the position of the band on the first electrode 22 side moves downward with respect to the position of the band on the second electrode 25 side. In other words, in the example illustrated in FIG. 10, the position of the band of the oxide layer 24b moves downward (band shift) with respect to the position of the band of the hole transport layer 24c and the position of the band of the light-emitting layer 24d. Also, the position of the band of the first electrode 22 and the position of the band of the oxide layer 24a move further downward (band shift) with respect to the position of the band of the oxide layer 24b, the position of the band of the hole transport layer 24c, and the position of the band of the light-emitting layer 24d. Although not illustrated, at this time, obviously the position of the band on the second electrode 25 side includes the position of the band of the layer on the second electrode 25 side of the light-emitting layer 24d. Note that in FIG. 10, the position of the band of the Fermi level E_{F1} of the first electrode 22 before the vacuum level shift due to the electric dipoles 1 and 31 is indicated by a dot-dash line, and the position of the bands of the oxide layer 24a and the oxide layer 24b before the vacuum level shift due to the electric dipoles 1 and 31 is indicated by a two-dot chain line. Also, the vacuum level after the vacuum level shift due to the electric dipoles 1 and 31 is indicated by a dotted line.

Specifically, when the electric dipoles 1 and 31 are formed, the Fermi level E_{F1} of the first electrode 22 moves to the Fermi level E_{F1}′ of the first electrode 22, the valence band of the oxide layer 24a moves to the valence band′ of the oxide layer 24a, and the valence band of the oxide layer 24b moves to the valence band′ of the oxide layer 24b. Also, the conduction band of the oxide layer 24a moves to the conduction band′ of the oxide layer 24a, and the conduction band of the oxide layer 24b moves to the conduction band′ of the oxide layer 24b. By this movement, the energy difference ΔE_{F1} between the Fermi level E_{F1} of the first electrode 22 and the upper end of the HTL valence band becomes the energy difference ΔE_{F1}′ between the Fermi level E_{F1}′ of the first electrode 22 and the upper end of the HTL valence band. As a result, the energy difference ΔE_{F1}′ after formation of the electric dipoles 1 and 31 (in other words, the hole injection barrier height from the first electrode 22 to the hole transport layer 24c after formation of the electric dipoles 1 and 31) is less than the energy difference ΔE_{F1} (in other words, the hole injection barrier height from the first electrode 22 to the hole transport layer 24c in a case where the material of the hole transport layer 24c is not an oxide or the oxide layer 24a and the oxide layer 24b are not formed).

In a similar manner to the light-emitting element 5 of the first embodiment, in a case where the film thickness of the oxide layer 24a and the oxide layer 24b is sufficiently thin in the light-emitting element 55, because the holes have conductivity via tunneling of the oxide layer 24a and oxide layer 24b, the hole injection barrier height between the first electrode 22 and the hole transport layer 24c is effectively the energy difference ΔE_{F1}′ between the Fermi level E_{F1}′ of the first electrode 22 and the upper end of the HTL valence band.

According to the present embodiment, by forming the hole transport layer 24c, the oxide layer 24a, and the oxide layer 24b as described above, at the two interfaces, i.e., the interface between the oxide layer 24a and the oxide layer 24b and the interface between the oxide layer 24b and the hole transport layer 24c, the dipole moments 1, 31 having a dipole moment including a component orientated in the direction from the hole transport layer 24c to the oxide layer 24a are formed. Thus, according to the present embodiment, compared to the first embodiment, the position of the bands of the first electrode 22, the oxide layer 24a, and the oxide layer 24b move further downward with respect to the position of the band of the hole transport layer 24c. By this movement, the energy difference ΔE_{F1}′ between the Fermi level E_{F1}′ of the first electrode 22 and the upper end of the HTL valence band is made even smaller than in the first embodiment. Thus, according to the present embodiment, hole injection that is more efficient than in the first embodiment is possible.

Note that in the present disclosure, the energy difference ΔE_{F1}′ indicates “the energy difference between the Fermi level of the first electrode 22 and the upper end of the valence band of the hole transport layer 24c after electric dipole formation”. Thus, in the present embodiment, “after electric dipole formation” refers to “after formation of the electric dipoles 1 and 31”, and the energy difference ΔE_{F1}′ refers to the energy difference between the Fermi level E_{F1}′ of the first electrode 22 and the upper end of the HTL valence band after formation of the electric dipoles 1 and 31” as described above. Also, “before electric dipole formation” refers to “before the formation of the electric dipoles 1 and 31” (in other words, a state in which there is no vacuum level shift).

In a similar manner, in the present disclosure, the energy difference ΔE_{F1} indicates “the energy difference between the Fermi level of the first electrode 22 (in other words, the Fermi level E_{F1} of the first electrode 22) and the upper end of the valence band of the hole transport layer 24c (in other words, the upper end of the HTL valence band) after electric dipole formation (in other words, in a state where there is no vacuum level shift)”. Note that in the present embodiment, “before electric dipole formation” refers to “before forming the electric dipoles 1 and 31”.

FIG. 11 is a diagram listing the oxygen atom density of inorganic oxides which are examples of the oxide for forming the hole transport layer 24c.

For the oxide forming the hole transport layer 24c, for example, an inorganic oxide having an oxygen atom density less than the oxygen atom density of the oxide layer 24b may selected from the inorganic oxides listed in FIG. 11, and the inorganic oxide may be used as the oxide for forming the hole transport layer 24c. Furthermore, after selecting the oxide for forming the hole transport layer 24c from the inorganic oxides listing in FIG. 11, a combination of inorganic oxides having an oxygen atom density greater than the oxygen atom density of the hole transport layer 24c may be selected from the inorganic oxides listed in FIG. 5 or FIG. 6 and combinations thereof to form the oxide layer 24a and the oxide layer 24b.

As the oxide forming the hole transport layer 24c, a composite oxide containing multiple cations of the oxides listed in FIG. 11 can be used, for example. Also, the hole transport layer 24c may be formed from an oxide containing at least one of Ni or Cu. In addition, the hole transport layer 24c may include an oxide in which the most abundant elements other than oxygen are one of Ni or Cu.

Also in the present embodiment, by the oxygen atom density of the oxide layer 24b being less than the oxygen atom density of the oxide layer 24a, the electric dipole 1 having a dipole moment including a component oriented in the direction of the oxide layer 24a from the oxide layer 24b is more easily formed, and the efficiency of hole injection can be improved. Also, according to the present embodiment, by the oxygen atom density of the hole transport layer 24c being less than the oxygen atom density of the oxide layer 24b adjacent to the hole transport layer 24c, the electric dipole 31 having a dipole moment including a component oriented in the direction of the oxide layer 24b from the hole transport layer 24c is more easily formed, and the efficiency of hole injection from the first electrode 22 to the hole transport layer 24c can be further improved.

Note that in a case where the hole transport layer 24c is formed of an oxide as described above, the oxygen atom density of the hole transport layer 24c is preferably 95% or less, more preferably 90% or less, even more preferably 85% or less, even more preferably 80% or less, even more preferably 75% or less, and even more preferably 70% or less of the oxygen atom density of the oxide layer 24b. Also, as in the first embodiment, the oxygen atom density of the oxide layer 24b is preferably 95% or less, preferably 90% or less, even more preferably 85% or less, even more preferably 80% or less, even more preferably 75% or less, and even more preferably 70% or less of the oxygen atom density of the oxide layer 24a. In this case, the energy difference ΔE_{F1}′ becomes even smaller, and more efficient hole injection is possible. At this time, the smaller the oxygen atom density of the hole transport layer 24c relative to the oxygen atom density of the oxide layer 24b, the more easily the oxygen atoms can move from the oxide layer 24b toward the hole transport layer 24c, and the electric dipole 31 having a dipole moment including a component orientated in the direction from the hole transport layer 24c to the oxide layer 24b is more efficiently formed. Also, the smaller the oxygen atom density of the oxide layer 24b relative to the oxygen atom density of the oxide layer 24a, the more easily the oxygen atoms can move from the oxide layer 24a toward the oxide layer 24b, and the electric dipole 1 having a dipole moment including a component orientated in the direction from the oxide layer 24b to the oxide layer 24a is more efficiently formed. Thus, more efficient hole injection from the first electrode 22 to the hole transport layer 24c is possible. As a result, more efficient hole injection to the light-emitting layer 24d is possible.

Also, the oxygen atom density of the oxide layer 24b is preferably 50% or less of the oxygen atom density of the oxide layer 24a. In this case, it is possible to suppress the formation of recombination centers due to dangling bonds and the like at the interface between the oxide layer 24a and the oxide layer 24b.

Also, the oxygen atom density of the hole transport layer 24c is preferably 50% or less of the oxygen atom density of the oxide layer 24b. In this case, it is possible to suppress the formation of recombination centers due to dangling bonds and the like at the interface between the oxide layer 24b and the hole transport layer 24c.

As a result, more efficient hole injection from the first electrode 22 to the hole transport layer 24c is possible. Note that the oxygen atom density in the present disclosure is a unique value for hole transport layer 24c and applies to the oxygen atom bulk density of the material forming the hole transport layer 24c.

FIG. 12 is a diagram listing examples of combinations of oxides forming the hole transport layer 24c and oxides forming the oxide layer 24b adjacent to the hole transport layer 24c.

In the combinations listed in FIG. 12, the oxygen atom density of the hole transport layer 24c is less than the oxygen atom density of the oxide layer 24b. Thus, the electric dipole 31 having a dipole moment including a component orientated in the direction from the hole transport layer 24c to the oxide layer 24b is formed at the interface between the hole transport layer 24c and the oxide layer 24b as illustrated in FIG. 10. As a result, efficient hole injection from the first electrode 22 to the hole transport layer 24c is possible, thus improving the luminous efficiency.

Note that the combinations of oxides forming the hole transport layer 24c and the oxide layer 24b listed in FIG. 12 are merely examples. In the present embodiment, as long as the oxygen atom density of the hole transport layer 24c is less than the oxygen atom density of the oxide layer 24b, the present disclosure is not limited to these combinations.

Note that in the examples of FIG. 12, the hole transport layer 24c is formed of one or two types of oxides. However, the oxide layer 24a, the oxide layer 24b, and the hole transport layer 24c may each be formed of one type of oxide, or may be formed of a plurality of oxides. That is, in a similar manner to the oxide layer 24a and the oxide layer 24b, the hole transport layer 24c may be formed of a composition formed by mixing a plurality of oxides, or as described above, may be formed of a composite oxide or the like containing two or more types of cations of the exemplified oxide.

Also, the oxide layer 24b (more precisely, the oxide forming the oxide layer 24b) may include cations contained in the hole transport layer 24c (in other words, cations contained in the oxide forming the hole transport layer 24c), but the contained content is preferably small. In a case where the oxide layer 24b contains “cations contained in the hole transport layer 24c”, the ratio of the number density of the “cations contained in the hole transport layer 24c” contained in the oxide layer 24b to all of the cations contained in the oxide layer 24b is preferably less than 50%, more preferably 20% or less, more preferably 10% or less, more preferably 4% or less, more preferably 1% or less, more preferably 0.4% or less, and more preferably less than 0.1%. In this case, because the “cations contained in the hole transport layer 24c” are contained in the oxide layer 24b, it is possible to suppress an increase in the hole density in the oxide layer 24b. Furthermore, the oxide layer 24b (more precisely, the oxide forming the oxide layer 24b) is more preferably free of “cations contained in the hole transport layer 24c”.

Also, the hole transport layer 24c (more precisely, the oxide forming the hole transport layer 24c) may include cations contained in the oxide layer 24b (in other words, cations contained in the oxide forming the oxide layer 24b), but the contained content is preferably small. In a case where the hole transport layer 24c contains “cations contained in the oxide layer 24b”, the ratio of the number density of the “cations contained in the oxide layer 24b” contained in the hole transport layer 24c to all of the cations contained in the hole transport layer 24c is preferably less than 50%, more preferably 20% or less, more preferably 10% or less, more preferably 4% or less, more preferably 1% or less, more preferably 0.4% or less, and more preferably less than 0.1%. In this case, because the “cations contained in the oxide layer 24b” are contained in the hole transport layer 24c, it is possible to suppress a decrease in the hole mobility in the hole transport layer 24c. Furthermore, the hole transport layer 24c (more precisely, the oxide forming the hole transport layer 24c) is more preferably free of “cations contained in the oxide layer 24b”.

Note that the oxide layer 24a (more precisely, the oxide forming the oxide layer 24a) may contain at least one of Ni, Cu, Ti, Zn, Sn, In, W, or Mo, but contained content is preferably small. In the oxide layer 24a, the ratio of the total number density of Ni, Cu, Ti, Zn, Sn, In, W, Mo to the total number density of all cations contained in the oxide layer 24a is preferably less than 50%, more preferably 20% or less, preferably 10% or less, more preferably 4% or less, more preferably 1% or less, more preferably 0.4% or less, and more preferably less than 0.1%. In this case, the carrier density in the oxide layer 24a can be prevented from increasing, so the luminous efficiency is improved. Furthermore, the oxide layer 24a (more precisely, the oxide forming the oxide layer 24a) is further preferably free of any of Ni, Cu, Ti, Zn, Sn, In, W, and Mo.

Also, the oxide layer 24b (more precisely, the oxide forming the oxide layer 24b) may contain at least one of Ni, Cu, Ti, Zn, Sn, In, W, or Mo, but contained content is preferably small. In the oxide layer 24b, the ratio of the total number density of Ni, Cu, Ti, Zn, Sn, In, W, Mo to the total number density of all cations contained in the oxide layer 24b is preferably less than 50%, more preferably 20% or less, preferably 10% or less, more preferably 4% or less, more preferably 1% or less, more preferably 0.4% or less, and more preferably less than 0.1%. In this case, the carrier density in the oxide layer 24b can be prevented from increasing, so the luminous efficiency is improved. Furthermore, the oxide layer 24b (more precisely, the oxide forming the oxide layer 24b) is further preferably free of any of Ni, Cu, Ti, Zn, Sn, In, W, and Mo.

Note that in a case where the hole transport layer 24c is formed of an oxide as described above, the hole transport layer 24c may be formed of an amorphous oxide or may be formed with at least a portion of the contact surface with oxide layer 24b formed of a polycrystalline oxide. In other words, in the latter case, only the contact surface of the hole transport layer 24c with the oxide layer 24b may be polycrystalline, or the entire hole transport layer 24c may be formed of a polycrystalline oxide.

Also, as described in the first embodiment, the oxide layer 24b may be formed of an amorphous oxide or may be formed with at least a portion of the contact surface with hole transport layer 24c formed of a polycrystalline oxide. Also, the oxide layer 24a may also be formed of an amorphous oxide or may be formed with at least a portion of the contact surface with oxide layer 24b formed of a polycrystalline oxide.

As long as the oxygen atom density of the oxide layer 24b is less than the oxygen atom density of the oxide layer 24a and the oxygen atom density of the hole transport layer 24c is less than the oxygen atom density of the oxide layer 24b, the method of making the oxide layer 24a, the oxide layer 24b, and the hole transport layer 24c polycrystalline is not particularly limited. Also, as long as the oxygen atom density of the oxide layer 24b is less than the oxygen atom density of the oxide layer 24a and the oxygen atom density of the hole transport layer 24c is less than the oxygen atom density of the oxide layer 24b, the type of polycrystalline oxide forming the oxide layer 24a the oxide layer 24b, and the hole transport layer 24c is not particularly limited. Note that also for the present embodiment, an example of the above-described method for polycrystallization includes a heat treatment using laser light.

According to the present embodiment, by forming the oxide layer 24a, the oxide layer 24b, and the hole transport layer 24c of an amorphous oxide, the film thickness uniformity of the oxide layer 24a, the oxide layer 24b, and the hole transport layer 24c can be improved, and the flatness of each surface can be improved. In this case, the electric dipole 1 is easily formed uniformly over the entire interface between the oxide layer 24a and the oxide layer 24b. Also, the electric dipole 31 is easily formed uniformly over the entire interface between the oxide layer 24b and the hole transport layer 24c. Thus, an increase in the efficiency of hole conduction by tunneling can be achieved, and more efficient hole injection from the first electrode 22 to the hole transport layer 24c is possible in the light-emitting element 55. As a result, more efficient hole injection to the light-emitting layer 24d is possible.

Also, in a case where the oxide layer 24a and the oxide layer 24b are each formed of an amorphous oxide and at least a portion of the contact surface of the hole transport layer 24c with the oxide layer 24b is formed of a polycrystalline oxide, because the film thickness uniformity of the oxide layer 24a and the oxide layer 24b can be improved, in-plane density variations of the electric dipole 31 can be suppressed. In addition, in this case, at least a portion of the contact surface of the hole transport layer 24c with the oxide layer 24b includes grains. Thus, the oxide layer 24b being formed of an amorphous oxide can result in good coverage with respect to the hole transport layer 24c including grains. Thus, the contact area between the oxide layer 24b and the hole transport layer 24c is increased, and the electric dipole 31 can be formed more efficiently. In this manner, at the contact surface between the hole transport layer 24c and the oxide layer 24b, at least one of the hole transport layer 24c or the oxide layer 24b includes grains, and thus the area of the interface between the hole transport layer 24c and the oxide layer 24b is increased. Accordingly, the electric dipole 31 can be formed more efficiently, allowing for efficient hole injection in the light-emitting element 55.

Note that in a case where the contact surface of the oxide layer 24b with the hole transport layer 24c includes grains, the surface roughness of the oxide layer 24b is also reflected in the contact surface (interface) between the oxide layer 24b and the hole transport layer 24c. Also, in a case where the contact surface of the oxide layer 24a with the oxide layer 24b includes grains, the surface roughness of the oxide layer 24a is also reflected in the contact surface (interface) between the oxide layer 24a and the oxide layer 24b and the contact surface (interface) between the oxide layer 24b and the hole transport layer 24c. Thus, in a case where at least a portion of the upper surface of at least one of the oxide layer 24a or the oxide layer 24b, from among the oxide layer 24a, the oxide layer 24b, and hole transport layer 24c, includes grains, from among the area of the interface between the oxide layer 24a and the oxide layer 24b and the area of the interface between the oxide layer 24b and the hole transport layer 24c, at least the area of the interface between the oxide layer 24b and the hole transport layer 24c is increased.

Thus, in this case, from among the electric dipoles 1 and 31, at least the electric dipole 31 can be formed more efficiently, and thus more efficient hole injection to the light-emitting layer 24d in the light-emitting element 55 is possible.

Note that in the present embodiment also, grains may be formed by polycrystallizing at least one of the contact surfaces adjacent to one another from among the layers described above, and grains may be formed in at least a portion of at least one of the contact surfaces adjacent to one another by spontaneous nucleation using a sputtering method, a CVD method, or the like. Note that, obviously, grains may be included in all of the at least one of the contact surfaces adjacent to one another from among the layers described above.

Also, at the contact surface, grains may be distributed discretely. Grains may also be crystal grains containing crystals or may include an amorphous phase.

### Third Embodiment

FIG. 13 is a cross-sectional view schematically illustrating a schematic configuration of a light-emitting element 155 according to the present embodiment.

A light-emitting device according to the present embodiment includes the light-emitting element 155 illustrated in FIG. 13 as a light-emitting element in the light-emitting device (for example, the display device 2) according to the first embodiment.

As illustrated in FIG. 13, the light-emitting element 155 of the present embodiment includes a first electrode (hole injection layer: HIL) 22, a second electrode (electron injection layer: EIL) 25, and a light-emitting layer 24d provided between the first electrode 22 and the second electrode 25. A hole transport layer (HTL) 24a is provided between the first electrode 22 and the light-emitting layer 24d. An electron transport layer (ETL) 24e, an oxide layer 124a (first oxide layer), and an oxide layer 124b (second oxide layer) are layered adjacent to one another in this order, for example, from the light-emitting layer 24d side between the light-emitting layer 24d and the second electrode 25. Note that the density of the oxygen atoms in the oxide layer 124a and the density of the oxygen atoms in the oxide layer 124b are different.

Accordingly, the light-emitting element 155 includes, for example, the first electrode 22 (anode), the hole transport layer 24c, the light-emitting layer 24d, the electron transport layer 24e, and the second electrode 25 (cathode) from the lower layer side in this order and includes the oxide layer 124a and the oxide layer 124b in contact with the oxide layer 124a between the electron transport layer 24e and the second electrode 25 in this order from the first electrode 22 side.

Note that the layering order from the first electrode 22 to the second electrode 25 may be reversed. In addition, the first electrode 22 (the second electrode 25 in a case where the layering order is reversed), the hole transport layer 24c, the light-emitting layer 24d, the electron transport layer 24e, the oxide layer 124a, and the oxide layer 124b may be formed into island shapes for each subpixel SP, with the second electrode 25 (the first electrode 22 in a case where the layering order is reversed) formed as a solid-like common layer. In addition, instead of the configuration described above, the first electrode 22 (the second electrode 25 in a case where the layering order is reversed) and the light-emitting layer 24d are formed into island shapes for each subpixel SP, and except these, at least one of the hole transport layer 24c, the electron transport layer 24e, the oxide layer 124a, the oxide layer 124b, and the second electrode 25 (the first electrode 22 in a case where the layering order is reversed) may be formed as a solid-like common layer.

Note that the hole transport layer 24c and the electron transport layer 24e are as described in the first embodiment. As described above, the electron transport material may be an oxide or a material other than an oxide. Accordingly, the electron transport layer 24e may or may not contain an oxygen atom within the electron transport layer 24e. In a case where the electron transport material is an oxide (in other words, when the electron transport layer 24e is formed from an oxide), the density of the oxygen atoms in the electron transport layer 24e (also referred to as “the oxygen atom density of the electron transport layer 24e” below) is preferably less than the oxygen atom density of the oxide layer 124a, as illustrated in the fourth embodiment described below. However, the oxygen atom density of the electron transport layer 24e may be the same as the oxygen atom density of the oxide layer 124a. Also, the oxygen atom density of the electron transport layer 24e may be greater than the oxygen atom density of the oxide layer 124a.

Because the oxide layer 124a and the oxide layer 124b are provided separately from the electron transport layer 24e, the electric dipole can be freely formed without reducing the flexibility in the selection of the material of the electron transport layer 24e. Accordingly, the amount of electron injection to the light-emitting layer 24d can be freely controlled.

The oxide layer 124a and the oxide layer 124b are formed of inorganic oxide, for example, similar to the oxide layer 24a and the oxide layer 24b of the first embodiment. Additionally, the oxide layer 124a and the oxide layer 124b are preferably formed of an inorganic insulator. A material similar to that used for the oxide layer 24a described in the first embodiment can be used for the oxide layer 124a. Also, a material similar to that used for the oxide layer 24b described in the first embodiment can be used for the oxide layer 124b.

In the present embodiment also, the density of the oxygen atoms in the oxide layer 124b, which is the oxide layer (second oxide layer) farther from the first electrode 22 of the oxide layer 124a and the oxide layer 124b adjacent to one another provided between the carrier transport layer (the electron transport layer 24e in the present embodiment) and the light-emitting layer 24d, is preferably less than the density of the oxygen atoms in the oxide layer 124a, which is the oxide layer (first oxide layer) closer to the first electrode 22. Note that the density of the oxygen atoms in the oxide layer 124b may be referred to as the “oxygen atom density of the oxide layer 124b”. Also, the density of the oxygen atoms in the oxide layer 124a may be referred to as the “oxygen atom density of the oxide layer 124a”.

As described above, in the present embodiment, the oxygen atom density of the oxide layer 124b is less than the oxygen atom density of the oxide layer 124a. Thus, when the oxide layer 124a is formed above the oxide layer 124b in contact with the oxide layer 124b, oxygen atoms easily move at the interface between the oxide layer 124a and the oxide layer 124b from the oxide layer 124a toward the oxide layer 124b. As oxygen atoms move, the oxygen holes become positively charged and the moving oxygen atoms become negatively charged.

In other words, in the light-emitting element 155 of the present embodiment, the mechanism by which the oxygen atoms move at the interface between the oxide layer 124a on the first electrode 22 side and the oxide layer 124b on the second electrode 25 side adjacent to one another is the same as the mechanism by which the oxygen atoms move at the interface between the oxide layer 24a on the first electrode 22 side and the oxide layer 24b on the second electrode 25 side as illustrated in (a) of FIG. 4. Accordingly, at the interface between the oxide layer 124a and the oxide layer 124b, the electric dipole (referred to as ‘electric dipole 1′’ below) having a dipole moment including a component orientated in the direction from the oxide layer 124b to the oxide layer 124a is formed. Thus, in (a) and (b) of FIG. 4, “24a”, “24b”, and “1” can, in this order, be read as “124a”, “124b”, and “1′”.

(a) of FIG. 14 is an energy band diagram for describing an electron injection barrier between the second electrode 25 (cathode) and the electron transport layer 24e in the light-emitting element according to a comparative example. (b) of FIG. 14 is an energy band diagram for describing an electron injection barrier between the second electrode 25 (cathode) and the electron transport layer 24e in the light-emitting element 155.

As illustrated in (a) of FIG. 14, an energy difference ΔE_{F2} between the lower end of the conduction band (ETL conduction band) of the electron transport layer 24e and the Fermi level E_{F2} of the second electrode 25 in the light-emitting element according to the comparative example directly in contact with the second electrode 25 and the electron transport layer 24e is large. Because the energy difference ΔE_{F2} is the height of the electron injection barrier from the second electrode 25 to the electron transport layer 24e, efficient electron injection from the second electrode 25 to the electron transport layer 24e cannot be achieved in the light-emitting element illustrated in (a) of FIG. 14. Thus, efficient electron injection to the light-emitting layer 24d cannot be achieved.

On the other hand, as illustrated in (b) of FIG. 14, the light-emitting element 155 according to the present embodiment includes, between the second electrode 25 and the electron transport layer 24e, the oxide layer 124a and the oxide layer 124b layered adjacent to one another in this order from the electron transport layer 24e side, and as described above, the oxygen atom density of the oxide layer 124b is less than the oxygen atom density of the oxide layer 124a. Thus, the oxygen atoms can easily move from the oxide layer 124a toward the oxide layer 124b at the interface between the oxide layer 124a and the oxide layer 124b, and, at the interface, the electric dipole 1′ having a dipole moment including a component orientated in the direction from the oxide layer 124b to the oxide layer 124a is formed.

When the electric dipole 1′ is formed in this manner, as illustrated in (b) of FIG. 14, a vacuum level shift caused by the electric dipole 1′ occurs at the interface between the oxide layer 124a and the oxide layer 124b, which is the interface where the electric dipole 1′ is formed. As a result, as illustrated in (b) of FIG. 14, at the interface between the oxide layer 124a and the oxide layer 124b, the position of the band on the second electrode 25 side moves upward with respect to the position of the band on the first electrode 22 side. In other words, in the example illustrated in (b) of FIG. 14, the position of the band of the second electrode 25 and the position of the band of the oxide layer 124b move downward (band shift) with respect to the position of the band of the oxide layer 124a, the position of the band of the hole transport layer 24c and the position of the band of the light-emitting layer 24d. Although not illustrated, at this time, obviously the position of the band on the first electrode 22 side includes the position of the band of the layer on the first electrode 22 side of the light-emitting layer 24d. Note that in (b) of FIG. 14, the position of the Fermi level E_{F2} of the second electrode 25 before the vacuum level shift due to the electric dipole 1′ is indicated by a dot-dash line, and the position of the band of the oxide layer 124b before the vacuum level shift due to the electric dipole 1′ is indicated by a two-dot chain line. Also, the vacuum level after the vacuum level shift due to the electric dipole 1′ is indicated by a dotted line.

Specifically, when the electric dipole 1′ is formed, the Fermi level E_{F2} of the second electrode 25 moves to the Fermi level E_{F2}′ of the second electrode 25, the valence band of the oxide layer 124b moves to the valence band′ of the oxide layer 124b, and the conduction band of the oxide layer 124b moves to the conduction band′ of the oxide layer 124b. By this movement, the energy difference ΔE_{F2} between the lower end of the conduction band (lower end of the ETL conduction band) of the electron transport layer 24e and the Fermi level E_{F2} of the second electrode 25 becomes the energy difference ΔE_{F2}′ between the lower end of the conduction band (lower end of the ETL conduction band) of the electron transport layer 24e and the Fermi level E_{F2}′ of the second electrode 25. As a result, the energy difference ΔE_{F2}′ after formation of the electric dipole 1′ (in other words, the electron injection barrier height from the second electrode 25 to the electron transport layer 24e after formation of the electric dipole 1′) is less than the energy difference ΔE_{F2} (in other words, the electron injection barrier height from the second electrode 25 to the electron transport layer 24e in a case where the oxide layer 124a and the oxide layer 124b are not formed).

In a case where the film thickness of the oxide layer 124a and the oxide layer 124b is sufficiently thin in the light-emitting element 155, because the electrons have conductivity via tunneling of the oxide layer 124a and oxide layer 124b, the electron injection barrier height between the second electrode 25 and the electron transport layer 24e is effectively the energy difference ΔE_{F2}′ between the lower end of the conduction band (lower end of the ETL conduction band) of the electron transport layer 24e and the Fermi level E_{F1}′ of the second electrode 25. According to the present embodiment, by forming the oxide layer 124a and the oxide layer 124b in this manner, efficient electron injection from the second electrode 25 to the electron transport layer 24e can be achieved. As a result, efficient electron injection from the second electrode 25 to the light-emitting layer 24d (via the electron transport layer 24e) is possible, and the luminous efficiency can be improved.

Note that in (b) of FIG. 14, an example is given of a case in which the position (position of the lower end of the conduction band and the upper end of the valence band) of the band of the oxide layer 124b and the position (position of the lower end of the conduction band and the upper end of the valence band) of the band of the oxide layer 124a before the vacuum level shift is caused by the electric dipole 1, indicated by the two-dot chain line, are the same. However, the position of the bands of oxide layer 124a and oxide layer 124b are determined by the material selected for the oxide layer 124a and oxide layer 124b, and thus the positions are not limited to those in example illustrated in (b) of FIG. 14. In the example illustrated in (b) of FIG. 14, an example is given of a case in which the Fermi level E_{F2}′ of the second electrode 25 after a band shift has been caused by formation of the electric dipole 1′ is positioned below the lower end of the ETL conduction band. However, the Fermi level E_{F2}′ of the second electrode 25 after the band shift may be positioned above the lower end of the ETL conduction band and is more preferably positioned above.

Note that in the present disclosure, the energy difference ΔE_{F2}′ indicates the “energy difference between the lower end of the conduction band of the electron transport layer 24e and the Fermi level of the second electrode 25 after electric dipole formation”. Thus, in the present embodiment, “after electric dipole formation” refers to “after formation of the electric dipole 1”, and “the energy difference between the lower end of the conduction band of the electron transport layer 24e and the Fermi level of the second electrode 25 after electric dipole formation” refers to “the energy difference between the lower end of the ETL conduction band and the Fermi level E_{F2}′ of the second electrode 25 after formation of the electric dipole 1′” as described above. Also in the present disclosure, the reference sign of the energy difference ΔE_{F2}′ is positive (ΔE_{F2}′>0) in a case where, after electric dipole formation, the lower end of the conduction band (the lower end of the ETL conduction band in the present embodiment) of the electron transport layer 24e is on a higher energy side (on the upper side in the band diagram) than the Fermi level of the second electrode 25 (the Fermi level E_{F2}′ of the second electrode 25 in the present embodiment), and is negative (ΔE_{F2}′<0) in a case where, after electric dipole formation, the lower end of the conduction band (the lower end of the ETL conduction band in the present embodiment) of the electron transport layer 24e is on a lower energy side (on the lower side in the band diagram) than the Fermi level of the second electrode 25 (the Fermi level E_{F2}′ of the second electrode 25 in the present embodiment).

In a similar manner, in the present disclosure, the energy difference ΔE_{F2}′ indicates the “energy difference between the lower end of the conduction band (in other words, the lower end of the ETL conduction band) of the electron transport layer 24e and the Fermi level of the second electrode 25 (in other words, the Fermi level E_{F2} of the second electrode 25) before electric dipole formation (in other words, in a state where there is no vacuum level shift)”. Note that in the present embodiment, “before electric dipole formation” refers to “before forming the electric dipole 1”. Also in the present disclosure, the reference sign of the energy difference ΔE_{F2} is positive (ΔE_{F2}>0) in a case where, before electric dipole formation, the lower end of the conduction band (in other words, the lower end of the ETL conduction band) of the electron transport layer 24e is on a higher energy side (on the upper side in the band diagram) than the Fermi level of the second electrode 25 (in other words, the Fermi level E_{F2} of the second electrode 25), and is negative (ΔE_{F2}<0) in a case where, before electric dipole formation, the lower end of the conduction band (in other words, the lower end of the ETL conduction band) of the electron transport layer 24e is on a lower energy side (on the lower side in the band diagram) than the Fermi level of the second electrode 25 (in other words, the Fermi level E_{F2} of the second electrode 25).

In a case where the electron injection barrier height is negative, it means that there is no electron injection barrier present.

As illustrated in (b) of FIG. 14, the energy difference Ed2 (=work function of the second electrode 25) between the vacuum level and the Fermi level E_{F2}′ of the second electrode 25 is greater than an electron affinity EA1 of the electron transport layer 24e, and the electron affinity EA1 of the electron transport layer 24e is greater than an electron affinity EA3 of the oxide layer 124a and an electron affinity EA4 of the oxide layer 124b. In the example illustrated in (b) of FIG. 14, the energy difference Ed2 (=work function of the second electrode 25) between the vacuum level and the Fermi level E_{F2}′ of the second electrode 25)>(the electron affinity EA1 of the electron transport layer 24e)>(the electron affinity EA3 of the oxide layer 124a)=(the electron affinity EA4 of the oxide layer 124b). In other words, in the example illustrated in (b) of FIG. 14, the electron affinity EA3 of the oxide layer 124a and the electron affinity EA4 of the oxide layer 124b are equal. However, in the present embodiment, no such limitation is intended, and it is only required that (i) the work function of the second electrode 25 (the energy difference Ed2 between the vacuum level and the Fermi level E_{F2}′ of the second electrode 25), (ii) the electron affinity EA1 of the electron transport layer 24e, and (iii) the electron affinity EA3 of the oxide layer 124a and the electron affinity EA4 of the oxide layer 124b are larger in this order.

The relationship between the electron affinity EA3 of the oxide layer 124a and the electron affinity EA4 of the oxide layer 124b varies depending on the material selected. Thus, there is no particular constraint on the relationship between the electron affinity EA3 of the oxide layer 124a and the electron affinity EA4 of the oxide layer 124b. Regarding the work function and the electron affinity of the layers, (i) the work function of the second electrode 25 (the energy difference Ed2 between the vacuum level and the Fermi level E_{F2}′ of the second electrode 25), (ii) the electron affinity EA1 of the electron transport layer 24e, (iii) the electron affinity EA3 of the oxide layer 124a, and (iv) the electron affinity EA4 of the oxide layer 124b may be larger in this order. Also, regarding the work function and the electron affinity of the layers, (i) the work function of the second electrode 25 (the energy difference Ed2 between the vacuum level and the Fermi level E_{F2}′ of the second electrode 25), (ii) the electron affinity EA1 of the electron transport layer 24e, (iii) the electron affinity EA4 of the oxide layer 124b, and (iv) the electron affinity EA3 of the oxide layer 124a may be larger in this order. In either case, the electric dipole 1′ can reduce the electron injection barrier height between the second electrode 25 and the electron transport layer 24e from the energy difference ΔE_{F2} to the energy difference ΔE_{F2}′.

Also, as illustrated in (b) of FIG. 14, the energy difference between the lower end of the conduction band and the upper end of the valence band in the oxide layer 124a and the oxide layer 124b is greater than the energy difference between the lower end of the ETL conduction band and the upper end of the ETL valence band in the electron transport layer 24e. Thus, the carrier density (electron density) of the oxide layer 124a and the oxide layer 124b is less than the carrier density (electron density) of the electron transport layer 24e, and the oxide layer 124a and the oxide layer 124b are better at insulating than the electron transport layer 24e. Note that herein, the energy difference between the lower end of the conduction band and the upper end of the valence band in the oxide layer 124a and the oxide layer 124b refers to the energy difference between the lower end of the conduction band and the upper end of the valence band in the oxide layer 124a and the energy difference between the lower end of the conduction band and the upper end of the valence band in the oxide layer 124b. Note that, in (b) of FIG. 14, the energy difference between the lower end of the conduction band and the upper end of the valence band in the oxide layer 124a is equal to the energy difference between the lower end of the conduction band′ and the upper end of the valence band′ of the oxide layer 124b. However, no such limitation is intended. The energy difference between the lower end of the conduction band and the upper end of the valence band in the oxide layer 124a and the energy difference between the lower end of the conduction band′ and the upper end of the valence band′ in the oxide layer 124b are determined by the selection of the material of the oxide layer 124a and the material of the oxide layer 124b. Thus, regarding the size relationship between the energy difference between the lower end of the conduction band and the upper end of the valence band in the oxide layer 124a and the energy difference between the lower end of the conduction band′ and the upper end of the valence band′ in the oxide layer 124b is not particularly restricted.

Also, as described above, the carrier density (electron density) of the oxide layer 124a and the oxide layer 124b is less than the carrier density (electron density) of the electron transport layer 24e. Accordingly, electron conduction by tunneling occurs in the oxide layer 124a and the oxide layer 124b. Note that the electron transport layer 24e is preferably an n-type semiconductor as described above. Note that the carrier density (electron density) of the electron transport layer 24e is preferably 1×10¹⁵ cm⁻³ or greater. In this case, the electron transport layer 24e has good electrical conductivity. Note that the carrier density (electron density) of the electron transport layer 24e is preferably 3×10¹⁷ cm⁻³ or less. In this case, non-emission recombination is suppressed, and the luminous efficiency is improved.

As described above, materials similar to that used for the oxide layer 24a and the oxide layer 24b described of the first embodiment can be used for the oxide layer 124a and the oxide layer 124b. In the present embodiment, for the oxides forming the oxide layer 124a and the oxide layer 124b, for example, of the two oxides selected from the inorganic oxides listed in FIG. 5, the oxide with the smaller oxygen atom density should be selected as the oxide to form the oxide layer 124b, and the oxide with the larger oxygen atom density should be selected as the oxide to form the oxide layer 124a.

A composite oxide containing multiple cations of the oxides listed in FIG. 5 can be used as the oxides for forming the oxide layer 124a and the oxide layer 124b. In addition, by reducing the oxygen composition ratio to the cation, the oxygen atom density of the oxide may be reduced.

By the oxygen atom density of the oxide layer 124b being less than the oxygen atom density of the oxide layer 124a, the electric dipole 1′ having a dipole moment including a component oriented in the direction of the oxide layer 124a from the oxide layer 124b is more easily formed, and electron injection efficiency can be improved.

The oxygen atom density of the oxide layer 124b is preferably 95% or less, more preferably 90% or less, even more preferably 85% or less, even more preferably 80% or less, even more preferably 75% or less, and even more preferably 70% or less of the oxygen atom density of the oxide layer 124a. The smaller the oxygen atom density of the oxide layer 124b relative to the oxygen atom density of the oxide layer 124a, the more easily the oxygen atoms can move from the oxide layer 124a toward the oxide layer 124b, and the electric dipole 1′ having a dipole moment including a component orientated in the direction from the oxide layer 124b to the oxide layer 124a is more efficiently formed. This allows for more efficient electron injection to the light-emitting layer 24d.

Also, the oxygen atom density of the oxide layer 124b is preferably 50% or less of the oxygen atom density of the oxide layer 124a. In this case, it is possible to suppress the formation of recombination centers due to dangling bonds and the like at the interface between the oxide layer 124a and the oxide layer 124b.

Note that the oxygen atom density in the present disclosure is a unique value for the oxide layer 124a and for the oxide layer 124b and applies to the oxygen atom bulk density of the material forming the oxide layer 124a or oxide layer 124b.

FIG. 15 is a diagram listing examples of combinations of oxides forming the oxide layer 124a and oxides forming the oxide layer 124b.

In the combinations listed in FIG. 15, because the oxygen atom density of the oxide layer 124b is less than the oxygen atom density of the oxide layer 124a, the electric dipole 1′ is formed as illustrated in (b) of FIG. 14 and efficient electron injection from the electron transport layer 24e to the light-emitting layer 24d is possible.

Note that the combinations of oxides forming the oxide layer 124a and the oxide layer 124b listed in FIG. 15 are merely examples. As long as the oxygen atom density of the oxide layer 124b is less than the oxygen atom density of the oxide layer 124a, the present disclosure is not limited to these combinations.

Note that in the examples of FIG. 15, the oxide layer 124b is formed of only one type of oxide. However, the oxide layer 124a and the oxide layer 124b may each be formed of one type of oxide, or may be formed of a plurality of oxides. That is, the oxide layer 124a may be formed of a composition formed by mixing a plurality of oxides, or as described above, may be formed of a composite oxide or the like containing two or more types of cations of the exemplified oxide. In a similar manner, the oxide layer 124b may be formed of a composition formed by mixing a plurality of oxides, or as described above, may be formed of a composite oxide or the like containing two or more types of cations of the exemplified oxide.

Also, the oxide layer 124b (more precisely, the oxide forming the oxide layer 124b) may include cations contained in the oxide layer 124a (in other words, cations contained in the oxide forming the oxide layer 124a). Also, the oxide layer 124a (more precisely, the oxide forming the oxide layer 124a) may include cations contained in the oxide layer 124b (in other words, cations contained in the oxide forming the oxide layer 124b). In either case, by the oxide layer 124a and the oxide layer 124b including a common cation, a structure that alleviates lattice mismatch between the oxide layer 124a and the oxide layer 124b can be obtained. As a result, defects due to lattice mismatch can be minimized or prevented and the electric dipole 1′ having a dipole moment including a component orientated in the direction from the oxide layer 124b to the oxide layer 124a can be more efficiently formed. This allows for more efficient electron injection from the electron transport layer 24e to the light-emitting layer 24d.

Note that the oxide layer 124a (more precisely, the oxide forming the oxide layer 124a) may contain at least one of Ni, Cu, Ti, Zn, Sn, In, W, or Mo, but contained content is preferably small. In the oxide layer 124a, the ratio of the total number density of Ni, Cu, Ti, Zn, Sn, In, W, Mo to the total number density of all cations contained in the oxide layer 124a is preferably less than 50%, more preferably 20% or less, preferably 10% or less, more preferably 4% or less, more preferably 1% or less, more preferably 0.4% or less, and more preferably less than 0.1%. In this case, the carrier density in the oxide layer 124a can be prevented from increasing, so the luminous efficiency is improved. Furthermore, the oxide layer 24a (more precisely, the oxide forming the oxide layer 124a) is further preferably free of any of Ni, Cu, Ti, Zn, Sn, In, W, and Mo.

Also, the oxide layer 124b (more precisely, the oxide forming the oxide layer 124b) may contain at least one of Ni, Cu, Ti, Zn, Sn, In, W, or Mo, but contained content is preferably small. In the oxide layer 124b, the ratio of the total number density of Ni, Cu, Ti, Zn, Sn, In, W, Mo to the total number density of all cations contained in the oxide layer 124b is preferably less than 50%, more preferably 20% or less, preferably 10% or less, more preferably 4% or less, more preferably 1% or less, more preferably 0.4% or less, and more preferably less than 0.1%. In this case, the carrier density in the oxide layer 124b can be prevented from increasing, so the luminous efficiency is improved. Furthermore, the oxide layer 124b (more precisely, the oxide forming the oxide layer 124b) is further preferably free of any of Ni, Cu, Ti, Zn, Sn, In, W, and Mo.

The film thickness of the oxide layer 124a is preferably is from 0.2 nm to 5 nm. By setting the film thickness of the oxide layer 124a to be 5 nm or less, electron tunneling can be efficient. Additionally, by setting the film thickness of the oxide layer 124a to be 0.2 nm or greater, a sufficiently large dipole moment can be obtained. The film thickness of the oxide layer 124a is more preferably is from 0.8 nm to 3 nm or less. In this case, more efficient electron injection is possible.

In a similar manner, the film thickness of the oxide layer 124b is preferably is from 0.2 nm to 5 nm. By setting the film thickness of the oxide layer 124b to be 5 nm or less, electron tunneling can be efficient. Additionally, by setting the film thickness of the oxide layer 124b to be 0.2 nm or greater, a sufficiently large dipole moment can be obtained. The film thickness of the oxide layer 124b is also more preferably is from 0.8 nm to 3 nm or less, and in this case, more efficient electron injection is possible.

The total film thickness of the oxide layer 124a and the oxide layer 124b is preferably is from 0.4 nm to 5 nm. By setting the total film thickness to be 5 nm or less, electron tunneling can be efficient. Additionally, by setting the total film thickness to be 0.4 nm or greater, a sufficiently large dipole moment can be obtained. The total film thickness is more preferably is from 1.6 nm to 4 nm or less. In this case, more efficient electron injection is possible.

In this manner, the film thickness of oxide layer 124a and the film thickness of the oxide layer 124b can be set in a similar manner to the film thickness of the oxide layer 24a and the film thickness of the oxide layer 24b, respectively, of the first embodiment. In other words, in the description of the film thickness of the oxide layer 24a and the film thickness of the oxide layer 24b in the first embodiment, “oxide layer 24a”, “oxide layer 24b”, and “holes” can be read as “oxide layer 124a”, “oxide layer 124b”, and “electrons”, respectively.

In addition, in the present embodiment, regarding the description of the crystalline state of the oxide layer 24a and oxide layer 24b and the shape of the oxide layer 24a and oxide layer 24b, the crystalline state of the oxide layer 24a and the oxide layer 24b and the shape of the oxide layer 24a and oxide layer 24b of the first embodiment can be read as described below. Thus, in the present embodiment, a detailed description of the crystalline state of the oxide layer 24a and the oxide layer 24b and the shape of the oxide layer 24a and the oxide layer 24b will be omitted, and, for example, the oxide layer 124a may be formed of an amorphous oxide or may be formed with at least a portion of the contact surface with oxide layer 124b formed of a polycrystalline oxide. Also, the oxide layer 124b may also be formed of an amorphous oxide or may be formed with at least a portion of the contact surface with oxide layer 124a formed of a polycrystalline oxide. Also, at least at the contact surface between the oxide layer 124a and the oxide layer 124b, at least one of the oxide layer 124a or the oxide layer 124b may include grains. In addition, at least one layer of the oxide layer 124a or the oxide layer 124b is preferably a continuous film, and at least the layer, from among the oxide layer 124a and the oxide layer 124b, on the upper layer side is more preferably a continuous film.

In other words, in the description of the crystalline state of the oxide layer 24a and the oxide layer 24b and the shape of the oxide layer 24a and oxide layer 24b in the first embodiment, “oxide layer 24a”, “oxide layer 24b”, “electric dipole 1”, “first electrode 22”, “Fermi level E_{F1}′”, “upper end of HTL valence band”, “energy difference ΔE_{F1}′”, “holes”, “light-emitting element 5”, and “FIG. 2” can be read as “oxide layer 124a”, “oxide layer 124b”, “electric dipole 1”, “second electrode 25”, “Fermi level E_{F2}′”, “lower end of ETL conduction band”, “energy difference ΔE_{F2}′”, “electrons”, “light-emitting element 155”, and “FIG. 13”, respectively.

In addition, in the present embodiment as well, similar to the second modified example or the third modified example of the first embodiment, from among the oxide layer 124a and the oxide layer 124b, the oxide layer on the lower layer side may be formed into island shapes.

### Fourth Embodiment

FIG. 16 is an energy band diagram for describing an electron injection barrier between the second electrode 25 (cathode) and the electron transport layer 24e in a light-emitting element 255 according to the present embodiment.

A light-emitting device according to the present embodiment includes the light-emitting element 255 illustrated in FIG. 16 as a light-emitting element in the light-emitting device (for example, the display device 2) according to the first embodiment. The light-emitting element 255 according to the present embodiment has the same configuration as the light-emitting element 155 according to the third embodiment except that the electron transport layer 24e is formed of an oxide.

In the example described below, the light-emitting element 255 has the same layered structure as the layered structure illustrated in FIG. 13. As illustrated in FIG. 16, the oxide layer 124a and the oxide layer 124b are layered in this order from the electron transport layer 24e side (in other words, the first electrode 22 side) between the electron transport layer 24e and the second electrode 25. Note that the electron transport layer 24e, the oxide layer 124a, and the oxide layer 124b are layered in this order and in contact with each other. As described above, the oxygen atom density of the oxide layer 124a and the oxygen atom density of the oxide layer 124b are different. Furthermore, the oxygen atom density of the electron transport layer 24e is different from the oxygen atom density of the oxide layer 124a adjacent to the electron transport layer 24e. In this case, oxygen atom movement occurs not only at the interface between the oxide layer 124a and the oxide layer 124b, but also at the interface between the oxide layer 124a and the electron transport layer 24e, and the electric dipole is easily formed.

The oxygen atom density of the oxide layer 124b is preferably less than the oxygen atom density of the oxide layer 124a. In this case, as described in the third embodiment, the energy difference ΔE_{F2}′ becomes smaller than the energy difference ΔE_{F2}, and thus efficient electron injection is possible.

Also, the oxygen atom density of the oxide layer 124a is preferably less than the oxygen atom density of the electron transport layer 24e. In this case, the aforementioned energy difference ΔE_{F2}′ becomes even smaller, and more efficient electron injection is possible.

In the present embodiment described below, the oxygen atom density of the oxide layer 124a is less than the oxygen atom density of the electron transport layer 24e, and the oxygen atom density of the oxide layer 124b is less than the oxygen atom density of the oxide layer 124a. In this case, as in the third embodiment, oxygen atoms easily move at the interface between the oxide layer 124a and the oxide layer 124b from the oxide layer 124a toward the oxide layer 124b. Furthermore, oxygen atoms easily move from the electron transport layer 24e toward the oxide layer 124a at the interface between the electron transport layer 24e and the oxide layer 124a. Accordingly, as illustrated in FIG. 16, as in the third embodiment, at the interface between the oxide layer 124a and the oxide layer 124b, the electric dipole 1′ having a dipole moment including a component orientated in the direction from the oxide layer 124b to the oxide layer 124a is formed. Also, at the interface between the electron transport layer 24e and the oxide layer 124a, an electric dipole 41 having a dipole moment including a component oriented in the direction of the electron transport layer 24e from the oxide layer 124a is formed.

Note that in the light-emitting element 255 of the present embodiment, the mechanism by which the oxygen atoms move at the interface between the oxide layer 124a and the oxide layer 124b adjacent to one another is the same as the mechanism by which the oxygen atoms move at the interface between the oxide layer 24a and the oxide layer 24b as illustrated in (a) of FIG. 4. Thus, in (a) and (b) of FIG. 4, “24a”, “24b”, and “1” can, in this order, be read as “124a”, “124b”, and “41”.

When the electric dipoles 1′ and 41 are formed in this manner, as illustrated in FIG. 16, a vacuum level shift caused by the electric dipoles 1′ and the electric dipole 41 occurs at the interface between the oxide layer 124a and the oxide layer 124b, which is the interface where the electric dipole 1′ is formed, and at the interface between the electron transport layer 24e and the oxide layer 124a, which is the interface where the electric dipole 41 is formed. As a result, as illustrated in FIG. 16, at the interface between the electron transport layer 24e and the oxide layer 124a and at the interface between the oxide layer 124a and the oxide layer 124b, the position of the band on the second electrode 25 side moves upward with respect to the position of the band on the first electrode 22 side. In other words, in the example illustrated in FIG. 16, the position of the band of the oxide layer 124a moves upward (band shift) with respect to the position of the band of the hole transport layer 24c and the position of the band of the light-emitting layer 24d. Also, the position of the band of the second electrode 25 and the position of the band of the oxide layer 124b move further upward (band shift) with respect to the position of the band of the oxide layer 124a, the position of the band of the hole transport layer 24c, and the position of the band of the light-emitting layer 24d. Although not illustrated, at this time, obviously the position of the band on the first electrode 22 side includes the position of the band of the layer on the first electrode 22 side of the light-emitting layer 24d. Note that in FIG. 16, the position of the band of the Fermi level E_{F2} of the second electrode 25 before the vacuum level shift due to the electric dipoles 1′ and 41 is indicated by a dot-dash line, and the position of the bands of the oxide layer 124a and the oxide layer 124b before the vacuum level shift due to the electric dipoles 1′ and 41 is indicated by a two-dot chain line. Also, the vacuum level after the vacuum level shift due to the electric dipoles 1′ and 41 is indicated by a dotted line.

Specifically, when the electric dipoles 1′ and 41 are formed, the Fermi level E_{F2} of the second electrode 25 moves to the Fermi level E_{F2}′ of the second electrode 25, the valence band of the oxide layer 124b moves to the valence band′ of the oxide layer 124b, and the valence band of the oxide layer 124a moves to the valence band′ of the oxide layer 124a. Also, the conduction band of the oxide layer 124b moves to the conduction band′ of the oxide layer 124b, and the conduction band of the oxide layer 124a moves to the conduction band′ of the oxide layer 124a. By this movement, the energy difference ΔE_{F2} between the lower end of the ETL conduction band and the Fermi level E_{F2} of the second electrode 25 becomes the energy difference ΔE_{F2}′ between the lower end of the ETL conduction band and the Fermi level E_{F2}′ of the second electrode 25. As a result, the energy difference ΔE_{F2}′ after formation of the electric dipoles 1′ and 41 (in other words, the electron injection barrier height from the second electrode 25 to the electron transport layer 24e after formation of the electric dipoles 1′ and 41) is less than the energy difference ΔE_{F2} (in other words, the electron injection barrier height from the second electrode 25 to the electron transport layer 24e in a case where the material of the electron transport layer 24e is not an oxide or the oxide layer 124a and the oxide layer 124b are not formed).

Similar to the light-emitting element 155 according to the third embodiment, in a case where the film thickness of the oxide layer 124a and the oxide layer 124b is sufficiently thin in the light-emitting element 255, because the electrons have conductivity via tunneling of the oxide layer 124a and oxide layer 124b, the electron injection barrier height between the second electrode 25 and the electron transport layer 24e is effectively the energy difference ΔE_{F2}′ between the lower end of the ETL conduction band and the Fermi level E_{F2}′ of the second electrode 25.

According to the present embodiment, by forming the electron transport layer 24e, the oxide layer 124b, and the oxide layer 124a as described above, at the two interfaces, the interface between the oxide layer 124a and the oxide layer 124b and the interface between the electron transport layer 24e and the oxide layer 124a, the electric dipole 1′ having a dipole moment including a component orientated in the direction from the oxide layer 124b to the oxide layer 124a and the electric dipole 41 having a dipole moment including a component orientated in the direction from the oxide layer 124b to the electron transport layer 24e are formed, respectively. Thus, according to the present embodiment, compared to the third embodiment, the position of the bands of the second electrode 25, the oxide layer 124b, and the oxide layer 124a move further upward with respect to the position of the band of the electron transport layer 24e. By this movement, the energy difference ΔE₂₁′ between the lower end of the ETL conduction band and the Fermi level E_{F2}′ of the second electrode 25 is made even smaller than in the third embodiment. Thus, according to the present embodiment, the electron injection from the second electrode 25 to the electron transport layer 24e is more efficient than in the third embodiment. As a result, the electron injection from the second electrode 25 to the light-emitting layer 24d (via the electron transport layer 24e) is more efficient than in the third embodiment, and the luminous efficiency of the light-emitting element 255 is further improved.

Note that in the present disclosure, the energy difference ΔE_{F2}′ indicates the “energy difference between the lower end of the conduction band of the electron transport layer 24e and the Fermi level of the second electrode 25 after electric dipole formation”. Thus, in the present embodiment, “after electric dipole formation” refers to “after formation of the electric dipoles 1 and 41”, and “the energy difference between the lower end of the conduction band of the electron transport layer 24e and the Fermi level of the second electrode 25 after electric dipole formation” refers to “the energy difference between the lower end of the ETL conduction band and the Fermi level E_{F2}′ of the second electrode 25 after formation of the electric dipoles 1′ and 41” as described above.

In a similar manner, in the present disclosure, the energy difference ΔE_{F2}′ indicates the “energy difference between the lower end of the conduction band (in other words, the lower end of the ETL conduction band) of the electron transport layer 24e and the Fermi level of the second electrode 25 (in other words, the Fermi level E_{F2} of the second electrode 25) before electric dipole formation (in other words, in a state where there is no vacuum level shift)”. Note that in the present embodiment, “before electric dipole formation” refers to “before forming the electric dipoles 1′ and 41”.

FIG. 17 is a diagram listing the oxygen atom density of inorganic oxides which are examples of the oxide for forming the electron transport layer 24e.

For the oxide forming the electron transport layer 24e, for example, an inorganic oxide having an oxygen atom density greater than the oxygen atom density of the oxide layer 124a may selected from the inorganic oxides listed in FIG. 17, and the inorganic oxide may be used as the oxide for forming the electron transport layer 24e. Furthermore, after selecting the oxide for forming the electron transport layer 24e from the inorganic oxides listing in FIG. 17, a combination of inorganic oxides having an oxygen atom density less than the oxygen atom density of the electron transport layer 24e may be selected from the inorganic oxides listed in FIG. 5 or FIG. 15 and combinations thereof to form the oxide layer 124a and the oxide layer 124b.

As the oxide forming the electron transport layer 24e, a composite oxide containing multiple cations of the oxides listed in FIG. 17 can be used, for example. Also, the electron transport layer 24e may be formed from an oxide containing at least one of Ti, Zn, Sn, or In. Furthermore, the electron transport layer 24e may include an oxide in which the most abundant elements other than oxygen are one of Ti, Zn, Sn, or In.

In the present embodiment also, by the oxygen atom density of the oxide layer 124b being less than the oxygen atom density of the oxide layer 124a, the electric dipole 1′ having a dipole moment including a component oriented in the direction of the oxide layer 124a from the oxide layer 124b is more easily formed, and electron injection efficiency can be improved. Also, according to the present embodiment, by the oxygen atom density of the oxide layer 124a adjacent to the electron transport layer 24e being less than the oxygen atom density of the electron transport layer 24e, the electric dipole 41 having a dipole moment including a component oriented in the direction of the electron transport layer 24e from the oxide layer 124a is more easily formed, and electron injection efficiency from the second electrode 25 to the electron transport layer 24e can be improved.

Note that in a case where the electron transport layer 24e is formed of an oxide as described above, the oxygen atom density of the oxide layer 124a is preferably 95% or less, more preferably 90% or less, even more preferably 85% or less, even more preferably 80% or less, even more preferably 75% or less, and even more preferably 70% or less of the oxygen atom density of the electron transport layer 24e. Also, as in the third embodiment, the oxygen atom density of the oxide layer 124b is preferably 95% or less, more preferably 90% or less, even more preferably 85% or less, even more preferably 80% or less, even more preferably 75% or less, and even more preferably 70% or less of the oxygen atom density of the oxide layer 124a. The smaller the oxygen atom density of the oxide layer 124b relative to the oxygen atom density of the electron transport layer 24e, the more easily the oxygen atoms can move from the electron transport layer 24e toward the oxide layer 124a, and the electric dipole 41 having a dipole moment including a component orientated in the direction from the oxide layer 124a to the electron transport layer 24e is more efficiently formed. Also, the smaller the oxygen atom density of the oxide layer 124b relative to the oxygen atom density of the oxide layer 124a, the more easily the oxygen atoms can move from the oxide layer 124a toward the oxide layer 124b, and the electric dipole 1′ having a dipole moment including a component orientated in the direction from the oxide layer 124b to the oxide layer 124a is more efficiently formed. Thus, efficient electron injection from the second electrode 25 to the electron transport layer 24e is possible. As a result, more efficient electron injection to the light-emitting layer 24d is possible, and luminous efficiency is improved.

Also, the oxygen atom density of the oxide layer 124b is preferably 50% or less of the oxygen atom density of the oxide layer 124a. In this case, it is possible to suppress the formation of recombination centers due to dangling bonds and the like at the interface between the oxide layer 124b and the oxide layer 124a.

Also, the oxygen atom density of the oxide layer 124a is preferably 50% or less of the oxygen atom density of the electron transport layer 24e. In this case, it is possible to suppress the formation of recombination centers due to dangling bonds and the like at the interface between the electron transport layer 24e and the oxide layer 124a.

As a result, more efficient electron injection from the second electrode 25 to the electron transport layer 24e is possible. Note that the oxygen atom density in the present disclosure is a unique value for electron transport layer 24e and applies to the oxygen atom bulk density of the material forming the electron transport layer 24e.

FIG. 18 is a diagram listing examples of combinations of oxides forming the electron transport layer 24e and oxides forming the oxide layer 124a adjacent to the electron transport layer 24e.

In the combinations listed in FIG. 18, the oxygen atom density of the oxide layer 124a is less than the oxygen atom density of the electron transport layer 24e. Thus, the electric dipole 41 having a dipole moment including a component orientated in the direction from the oxide layer 124a to the electron transport layer 24e is formed at the interface between the electron transport layer 24e and the oxide layer 124a as illustrated in FIG. 16. As a result, efficient electron injection from the second electrode 25 to the electron transport layer 24e is possible, and luminous efficiency is improved.

Note that the combinations of oxides forming the electron transport layer 24e and the oxide layer 124a listed in FIG. 18 are merely examples. As long as the oxygen atom density of the oxide layer 124a is less than the oxygen atom density of the electron transport layer 24e, the present disclosure is not limited to these combinations.

Note that in the examples of FIG. 18, the electron transport layer 24e is formed of only one type of oxide. However, the electron transport layer 24e, the oxide layer 124a, and the oxide layer 124b may each be formed of one type of oxide, or may be formed of a plurality of oxides. That is, in a similar manner to the oxide layer 124a and the oxide layer 124b, the electron transport layer 24e may be formed of a composition formed by mixing a plurality of oxides, or as described above, may be formed of a composite oxide or the like containing two or more types of cations of the exemplified oxide.

Also, the oxide layer 124a (more precisely, the oxide forming the oxide layer 124a) may include cations contained in the electron transport layer 24e (in other words, cations contained in the oxide forming the electron transport layer 24e), but the contained content is preferably small. In a case where the oxide layer 124a contains “cations contained in the electron transport layer 24e”, the ratio of the number density of the “cations contained in the electron transport layer 24e” contained in the oxide layer 124a to all of the cations contained in the oxide layer 124a is preferably less than 50%, more preferably 20% or less, more preferably 10% or less, more preferably 4% or less, more preferably 1% or less, more preferably 0.4% or less, and more preferably less than 0.1%. In this case, because the “cations contained in the electron transport layer 24e” are contained in the oxide layer 124a, it is possible to suppress an increase in the electron density in the oxide layer 124a. Furthermore, the oxide layer 124a (more precisely, the oxide forming the oxide layer 124a) is more preferably free of “cations contained in the electron transport layer 24e”.

Also, the electron transport layer 24e (more precisely, the oxide forming the electron transport layer 24e) may include cations contained in the oxide layer 124a (in other words, cations contained in the oxide forming the oxide layer 124b), but the contained content is preferably small. In a case where the electron transport layer 24e contains “cations contained in the oxide layer 124a”, the ratio of the number density of the “cations contained in the oxide layer 124a” contained in the electron transport layer 24e to all of the cations contained in the electron transport layer 24e is preferably less than 50%, more preferably 20% or less, more preferably 10% or less, more preferably 4% or less, more preferably 1% or less, more preferably 0.4% or less, and more preferably less than 0.1%. In this case, because the “cations contained in the oxide layer 124a” are contained in the electron transport layer 24e, it is possible to suppress a decrease in the electron mobility in the electron transport layer 24e. Furthermore, the electron transport layer 24e (more precisely, the oxide forming the electron transport layer 24e) is more preferably free of “cations contained in the oxide layer 124a”.

Note that the oxide layer 124a (more precisely, the oxide forming the oxide layer 124a) may contain at least one of Ni, Cu, Ti, Zn, Sn, In, W, or Mo, but contained content is preferably small. In the oxide layer 124a, the ratio of the total number density of Ni, Cu, Ti, Zn, Sn, In, W, Mo to the total number density of all cations contained in the oxide layer 124a is preferably less than 50%, more preferably 20% or less, preferably 10% or less, more preferably 4% or less, more preferably 1% or less, more preferably 0.4% or less, and more preferably less than 0.1%. In this case, the carrier density in the oxide layer 124a can be prevented from increasing, so the luminous efficiency is improved. Furthermore, the oxide layer 24a (more precisely, the oxide forming the oxide layer 124a) is further preferably free of any of Ni, Cu, Ti, Zn, Sn, In, W, and Mo.

Also, the oxide layer 124b (more precisely, the oxide forming the oxide layer 124b) may contain at least one of Ni, Cu, Ti, Zn, Sn, In, W, or Mo, but contained content is preferably small. In the oxide layer 124b, the ratio of the total number density of Ni, Cu, Ti, Zn, Sn, In, W, Mo to the total number density of all cations contained in the oxide layer 124b is preferably less than 50%, more preferably 20% or less, preferably 10% or less, more preferably 4% or less, more preferably 1% or less, more preferably 0.4% or less, and more preferably less than 0.1%. In this case, the carrier density in the oxide layer 124b can be prevented from increasing, so the luminous efficiency is improved. Furthermore, the oxide layer 124b (more precisely, the oxide forming the oxide layer 124b) is further preferably free of any of Ni, Cu, Ti, Zn, Sn, In, W, and Mo.

Also, though a detailed description is omitted, in a case where the electron transport layer 24e is formed of an oxide as described above, the electron transport layer 24e may be formed of an amorphous oxide or may be formed with at least a portion of the contact surface with oxide layer 124a formed of a polycrystalline oxide. In other words, in the latter case, only the contact surface of the electron transport layer 24e with the oxide layer 124a may be polycrystalline, or the entire electron transport layer 24e may be formed of a polycrystalline oxide. In other words, at least at a portion of the contact surface between the electron transport layer 24e and the oxide layer 124a, at least one of the electron transport layer 24e or the oxide layer 124a may include a polycrystalline oxide.

Also, as described in the third embodiment, the oxide layer 124a may be formed of an amorphous oxide or may be formed with at least a portion of the contact surface with electron transport layer 24e formed of a polycrystalline oxide. Also, the oxide layer 124b may also be formed of an amorphous oxide or may be formed with at least a portion of the contact surface with oxide layer 124a formed of a polycrystalline oxide.

In the present embodiment also, as long as the oxygen atom density of the oxide layer 124a is less than the oxygen atom density of the electron transport layer 24e and the oxygen atom density of the oxide layer 124b is less than the oxygen atom density of the oxide layer 124a, the method of making the electron transport layer 24e, the oxide layer 124a, and the oxide layer 124b polycrystalline is not particularly limited. Also, as long as the oxygen atom density of the oxide layer 124a is less than the oxygen atom density of the electron transport layer 24e and the oxygen atom density of the oxide layer 124b is less than the oxygen atom density of the oxide layer 124a, the type of the polycrystalline oxide forming the electron transport layer 24e, the oxide layer 124a, and the oxide layer 124b is not particularly limited. Also, as with the contact surface between the oxide layer 124a and the oxide layer 124b, at least at a portion of the contact surface between the electron transport layer 24e and the oxide layer 124a, at least one of the electron transport layer 24e or the oxide layer 124a may include grains.

### Fifth Embodiment

FIG. 19 is a cross-sectional view schematically illustrating a schematic configuration of a light-emitting element 355 according to the present embodiment.

A light-emitting device according to the present embodiment includes the light-emitting element 355 illustrated in FIG. 19 as a light-emitting element in the light-emitting device (for example, the display device 2) according to the first embodiment. The light-emitting element 355 according to the present embodiment has the same configuration as the light-emitting element 5 according to the first embodiment except for the following points. Specifically, as illustrated in FIG. 19, the light-emitting element 355 according to the present embodiment further includes an oxide layer 224a and an oxide layer 224b between the hole transport layer 24c and the light-emitting layer 24d of the light-emitting element 5 according to the first embodiment.

In other words, the light-emitting element 355 of the present embodiment includes the first electrode 22 (hole injection layer: HIL), which is an anode, the hole transport layer 24c (HTL), the light-emitting layer 24d, the electron transport layer (ETL) 24e, and the second electrode 25 (electron injection layer: EIL), which is a cathode, formed in this order from the lower layer side. The oxide layer 24a (first oxide layer) and the oxide layer 24b (second oxide layer) that is in contact with the oxide layer 24b are provided in this order from the first electrode 22 side between the first electrode 22 and the hole transport layer 24c. The oxide layer 224a (third oxide layer) and the oxide layer 224b (fourth oxide layer) are provided in this order from the hole transport layer 24c side (in other words, the first electrode 22 side) between the hole transport layer 24c and the light-emitting layer 24d.

Note that in the present embodiment also, the layering order from the first electrode 22 to the second electrode 25 may be reversed. In addition, the first electrode 22 (the second electrode 25 in a case where the layering order is reversed), the oxide layer 24a, the oxide layer 24b, the hole transport layer 24c, the oxide layer 224a, the oxide layer 224b, the light-emitting layer 24d, and the electron transport layer 24e may be formed into island shapes for each subpixel SP, with the second electrode 25 (the first electrode 22 in a case where the layering order is reversed) formed as a solid-like common layer. In addition, instead of the configuration described above, the first electrode 22 (the second electrode 25 in a case where the layering order is reversed) and the light-emitting layer 24d are formed into island shapes for each subpixel SP, and except these, at least one of the oxide layer 24a, the oxide layer 24b, the hole transport layer 24c, the oxide layer 224a, the oxide layer 224b, the electron transport layer 24e, and the second electrode 25 (the first electrode 22 in a case where the layering order is reversed) may be formed as a solid-like common layer.

As described in the first embodiment, the oxygen atom density of the oxide layer 24a and the oxygen atom density of the oxide layer 24b are different. Similarly, the density of the oxygen atoms in the oxide layer 224a (also referred to as “the oxygen atom density of the oxide layer 224a” below) is different from the density of oxygen atoms in the oxide layer 224b (also referred to as “the oxygen atom density of oxide layer 224b” below). In this case, oxygen atoms easily move at the interface between the oxide layer 24a and the oxide layer 24b and at the interface between the oxide layer 224a and the oxide layer 224b, and the electric dipole is easily formed. Accordingly, the light-emitting element 355 of the present embodiment can effectively control the amount of hole injection to the light-emitting layer 24d more than the light-emitting element 5 of the first embodiment.

As described in the first embodiment, the oxygen atom density of the oxide layer 24b is also preferably less than the oxygen atom density of the oxide layer 24a. In this case, as described in the first embodiment, the hole injection barrier height between the first electrode 22 and the hole transport layer 24c decreases from the energy difference ΔE_{F1} to the energy difference ΔE_{F1}′. Thus, efficient hole injection from the first electrode 22 to the hole transport layer 24c is possible. As a result, efficient hole injection to the light-emitting layer 24d is possible. Also, the oxygen atom density of the oxide layer 224b is preferably less than the oxygen atom density of the oxide layer 224a. In this case, as described below, the hole injection barrier height from the hole transport layer 24c to the light-emitting layer 24d decreases from an energy difference ΔEv to an energy difference ΔEv′. Thus, efficient hole injection from the hole transport layer 24c to the light-emitting layer 24d is possible. In the present embodiment described below, the oxygen atom density of the oxide layer 24b is less than the oxygen atom density of the oxide layer 24a, and the oxygen atom density of the oxide layer 224b is less than the oxygen atom density of the oxide layer 224a.

FIG. 20 is an energy band diagram for describing a hole injection barrier between the first electrode 22 (anode) and the hole transport layer 24c and a hole injection barrier between the hole transport layer 24c and the light-emitting layer 24d in a light-emitting element according to a comparative example. FIG. 21 is an energy band diagram for describing a hole injection barrier between the first electrode 22 (anode) and the hole transport layer 24c and a hole injection barrier between the hole transport layer 24c and the light-emitting layer 24d in the light-emitting element 355.

As illustrated in FIG. 20, in the light-emitting element of the comparative example in which the hole transport layer 24c and the light-emitting layer 24d are in direct contact, the energy difference ΔEv between the upper end of the valence band (HTL valence band) of the hole transport layer 24c and the upper end of the valence band (light-emitting layer valence band) of the light-emitting layer 24d is large. Because the energy difference ΔEv is the height of the hole injection barrier from the hole transport layer 24c to the light-emitting layer 24d, in the light-emitting element illustrated in FIG. 20, efficient hole injection to the light-emitting layer 24d is not possible.

In addition, the light-emitting element of PTL 1 has a small difference in ionization potential between the light-emitting layer with no band level adjustment and the light-emitting layer with an adjusted band level. Thus, the light-emitting element of PTL 1 cannot satisfactorily reduce the height of a hole injection barrier Eh2 illustrated in FIG. 29 corresponding to the energy difference ΔEv. That is, in the method of PTL 1, effective band level adjustment cannot be achieved.

Thus, the light-emitting element of PTL 1 is still unable to effectively control the amount of hole injection to a light-emitting layer 103 illustrated in FIG. 29, and thus there is a problem in that the luminous efficiency is poor for a light-emitting element.

Note that the hole injection barrier between the first electrode 22 (anode) and the hole transport layer 24c is as described in the first embodiment, and thus description thereof is omitted here.

On the other hand, as illustrated in FIG. 21, the light-emitting element 355 according to the present embodiment includes, between the first electrode 22 and the hole transport layer 24c, the oxide layer 24a and the oxide layer 24b layered adjacent to one another in this order from the first electrode 22 side, and as described above, the oxygen atom density of the oxide layer 24b is less than the oxygen atom density of the oxide layer 24a. Also, as illustrated in FIG. 21, the light-emitting element 355 according to the present embodiment includes, between the hole transport layer 24c and the light-emitting layer 24d, the oxide layer 224a and the oxide layer 224b layered adjacent to one another in this order from the hole transport layer 24c side, and as described above, the oxygen atom density of the oxide layer 224b is less than the oxygen atom density of the oxide layer 224a. Thus, as illustrated in FIG. 21, as in the first embodiment, the oxygen atoms can easily move from the oxide layer 24a toward the oxide layer 24b at the interface between the oxide layer 24a and the oxide layer 24b, and, at the interface, the electric dipole 1 having a dipole moment including a component orientated in the direction from the oxide layer 24b to the oxide layer 24a is formed. Also, the oxygen atoms can easily move from the oxide layer 224a toward the oxide layer 224b at the interface between the oxide layer 224a and the oxide layer 224b, and, at the interface, an electric dipole 51 having a dipole moment including a component orientated in the direction from the oxide layer 224b to the oxide layer 224a is formed.

Note that in the light-emitting element 355 of the present embodiment, the mechanism by which the oxygen atoms move at the interface between the oxide layer 224a and the oxide layer 224b adjacent to one another is the same as the mechanism by which the oxygen atoms move at the interface between the oxide layer 24a and the oxide layer 24b as illustrated in (a) of FIG. 4. Thus, in (a) and (b) of FIG. 4, “24a”, “24b”, and “1” can, in this order, be read as “224a”, “224b”, and “51”.

When the electric dipoles 1 and 51 are formed in this manner, as illustrated in FIG. 21, a vacuum level shift caused by the electric dipole 1 and the electric dipole 51 occurs at the interface between the oxide layer 24a and the oxide layer 24b, which is the interface where the electric dipole 1 is formed, and at the interface between the oxide layer 224a and the oxide layer 224b, which is the interface where the electric dipole 51 is formed. As a result, as illustrated in FIG. 21, at the interface between the oxide layer 24a and the oxide layer 24b and at the interface between the oxide layer 224a and the oxide layer 224b, the position of the band on the first electrode 22 side moves downward with respect to the position of the band on the second electrode 25 side. That is, in the case of the example illustrated in FIG. 21, the electric dipole 51 causes the position of the band of the oxide layer 224a, the position of the band of the hole transport layer 24c, the position of the band of the oxide layer 24b, the position of the band of the oxide layer 24a, and the position of the band of the first electrode 22 to move downward (band shift) with respect to the position of the band of the oxide layer 224b and the position of the band of the light-emitting layer 24d. At this time, obviously the position of the band on the second electrode 25 side includes the position of the band of the layer on the second electrode 25 side of the light-emitting layer 24d. Also, the electric dipole 1 causes the position of the band of the oxide layer 224a, the position of the band of the hole transport layer 24c, the position of the band of the oxide layer 24b, the position of the band of the oxide layer 24a, and the position of the band of the first electrode 22 to move further downward (band shift) with respect to the position of the band of the oxide layer 224b and the position of the band of the light-emitting layer 24d. Note that in FIG. 21, the position of the band of the Fermi level E_{F1} of the first electrode 22 before the vacuum level shift due to the electric dipoles 1 and 51 is indicated by a dot-dash line, and the position of the bands of the oxide layers 24a, 24b, and 224a and the position of the band of the hole transport layer 24c before the vacuum level shift due to the electric dipoles 1 and 51 is indicated by a two-dot chain line. Also, the vacuum level after the vacuum level shift due to the electric dipoles 1 and 51 is indicated by a dotted line.

Specifically, when the electric dipoles 1 and 51 are formed, the Fermi level E_{F1} of the first electrode 22 moves to the Fermi level E_{F1}′ of the first electrode 22, the valence band of the oxide layer 24a moves to the valence band′ of the oxide layer 24a, the valence band of the oxide layer 24b moves to the valence band′ of the oxide layer 24b, the valence band (HTL valence band) of the hole transport layer 24c moves to the HTL valence band′, the valence band of the oxide layer 224a moves to the valence band′ of the oxide layer 224a, and the valence band of the oxide layer 224b moves to the valence band′ of the oxide layer 224b. Also, the conduction band of the oxide layer 24a moves to the conduction band′ of the oxide layer 24a, the conduction band of the oxide layer 24b moves to the conduction band′ of the oxide layer 24b, the conduction band (HTL conduction band) of the hole transport layer 24c moves to the HTL conduction band′, the conduction band of the oxide layer 224a moves to the conduction band′ of the oxide layer 224a, and the conduction band of the oxide layer 224b moves to the conduction band′ of the oxide layer 224b.

By this movement, the energy difference ΔE_{F1} between the Fermi level E_{F1} of the first electrode 22 and the upper end of the HTL valence band becomes the energy difference ΔE_{F1}′ between the Fermi level E_{F1}′ of the first electrode 22 and the upper end of the HTL valence band. As a result, the energy difference ΔE_{F1}′ after formation of the electric dipoles 1 and 51 (in other words, the hole injection barrier height from the first electrode 22 to the hole transport layer 24c after formation of the electric dipoles 1 and 51) is less than the energy difference ΔE_{F1} (in other words, the hole injection barrier height from the first electrode 22 to the hole transport layer 24c in a case where the oxide layers 24a, 24b, 224a, and 224b are not formed). Furthermore, by this movement, the energy difference ΔEv between the upper end of the HTL valence band and the upper end of the light-emitting layer valence band is an energy difference ΔEv′ between the upper end of the HTL valence band′ and the upper end of the light-emitting layer valence band. As a result, the energy difference ΔEv′ after formation of the electric dipoles 1 and 51 (in other words, the hole injection barrier height from the hole transport layer 24c to the light-emitting layer 24d after formation of the electric dipoles 1 and 51) is less than the energy difference ΔEv (in other words, the hole injection barrier height from the hole transport layer 24c to the light-emitting layer 24d in a case where the oxide layers 24a, 24b, 224a, and 224b are not formed).

In a case where the film thickness of the oxide layer 24a and the oxide layer 24b is sufficiently thin in the light-emitting element 355, because the holes have conductivity via tunneling of the oxide layer 24a and oxide layer 24b, the hole injection barrier height between the first electrode 22 and the hole transport layer 24c is effectively the energy difference ΔE_{F1}′ between the Fermi level E_{F1}′ of the first electrode 22 and the upper end of the HTL valence band′ (the upper end of the valence band of the hole transport layer 24c after formation of the electric dipoles 1 and 51). Also, in a case where the film thickness of the oxide layer 224a and the oxide layer 224b is sufficiently thin in the light-emitting element 355, because the holes have conductivity via tunneling of the oxide layer 224a and oxide layer 224b, the hole injection barrier height between the hole transport layer 24c and the light-emitting layer 24d is effectively the energy difference ΔEv′ between the upper end of the HTL valence band′ and the upper end of the light-emitting layer valence band. According to the present embodiment, by forming the oxide layers 24a, 24b, 224a, and 224b in this manner, the hole injection barrier height between the first electrode 22 and the hole transport layer 24c and the hole injection barrier height between the hole transport layer 24c and the light-emitting layer 24d is reduced, allowing for more efficient hole injection to the light-emitting layer 24d.

Note that in the present disclosure, the energy difference ΔE_{F1}′ indicates “the energy difference between the Fermi level of the first electrode 22 and the upper end of the valence band of the hole transport layer 24c after electric dipole formation”. Thus, in the present embodiment, “after electric dipole formation” refers to “after formation of the electric dipoles 1 and 51”, and the energy difference ΔE_{F1}′ refers to “the energy difference between the Fermi level E_{F1}′ of the first electrode 22 and the upper end of the HTL valence band after formation of the electric dipoles 1 and 51” as described above.

In a similar manner, in the present disclosure, the energy difference ΔE_{F1} indicates “the energy difference between the Fermi level of the first electrode 22 (in other words, the Fermi level E_{F1} of the first electrode 22) and the upper end of the valence band of the hole transport layer 24c (in other words, the upper end of the HTL valence band) after electric dipole formation (in other words, in a state where there is no vacuum level shift)”. Note that in the present embodiment, “before electric dipole formation” refers to “before forming the electric dipoles 1 and 51”.

Additionally, in the present disclosure, the energy difference ΔEv′ indicates the “energy difference between the upper end of the valence band of the hole transport layer 24c and the upper end of the valence band of the light-emitting layer 24d after electric dipole formation”. Thus, in the present embodiment, the “energy difference between the upper end of the valence band of the hole transport layer 24c and the upper end of the valence band of the light-emitting layer 24d after electric dipole formation” refers to “the energy difference between the upper end of the HTL valence band′ and the upper end of the light-emitting layer valence band after formation of the electric dipoles 1 and 51”. Also in the present disclosure, the reference sign of the energy difference ΔEv′ is positive (ΔEv′>0) in a case where, after electric dipole formation, the upper end of the valence band of the hole transport layer 24c (in the present embodiment, the upper end of the HTL valence band′) is on a higher energy side (on the upper side in the band diagram) than the upper end of the valence band of the light-emitting layer 24d (in the present embodiment, the upper end of the light-emitting layer valence band), and is negative (ΔEv′<0) in a case where, after electric dipole formation, the upper end of the valence band of the hole transport layer 24c (in the present embodiment, the upper end of the HTL valence band′) is on a lower energy side (on the lower side in the band diagram) than the upper end of the valence band of the light-emitting layer 24d (in the present embodiment, the upper end of the light-emitting layer valence band).

Similarly, in the present disclosure, the energy difference ΔEv indicates the “energy difference between the upper end of the valence band of the hole transport layer 24c (in other words the upper end of the HTL valence band) and the upper end of the valence band of the light-emitting layer 24d (in other words, the upper end of the light-emitting layer valence band), before formation of the electric dipole (in other words, in a state where there is no vacuum level shift)”. Thus, in the present embodiment, “before electric dipole formation” refers to “before forming the electric dipoles 1 and 51”. Also in the present disclosure, the reference sign of the energy difference ΔEv is positive (ΔEv>0) in a case where, before electric dipole formation, the upper end of the valence band of the hole transport layer 24c (in other words, the upper end of the HTL valence band) is on a higher energy side (on the upper side in the band diagram) than the upper end of the valence band of the light-emitting layer 24d (in other words, the upper end of the light-emitting layer valence band), and is negative (ΔEv<0) in a case where, before electric dipole formation, the upper end of the valence band of the hole transport layer 24c (in other words, the upper end of the HTL valence band) is on a lower energy side (on the lower side in the band diagram) than the upper end of the valence band of the light-emitting layer 24d (in other words, the upper end of the light-emitting layer valence band).

In a case where the hole injection barrier height is negative, it means that there is no hole injection barrier present.

Note that in FIG. 21, an example is given of a case in which the position (position of the lower end of the conduction band and the upper end of the valence band) of the bands of the oxide layers 24a, 24b, 224a, and 224b before the vacuum level shift is caused by the electric dipoles 1 and 51, indicated by the two-dot chain line, are the same. However, the position of the bands of oxide layers 24a, 24b, 224a, 224b are determined by the material selected for the oxide layers 24a, 24b, 224a, 224b, and thus the positions are not limited to those in example illustrated in FIG. 21. In the example illustrated in FIG. 21, an example is given of a case in which the Fermi level E_{F1}′ of the first electrode 22 after a band shift has been caused by formation of the electric dipoles 1 and 51 is positioned above the upper end of the HTL valence band′. However, the Fermi level E_{F1}′ of the first electrode 22 after the band shift may be positioned below the upper end of the HTL valence band′ and is more preferably positioned below.

Note that in the present embodiment also, as illustrated in FIG. 21, the energy difference Ed1 between the vacuum level and the Fermi level E_{F1}′ of the first electrode 22 (=the work function of the first electrode 22), the ionization potential IP1 of the hole transport layer 24c, the ionization potential IP3 of the oxide layer 24a, and the ionization potential IP4 of the oxide layer 24b have the same relationship as described in the first embodiment.

In the example illustrated in FIG. 21, the ionization potential IP1 of the hole transport layer 24c, the ionization potential IP2 of the light-emitting layer 24d, an ionization potential IP5 of the oxide layer 224a, and an ionization potential IP6 of the oxide layer 224b have, but are not limited to having, the relationship: (the ionization potential IP1 of the hole transport layer 24c)<(ionization potential IP2 of the light-emitting layer 24d)<(the ionization potential IP5 of the oxide layer 224a)=(the ionization potential IP6 of the oxide layer 224b).

Regarding the ionization potential IP1 of the hole transport layer 24c, the ionization potential IP2 of the light-emitting layer 24d, the ionization potential IP5 of the oxide layer 224a, and the ionization potential IP6 of the oxide layer 224b, it is only required that the ionization potential IP1 of the hole transport layer 24c is less than the ionization potential IP2 of the light-emitting layer 24d, and that the ionization potential IP5 of the oxide layer 224a and the ionization potential IP6 of the oxide layer 224b are greater than the ionization potential IP2 of the light-emitting layer 24d. The relationship between ionization potential IP5 of the oxide layer 224a and ionization potential IP6 of the oxide layer 224b also varies depending on the material selected. Thus, there is no particular constraint on the relationship between the ionization potential IP5 of the oxide layer 224a and the ionization potential IP6 of the oxide layer 224b. Accordingly, regarding the ionization potential of each layer, the ionization potential IP1 of the hole transport layer 24c, the ionization potential IP2 of the light-emitting layer 24d, the ionization potential IP5 of the oxide layer 224a, and the ionization potential IP6 of the oxide layer 224b may be smaller in this order, or the ionization potential IP1 of the hole transport layer 24c, the ionization potential IP2 of the light-emitting layer 24d, the ionization potential IP6 of the oxide layer 224b, and the ionization potential IP5 of the oxide layer 224a may be smaller in this order. In either case, the electric dipole 51 can reduce the hole injection barrier height between the hole transport layer 24c and the light-emitting layer 24d from the energy difference ΔEv to the energy difference ΔEv′.

Note that in the example illustrated in FIG. 21, (the ionization potential IP3 of the oxide layer 24a)=(the ionization potential IP4 of the oxide layer 24b)=(the ionization potential IP5 of the oxide layer 224a)=(the ionization potential IP6 of the oxide layer 224b) holds true, but no such limitation is intended. The selection of the material determines the size relationship between the ionization potential IP3 of the oxide layer 24a, the ionization potential IP4 of the oxide layer 24b, the ionization potential IP5 of the oxide layer 224a, and the ionization potential IP6 of the oxide layer 224b, and thus the size relationship between the ionization potentials IP3 to IP6 is not particularly restricted.

Also, as illustrated in FIG. 21, in a similar manner to the oxide layer 24a and the oxide layer 24b, the energy difference between the lower end of the conduction band and the upper end of the valence band in the oxide layer 224a and the oxide layer 224b is greater than the energy difference between the lower end of the HTL conduction band and the upper end of the HTL valence band in the hole transport layer 24c. Thus, the carrier density (hole density) of the oxide layer 224a and the oxide layer 224b is less than the carrier density (hole density) of the hole transport layer 24c, and the oxide layer 224a and the oxide layer 224b are better at insulating than the hole transport layer 24c. Note that herein, the energy difference between the lower end of the conduction band and the upper end of the valence band in the oxide layer 224a and the oxide layer 224b refers to the energy difference between the lower end of the conduction band and the upper end of the valence band in the oxide layer 224a and the energy difference between the lower end of the conduction band and the upper end of the valence band in the oxide layer 224b. Note that the energy difference between the lower end of the conduction band and the upper end of the valence band in the oxide layer 224a is equal to the energy difference between the lower end of the conduction band′ and the upper end of the valence band′ of the oxide layer 224a. Also, as described above, the carrier density (hole density) of the oxide layer 224a and the oxide layer 224b is less than the carrier density (hole density) of the hole transport layer 24c. Accordingly, hole conduction by tunneling occurs in the oxide layer 224a and the oxide layer 224b in a similar manner to the oxide layer 24a and the oxide layer 24b.

Note that, of the oxide layers 24a, 24b, 224a, and 224b, the oxide layer 24a and the oxide layer 24b are as described in the first and second embodiments. Thus, the description of the oxide layer 24a and the oxide layer 24b will be omitted below. A material similar to that used for the oxide layer 24a and the oxide layer 24b described in the first and second embodiment can be used for the oxide layer 224a and the oxide layer 224b. For example, for the oxides forming the oxide layer 224a and the oxide layer 224b, of the two oxides selected from the inorganic oxides listed in FIG. 5, the oxide with the smaller oxygen atom density should be selected as the oxide to form the oxide layer 224b, and the oxide with the larger oxygen atom density should be selected as the oxide to form the oxide layer 224a. Also, a composite oxide containing multiple cations of the oxides listed in FIG. 5 can be used as the oxides for forming the oxide layer 224a and the oxide layer 224b in a similar manner to the oxide layers 24a and 24b. In addition, by reducing the oxygen composition ratio to the cation, the oxygen atom density of the oxide may be reduced.

By the oxygen atom density of the oxide layer 224b being less than the oxygen atom density of the oxide layer 224a, the electric dipole 51 having a dipole moment including a component oriented in the direction of the oxide layer 224a from the oxide layer 224b is more easily formed, and the efficiency of hole injection from the hole transport layer 24c to the light-emitting layer 24d can be improved.

A combination of the oxide forming the oxide layer 224a and the oxide forming the oxide layer 224b can be used in a similar manner to the combinations listed in FIG. 6, for example. In FIG. 6, “oxide layer 24a” and “oxide layer 24b” can be read as “oxide layer 224a” and “oxide layer 224b”, respectively. In a similar manner to the oxide layer 24a and the oxide layer 24b, the oxide layer 224a and the oxide layer 224b may be formed of one type of oxide, or may be formed of a plurality of oxides. That is, the oxide layers 224a, 224b may be formed of a composition formed by mixing a plurality of oxides, or as described above, may be formed of a composite oxide or the like containing two or more types of cations of the exemplified oxide.

Also, the oxide layer 224b (more precisely, the oxide forming the oxide layer 224b) may include cations contained in the oxide layer 224a (in other words, cations contained in the oxide forming the oxide layer 224a), and the oxide layer 224a (more precisely, the oxide forming the oxide layer 224a) may include cations contained in the oxide layer 224b (in other words, cations contained in the oxide forming the oxide layer 224b). In either case, by the oxide layer 224a and the oxide layer 224b including a common cation, a structure that alleviates lattice mismatch between the oxide layer 224a and the oxide layer 224b can be obtained. As a result, defects due to lattice mismatch can be minimized or prevented and the electric dipole 51 having a dipole moment including a component orientated in the direction from the oxide layer 224b to the oxide layer 224a can be more efficiently formed. This allows for more efficient hole injection from the hole transport layer 24c to the light-emitting layer 24d.

The oxygen atom density of the oxide layer 224b is preferably 95% or less, more preferably 90% or less, even more preferably 85% or less, even more preferably 80% or less, even more preferably 75% or less, and even more preferably 70% or less of the oxygen atom density of the oxide layer 224a. Also, the oxygen atom density of the oxide layer 224b is preferably 50% or less of the oxygen atom density of the oxide layer 224a.

The film thickness of the oxide layer 224a and the film thickness of the oxide layer 224b is preferably from 0.2 nm to 5 nm, and the total film thickness of the oxide layer 224a and the oxide layer 224b is preferably is from 0.4 nm to 5 nm.

In this manner, the oxygen atom density of the oxide layer 224a and the oxygen atom density of the oxide layer 224b can be set in a similar manner to the oxygen atom density of the oxide layer 24a and the oxygen atom density of the oxide layer 24b, respectively, of the first embodiment. Also, the film thickness of oxide layer 224a and the film thickness of the oxide layer 224b can be set in a similar manner to the film thickness of the oxide layer 24a and the film thickness of the oxide layer 24b, respectively, of the first embodiment. In other words, in the description of the oxygen atom density of the oxide layer 24a and the oxygen atom density of the oxide layer 24b and the description of the film thickness of the oxide layer 24a and the film thickness of the oxide layer 24b in the first embodiment, “oxide layer 24a”, “oxide layer 24b”, and “electric dipole 1” can be read as “oxide layer 224a”, “oxide layer 224b”, and “electric dipole 51”, respectively.

Also, thought a detailed description is omitted, the oxide layer 224a may be formed of an amorphous oxide or may be formed with at least a portion of the contact surface with oxide layer 224b formed of a polycrystalline oxide. Also, the oxide layer 224b may also be formed of an amorphous oxide or may be formed with at least a portion of the contact surface with oxide layer 224a formed of a polycrystalline oxide. Also, at least at a portion of the contact surface between the oxide layer 224a and the oxide layer 224b, at least one of the oxide layer 224a or the oxide layer 224b may include grains. In addition, at least one layer of the oxide layer 224a or the oxide layer 224b is preferably a continuous film, and at least the layer, from among the oxide layer 224a and the oxide layer 224b, on the upper layer side is more preferably a continuous film.

In other words, in the description of the crystalline state of the oxide layer 24a and the oxide layer 24b and the shape of the oxide layer 24a and oxide layer 24b in the first embodiment, “oxide layer 24a”, “oxide layer 24b”, “electric dipole 1”, “Fermi level E_{F1} of the first electrode 22”, “upper end of HTL valence band”, “energy difference ΔE_{F1}′”, “light-emitting element 5”, and “FIG. 2” can be read as “oxide layer 224a”, “oxide layer 224b”, “electric dipole 51′”, “upper end of valence band (HTL valence band′) of the hole transport layer 24c”, “upper end of valence band (light-emitting layer valence band) of the light-emitting layer 24d”, “energy difference ΔEv′”, “light-emitting element 355”, and “FIG. 19”, respectively.

In a similar manner to the oxide layer 24a and the oxide layer 24b, the oxide layer on the lower layer side, from among the oxide layer 224a and the oxide layer 224b, may be formed into island shapes.

### Sixth Embodiment

FIG. 22 is an energy band diagram for describing a hole injection barrier between the first electrode 22 (anode) and the hole transport layer 24c and a hole injection barrier between the hole transport layer 24c and the light-emitting layer 24d in a light-emitting element 455 according to the present embodiment.

A light-emitting device according to the present embodiment includes the light-emitting element 455 illustrated in FIG. 22 as a light-emitting element in the light-emitting device (for example, the display device 2) according to the first embodiment. The light-emitting element 455 according to the present embodiment has the same configuration as the light-emitting element 355 according to the fifth embodiment except that the hole transport layer 24c is formed of an oxide.

In the example described below, the light-emitting element 355 has a similar layered structure as the layered structure illustrated in FIG. 19. As illustrated in FIG. 22, the oxide layer 24a and the oxide layer 24b are layered in this order from the first electrode 22 side between the first electrode 22 and the hole transport layer 24c. Also, the oxide layer 224a and the oxide layer 224b are layered in this order from the hole transport layer 24c side (in other words, the first electrode 22 side) between the hole transport layer 24c and the light-emitting layer 24d. Note that the oxide layer 24a, the oxide layer 24b, the hole transport layer 24c, the oxide layer 224a, and the oxide layer 224b are layered in this order and in contact with each other. As described above, the oxygen atom density of the oxide layer 24a and the oxygen atom density of the oxide layer 24b are different. Also, the oxygen atom density of the oxide layer 224a and the oxygen atom density of the oxide layer 224b are different. Furthermore, the oxygen atom density of the hole transport layer 24c is different from the oxygen atom density of the oxide layer 24b adjacent to the hole transport layer 24c. Furthermore, the oxygen atom density of the hole transport layer 24c is different from the oxygen atom density of the oxide layer 224a adjacent to the hole transport layer 24c. In this case, oxygen atom movement occurs not only at the interface between the oxide layer 24a and the oxide layer 24b and the interface between the oxide layer 224a and the oxide layer 224b, but also at the interface between the oxide layer 24b and the hole transport layer 24c and the interface between the hole transport layer 24c and the oxide layer 224a, and the electric dipole is easily formed. Accordingly, the light-emitting element 455 of the present embodiment can more effectively control the amount of hole injection to the light-emitting layer 24d more than the light-emitting element 355 of the fifth embodiment.

In this case, as described in the fifth embodiment, the oxygen atom density of the oxide layer 24b is preferably less than the oxygen atom density of the oxide layer 24a, and the oxygen atom density of the oxide layer 224b is preferably less than the oxygen atom density of the oxide layer 224a. Also, as described in the second embodiment, the oxygen atom density of the hole transport layer 24c is also preferably less than the oxygen atom density of the oxide layer 24b. Furthermore, the oxygen atom density of the oxide layer 224a is preferably less than the oxygen atom density of the hole transport layer 24c. In the example of the present embodiment described below, the oxygen atom density of the oxide layer 24a>the oxygen atom density of the oxide layer 24b>the oxygen atom density of the hole transport layer 24c>the oxygen atom density of the oxide layer 224a>the oxygen atom density of the oxide layer 224b holds true. In other words, regarding the oxygen atom density of the layers, in the example of the present embodiment, the oxygen atom density of the oxide layer 24a, the oxygen atom density of the oxide layer 24b, the oxygen atom density of the hole transport layer 24c, the oxygen atom density of the oxide layer 224a, and the oxygen atom density of the oxide layer 224b are larger in this order.

In this case, as in the fifth embodiment, oxygen atoms easily move from the oxide layer 24a toward the oxide layer 24b at the interface between the oxide layer 24a and the oxide layer 24b, and the oxygen atoms easily move from the oxide layer 224a toward the oxide layer 224b at the interface between the oxide layer 224a and the oxide layer 224b. Also, as in the second embodiment, oxygen atoms easily move at the interface between the oxide layer 24b and the hole transport layer 24c from the oxide layer 24b toward the hole transport layer 24c. Furthermore, in the present embodiment, oxygen atoms easily move from the hole transport layer 24c toward the oxide layer 224a at the interface between the hole transport layer 24c and the oxide layer 224a. Thus, as illustrated in FIG. 21, as in the fifth embodiment, the electric dipole 1 having a dipole moment including a component orientated in the direction from the oxide layer 24b to the oxide layer 24a is formed at the interface between the oxide layer 24a and the oxide layer 24b, and the electric dipole 51 having a dipole moment including a component orientated in the direction from the oxide layer 224b to the oxide layer 224a is formed at the interface between the oxide layer 224a and the oxide layer 224b. Also, as in the second embodiment, at the interface between the oxide layer 24b and the hole transport layer 24c, an electric dipole 31 having a dipole moment including a component orientated from the hole transport layer 24c toward the oxide layer 24b is formed. In addition, in the present embodiment, at the interface between the hole transport layer 24c and the oxide layer 224a, an electric dipole 61 having a dipole moment including a component oriented from the oxide layer 224a toward the hole transport layer 24c is formed.

Note that in the light-emitting element 455 of the present embodiment, the mechanism by which the oxygen atoms move at the interface between the hole transport layer 24c and the oxide layer 224a adjacent to one another is the same as the mechanism by which the oxygen atoms move at the interface between the oxide layer 24a and the oxide layer 24b as illustrated in (a) of FIG. 4. Thus, in (a) and (b) of FIG. 4, “24a”, “24b”, and “1” can, in this order, be read as “24c”, “224a”, and “61”.

When the electric dipoles 1, 31, 51, and 61 are formed in this manner, as illustrated in FIG. 22, a vacuum level shift caused by the electric dipole 1, the electric dipole 31, the electric dipole 51, and the electric dipole 61 occurs at the interface between the oxide layer 24a and the oxide layer 24b, which is the interface where the electric dipole 1 is formed, at the interface between the oxide layer 24b and the hole transport layer 24c, which is the interface where the electric dipole 31 is formed, at the interface between the hole transport layer 24c and the oxide layer 224a, which is the interface where the electric dipole 61 is formed, and at the interface between the oxide layer 224a and the oxide layer 224b, which is the interface where the electric dipole 51 is formed, respectively. As a result, as illustrated in FIG. 22, the position of the band on the first electrode 22 side moves downward with respect to the position of the band on the second electrode 25 side at the interfaces described above where the electric dipoles 1, 31, 61, and 51 are formed. That is, in the case of the example illustrated in FIG. 22, the electric dipole 51 causes the position of the band of the oxide layer 224a, the position of the band of the hole transport layer 24c, the position of the band of the oxide layer 24b, the position of the band of the oxide layer 24a, and the position of the band of the first electrode 22 to move downward (band shift) with respect to the position of the band of the oxide layer 224b and the position of the band of the light-emitting layer 24d. Also, the electric dipole 61 causes the position of the band of the hole transport layer 24c, the position of the band of the oxide layer 24b, the position of the band of the oxide layer 24a, and the position of the band of the first electrode 22 to move further downward (band shift) with respect to the position of the band of the oxide layer 224a, the position of the band of the oxide layer 224b, and the position of the band of the light-emitting layer 24d. Also, the electric dipole 31 causes the position of the band of the oxide layer 24b, the position of the band of the oxide layer 24a, and the position of the band of the first electrode 22 to move further downward (band shift) with respect to the position of the band of the hole transport layer 24c, the position of the band of the oxide layer 224a, the position of the band of the oxide layer 224b, and the position of the band of the light-emitting layer 24d. Also, the electric dipole 1 causes the position of the band of the oxide layer 224a, the position of the band of the hole transport layer 24c, the position of the band of the oxide layer 24b, the position of the band of the oxide layer 24a, and the position of the band of the first electrode 22 to move further downward (band shift) with respect to the position of the band of the oxide layer 224b and the position of the band of the light-emitting layer 24d. Although not illustrated, at this time, obviously the position of the band on the second electrode 25 side includes the position of the band of the layer on the second electrode 25 side of the light-emitting layer 24d.

Note that in FIG. 22, the position of the band of the Fermi level E_{F1} of the first electrode 22 before the vacuum level shift due to the electric dipoles 1, 31, 61, and 51 is indicated by a dot-dash line, and the position of the bands of the oxide layers 24a, 24b, and 224a and the position of the band of the hole transport layer 24c before the vacuum level shift due to the electric dipoles 1, 31, 61, and 51 is indicated by a two-dot chain line. Also, the vacuum level after the vacuum level shift due to the electric dipoles 1, 31, 61, and 51 is indicated by a dotted line.

Specifically, when the electric dipoles 1, 31, 61, and 51 are formed, the Fermi level E_{F1} of the first electrode 22 moves to the Fermi level E_{F1}′ of the first electrode 22, the valence band of the oxide layer 24a moves to the valence band′ of the oxide layer 24a, the valence band of the oxide layer 24b moves to the valence band′ of the oxide layer 24b, the HTL valence band moves to the HTL valence band′, the valence band of the oxide layer 224a moves to the valence band′ of the oxide layer 224a, and the valence band of the oxide layer 224b moves to the valence band′ of the oxide layer 224b. Also, the conduction band of the oxide layer 24a moves to the conduction band′ of the oxide layer 24a, the conduction band of the oxide layer 24b moves to the conduction band′ of the oxide layer 24b, the HTL conduction band moves to the HTL conduction band′, the conduction band of the oxide layer 224a moves to the conduction band′ of the oxide layer 224a, and the conduction band of the oxide layer 224b moves to the conduction band′ of the oxide layer 224b.

By this movement, the energy difference ΔE_{F1} between the Fermi level E_{F1} of the first electrode 22 and the upper end of the HTL valence band becomes the energy difference ΔE_{F1}′ between the Fermi level E_{F1}′ of the first electrode 22 and the upper end of the HTL valence band. As a result, the energy difference ΔE_{F1}′ after formation of the electric dipoles 1, 31, 61, and 51 (in other words, the hole injection barrier height from the first electrode 22 to the hole transport layer 24c after formation of the electric dipoles 1, 31, 61, and 51) is less than the energy difference ΔE_{F1} (in other words, the hole injection barrier height from the first electrode 22 to the hole transport layer 24c in a case where the material of the hole transport layer 24c is not an oxide or the oxide layers 24a, 24b, 224a, and 224b are not formed). Furthermore, by this movement, the energy difference ΔEv between the upper end of the HTL valence band and the upper end of the light-emitting layer valence band is an energy difference ΔEv′ between the upper end of the HTL valence band′ and the upper end of the light-emitting layer valence band. As a result, the energy difference ΔEv′ after formation of the electric dipoles 1, 31, 61, and 51 (in other words, the hole injection barrier height from the hole transport layer 24c to the light-emitting layer 24d after formation of the electric dipoles 1, 31, 61, and 51) is less than the energy difference ΔEv (in other words, the hole injection barrier height from the hole transport layer 24c to the light-emitting layer 24d in a case where the material of the hole transport layer 24c is not an oxide or the oxide layers 24a, 24b, 224a, and 224b are not formed).

In a similar manner to the light-emitting element 355 of the fifth embodiment, in a case where the film thickness of the oxide layer 24a and the oxide layer 24b is sufficiently thin, because the holes have conductivity via tunneling of the oxide layer 24a and oxide layer 24b, the hole injection barrier height between the first electrode 22 and the hole transport layer 24c is effectively the energy difference ΔE_{F1}′ between the Fermi level E_{F1}′ of the first electrode 22 and the upper end of the valence band of the hole transport layer 24c (upper end of the HTL valence band). Also, in a similar manner to the light-emitting element 355 of the fifth embodiment, in a case where the film thickness of the oxide layer 224a and the oxide layer 224b is sufficiently thin, because the holes have conductivity via tunneling of the oxide layer 224a and oxide layer 224b, the hole injection barrier height between the hole transport layer 24c and the light-emitting layer 24d is effectively the energy difference ΔEv′ between the upper end of the HTL valence band′ and the upper end of the light-emitting layer valence band. According to the present embodiment, by forming the hole transport layer 24c and the oxide layers 24a, 24b, 224a, and 224b as described above, the hole injection barrier height between the first electrode 22 and the hole transport layer 24c and the hole injection barrier height between the hole transport layer 24c and the light-emitting layer 24d is reduced, allowing for more efficient hole injection from the first electrode 22 to the light-emitting layer 24d. As a result, the luminous efficiency is improved. Also, according to the present embodiment, because the electric dipoles 1, 31, 61, and 51 are formed, the hole injection barrier height between the first electrode 22 and the hole transport layer 24c and the hole injection barrier height between the hole transport layer 24c and the light-emitting layer 24d is reduced more than in the light-emitting element 355 of the fifth embodiment, allowing for more efficient hole injection from the first electrode 22 to the light-emitting layer 24d. As a result, with the light-emitting element 455 of the present embodiment, the luminous efficiency can be improved more than with the light-emitting element 355 of the fifth embodiment.

Note that in the present disclosure, the energy difference ΔE_{F1}′ indicates “the energy difference between the Fermi level of the first electrode 22 and the upper end of the valence band of the hole transport layer 24c after electric dipole formation”. Thus, in the present embodiment, the energy difference ΔE_{F1}′ refers to “the energy difference between the Fermi level E_{F1}′ of the first electrode 22 and the upper end of the HTL valence band after formation of the electric dipoles 1, 31, 61, and 51” as described above.

In a similar manner, in the present disclosure, the energy difference ΔE_{F1} indicates “the energy difference between the Fermi level of the first electrode 22 (in other words, the Fermi level E_{F1} of the first electrode 22) and the upper end of the valence band of the hole transport layer 24c (in other words, the upper end of the HTL valence band) after electric dipole formation (in other words, in a state where there is no vacuum level shift)”. Note that in the present embodiment, “before electric dipole formation” refers to “before forming the electric dipoles 1, 31, 61, and 51”.

Additionally, in the present disclosure, the energy difference ΔEv′ indicates the “energy difference between the upper end of the valence band of the hole transport layer 24c and the upper end of the valence band of the light-emitting layer 24d after electric dipole formation”. Thus, in the present embodiment, the “energy difference between the upper end of the valence band of the hole transport layer 24c and the upper end of the valence band of the light-emitting layer 24d after electric dipole formation” refers to the “energy difference between the upper end of the HTL valence band′ and the upper end of the light-emitting layer valence band after formation of the electric dipoles 1, 31, 61, and 51”.

Similarly, in the present disclosure, the energy difference ΔEv indicates the “energy difference between the upper end of the valence band of the hole transport layer 24c (in other words the upper end of the HTL valence band) and the upper end of the valence band of the light-emitting layer 24d (in other words, the upper end of the light-emitting layer valence band), before formation of the electric dipole (in other words, in a state where there is no vacuum level shift)”. Note that in the present embodiment, “before electric dipole formation” refers to “before forming the electric dipoles 1, 31, 61, and 51”.

Note that in FIG. 22, an example is given of a case in which the position (position of the lower end of the conduction band and the upper end of the valence band) of the bands of the oxide layers 24a, 24b, 224a, and 224b before the vacuum level shift is caused by the electric dipoles 1, 31, 61, and 51, indicated by the two-dot chain line, are the same. However, the position of the bands of oxide layers 24a, 24b, 224a, 224b are determined by the material selected for the oxide layers 24a, 24b, 224a, 224b, and thus the positions are not limited to those in example illustrated in FIG. 22. In the present embodiment also, the Fermi level E_{F1}′ of the first electrode 22 after the band shift caused by the electric dipoles 1, 31, 61, and 51 may be positioned above or below the upper end of the HTL valence band′ and is more preferably positioned below. Also, the upper end of the valence band of the hole transport layer 24c (the upper end of the HTL valence band′) after the band shift caused by the electric dipoles 1, 31, 61, and 51 may be positioned above or below the upper end of the valence band of the light-emitting layer 24d (upper end of the light-emitting layer valence band) and is more preferably positioned below.

Note that in the present embodiment also, the oxide forming the hole transport layer 24c can be selected in the same manner as in the second embodiment. However, in the present embodiment, an inorganic oxide having an oxygen atom density that is less than the oxygen atom density of the oxide layer 24b and greater than the oxygen atom density of the oxide layer 224a is selected as the oxide forming the hole transport layer 24c.

Note that in a case where the hole transport layer 24c is formed of an oxide as described above, the oxygen atom density of the oxide layer 224a is preferably 95% or less, more preferably 90% or less, even more preferably 85% or less, even more preferably 80% or less, even more preferably 75% or less, and even more preferably 70% or less of the oxygen atom density of the hole transport layer 24c. Also, the oxygen atom density of the oxide layer 224a is preferably 50% or less of the oxygen atom density of the hole transport layer 24c.

In this manner, the relationship between the oxygen atom density of the hole transport layer 24c and the oxygen atom density of the oxide layer 224a can be set in a similar manner to the relationship between oxygen atom density of the oxide layer 24a and the oxygen atom density of the oxide layer 24b of the first embodiment. In other words, in the description of the oxygen atom density of the oxide layer 24a and the oxygen atom density of the oxide layer 24b in the first embodiment, “oxide layer 24a”, “oxide layer 24b”, and “electric dipole 1” can be read as “hole transport layer 24c”, “oxide layer 224a”, and “electric dipole 61”, respectively.

Note that the relationship between the oxygen atom density of the oxide layer 24b and the oxygen atom density of the hole transport layer 24c in a case where the hole transport layer 24c is formed of an oxide is as described in the second embodiment, and the oxygen atom density of the hole transport layer 24c is preferably 95% or less, more preferably 90% or less, even more preferably 85% or less, even more preferably 80% or less, even more preferably 75% or less, and even more preferably 70% or less of the oxygen atom density of the oxide layer 24b. Also, as described in the second embodiment, the oxygen atom density of the hole transport layer 24c is also preferably 50% or greater of the oxygen atom density of the oxide layer 24b. Note that the relationship between the oxygen atom density of the oxide layer 24a and the oxygen atom density of the oxide layer 24b, and the relationship between the oxygen atom density of the oxide layer 224a and the oxygen atom density of the oxide layer 224b is as described in the fifth embodiment.

### Seventh Embodiment

FIG. 23 is a cross-sectional view schematically illustrating a schematic configuration of a light-emitting element 555 according to the present embodiment.

A light-emitting device according to the present embodiment includes the light-emitting element 555 illustrated in FIG. 23 as a light-emitting element in the light-emitting device (for example, the display device 2) according to the first embodiment. The light-emitting element 555 according to the present embodiment has the same configuration as the light-emitting element 155 according to the third embodiment except for the following points. Specifically, as illustrated in FIG. 23, the light-emitting element 555 according to the present embodiment further includes an oxide layer 324a and an oxide layer 324b between the electron transport layer 24e and the light-emitting layer 24d of the light-emitting element 155 according to the third embodiment.

In other words, the light-emitting element 555 of the present embodiment includes the first electrode 22 (hole injection layer: HIL), which is an anode, the hole transport layer 24c (HTL), the light-emitting layer 24d, the electron transport layer (ETL) 24e, and the second electrode 25 (electron injection layer: EIL), which is a cathode, formed in this order from the lower layer side. The oxide layer 124a (first oxide layer) and the oxide layer 124b (second oxide layer) that is in contact with the oxide layer 124a are provided in this order from the electron transport layer 24e side (in other words, the first electrode 22 side) between the electron transport layer 24e and the second electrode 25. The oxide layer 324a (third oxide layer) and the oxide layer 324b (fourth oxide layer) are provided in this order from the light-emitting layer 24d side (in other words, the first electrode 22 side) between the light-emitting layer 24d and the electron transport layer 24e.

Note that in the present embodiment also, the layering order from the first electrode 22 to the second electrode 25 may be reversed. In addition, the first electrode 22 (the second electrode 25 in a case where the layering order is reversed), the hole transport layer 24c, the light-emitting layer 24d, the oxide layer 324a, the oxide layer 324b, the electron transport layer 24e, the oxide layer 124a, and the oxide layer 124b may be formed into island shapes for each subpixel SP, with the second electrode 25 (the first electrode 22 in a case where the layering order is reversed) formed as a solid-like common layer. In addition, instead of the configuration described above, the first electrode 22 (the second electrode 25 in a case where the layering order is reversed) and the light-emitting layer 24d are formed into island shapes for each subpixel SP, and except these, at least one of the hole transport layer 24c, the oxide layer 324a, the oxide layer 324b, the electron transport layer 24e, the oxide layer 124a, the oxide layer 124b, and the second electrode 25 (the first electrode 22 in a case where the layering order is reversed) may be formed as a solid-like common layer.

As described in the third embodiment, the oxygen atom density of the oxide layer 124a and the oxygen atom density of the oxide layer 124b are different. Similarly, the density of the oxygen atoms in the oxide layer 324a (also referred to as “the oxygen atom density of the oxide layer 324a” below) is different from the density of oxygen atoms in the oxide layer 324b (also referred to as “the oxygen atom density of oxide layer 324b” below). In this case, oxygen atoms easily move at the interface between the oxide layer 124a and the oxide layer 124b and at the interface between the oxide layer 324a and the oxide layer 324b, and the electric dipole is easily formed. Accordingly, the light-emitting element 555 of the present embodiment can effectively control the amount of electron injection to the light-emitting layer 24d more than the light-emitting element 155 of the third embodiment.

As described in the third embodiment, the oxygen atom density of the oxide layer 124b is also preferably less than the oxygen atom density of the oxide layer 124a. Also, the oxygen atom density of the oxide layer 324b is preferably less than the oxygen atom density of the oxide layer 324a. In the present embodiment described below, the oxygen atom density of the oxide layer 124b is less than the oxygen atom density of the oxide layer 124a, and the oxygen atom density of the oxide layer 324b is less than the oxygen atom density of the oxide layer 324a.

FIG. 24 is an energy band diagram for describing an electron injection barrier between the second electrode 25 (cathode) and the electron transport layer 24e and an electron injection barrier between the electron transport layer 24e and the light-emitting layer 24d in a light-emitting element according to a comparative example. FIG. 25 is an energy band diagram for describing an electron injection barrier between the second electrode 25 (cathode) and the electron transport layer 24e and an electron injection barrier between the electron transport layer 24e and the light-emitting layer 24d in the light-emitting element 555.

As illustrated in FIG. 24, in the light-emitting element of the comparative example in which the electron transport layer 24e and the light-emitting layer 24d are in direct contact, an energy difference ΔEc between the lower end of the conduction band of the light-emitting layer 24d (light-emitting layer conduction band) and the lower end of the conduction band of the electron transport layer 24e (ETL conduction band) is large. Because the energy difference ΔEc is the height of the electron injection barrier between the electron transport layer 24e to the light-emitting layer 24d, in the light-emitting element illustrated in FIG. 24, efficient hole injection to the light-emitting layer 24d is not possible.

Furthermore, even in a case where the band level is adjusted as in PTL 1, the height of the electron injection barrier Ee2 illustrated in FIG. 29 corresponding to the energy difference ΔEc cannot be sufficiently reduced. That is, in the method of PTL 1, effective band level adjustment cannot be achieved.

Thus, the light-emitting element of PTL 1 is still unable to effectively control the amount of hole injection and electron injection to a light-emitting layer 103 illustrated in FIG. 29, and thus there is a problem in that the luminous efficiency is poor for a light-emitting element.

Note that the electron injection barrier between the second electrode 25 (cathode) and the electron transport layer 24e is as described in the third embodiment, and thus description thereof is omitted here.

On the other hand, as illustrated in FIG. 25, the light-emitting element 555 according to the present embodiment includes, between the second electrode 25 and the electron transport layer 24e, the oxide layer 124a and the oxide layer 124b layered adjacent to one another in this order from the electron transport layer 24e side, and as described above, the oxygen atom density of the oxide layer 124b is less than the oxygen atom density of the oxide layer 124a. Also, as illustrated in FIG. 25, the light-emitting element 555 according to the present embodiment includes, between the light-emitting layer 24d and the electron transport layer 24e, the oxide layer 324a and the oxide layer 324b layered adjacent to one another in this order from the light-emitting layer 24d side, and as described above, the oxygen atom density of the oxide layer 324b is less than the oxygen atom density of the oxide layer 324a. Thus, as illustrated in FIG. 25, as in the third embodiment, the oxygen atoms can easily move from the oxide layer 124a toward the oxide layer 124b at the interface between the oxide layer 124a and the oxide layer 124b, and, at the interface, the electric dipole 1′ having a dipole moment including a component orientated in the direction from the oxide layer 124b to the oxide layer 124a is formed. Also, the oxygen atoms can easily move from the oxide layer 324a toward the oxide layer 324b at the interface between the oxide layer 324a and the oxide layer 324b, and, at the interface, an electric dipole 71 having a dipole moment including a component orientated in the direction from the oxide layer 324b to the oxide layer 324a is formed.

Note that in the light-emitting element 555 of the present embodiment, the mechanism by which the oxygen atoms move at the interface between the oxide layer 324a and the oxide layer 324b adjacent to one another is the same as the mechanism by which the oxygen atoms move at the interface between the oxide layer 24a and the oxide layer 24b as illustrated in (a) of FIG. 4. Thus, in (a) and (b) of FIG. 4, “24a”, “24b”, and “1” can, in this order, be read as “324a”, “324b”, and “71”.

When the electric dipoles 71 and 1′ are formed in this manner, as illustrated in FIG. 25, a vacuum level shift caused by the electric dipole 71 and the electric dipole 1′ occurs at the interface between the oxide layer 324a and the oxide layer 324b, which is the interface where the electric dipole 71 is formed, and at the interface between the oxide layer 124a and the oxide layer 124b, which is the interface where the electric dipole 1′ is formed. As a result, as illustrated in FIG. 25, at the interface between the oxide layer 324a and the oxide layer 324b and at the interface between the oxide layer 124a and the oxide layer 124b, the position of the band on the second electrode 25 side moves upward with respect to the position of the band on the first electrode 22 side. That is, in the case of the example illustrated in FIG. 25, the electric dipole 71 causes the position of the band of the oxide layer 324b, the position of the band of the electron transport layer 24e, the position of the band of the oxide layer 124a, the position of the band of the oxide layer 124b, and the position of the band of the second electrode 25 to move upward (band shift) with respect to the position of the band of the light-emitting layer 24d and the position of the band of the oxide layer 324a. Also, the electric dipole 1′ causes the position of the band of the oxide layer 124b and the position of the band of the second electrode 25 to move further upward (band shift) with respect to the position of the band of the light-emitting layer 24d, the position of the band of the oxide layer 324a, the position of the band of the electron transport layer 24e, and the position of the band of the oxide layer 124a. Although not illustrated, at this time, obviously the position of the band on the first electrode 22 side includes the position of the band of the layer on the first electrode 22 side of the light-emitting layer 24d. Note that in FIG. 25, the position of the band of the Fermi level E_{F2} of the second electrode 25 before the vacuum level shift due to the electric dipoles 71 and 1′ is indicated by a dot-dash line, and the position of the bands of the oxide layers 324b, 124a, and 124b and the position of the band of the electron transport layer 24e before the vacuum level shift due to the electric dipoles 71 and 1′ is indicated by a two-dot chain line. Also, the vacuum level after the vacuum level shift due to the electric dipoles 71 and 1′ is indicated by a dotted line.

Specifically, when the electric dipoles 71 and 1′ are formed, the valence band of the oxide layer 324b moves to the valence band′ of the oxide layer 324b, the ETL valence band moves to the ETL valence band′, the valence band of the oxide layer 124a moves to the valence band′ of the oxide layer 124a, the valence band of the oxide layer 124b moves to the valence band′ of oxide layer 124b, and the Fermi level E_{F2} of the second electrode 25 moves to the Fermi level E_{F2}′ of the second electrode 25. Also, the conduction band of the oxide layer 324b moves to the conduction band′ of the oxide layer 324b, the ETL conduction band moves to the ETL conduction band′, the conduction band of the oxide layer 124a moves to the conduction band′ of the oxide layer 124a, and the conduction band of the oxide layer 124b moves to the conduction band′ of the oxide layer 124b.

By this movement, the energy difference ΔE_{F2} between the lower end of the ETL conduction band and the Fermi level E_{F2} of the second electrode 25 becomes the energy difference ΔE_{F2}′ between the lower end of the ETL conduction band and the Fermi level E_{F2}′ of the second electrode 25. As a result, the energy difference ΔE_{F2}′ after formation of the electric dipoles 71 and 1′ (in other words, the electron injection barrier height from the second electrode 25 to the electron transport layer 24e after formation of the electric dipoles 71 and 1′) is less than the energy difference ΔE_{F2} (in other words, the electron injection barrier height from the second electrode 25 to the electron transport layer 24e in a case where the oxide layer 324a, 324b, 124a, and 124b are not formed). Furthermore, by this movement, the energy difference ΔEc between the lower end of the light-emitting layer conduction band and the lower end of the ETL conduction band becomes an energy difference ΔEc′ between the lower end of the light-emitting layer conduction band and the lower end of the ETL conduction band′. As a result, the energy difference ΔEc′ after formation of the electric dipoles 71 and 1′ (in other words, the electron injection barrier height from the electron transport layer 24e to the light-emitting layer 24d after formation of the electric dipoles 71 and 1′) is less than the energy difference ΔEc (in other words, the electron injection barrier height from the electron transport layer 24e to the light-emitting layer 24d in a case where the oxide layers 324a, 324b, 124a, and 124b are not formed).

In a case where the film thickness of the oxide layer 124a and the oxide layer 124b is sufficiently thin in the light-emitting element 555, because the electrons have conductivity via tunneling of the oxide layer 124a and oxide layer 124b, the electron injection barrier height between the second electrode 25 and the electron transport layer 24e is effectively the energy difference ΔE_{F2}′ between the Fermi level E_{F2}′ of the second electrode 25 and the lower end of the conduction band of the electron transport layer 24e (lower end of the ETL conduction band′). Also, in a case where the film thickness of the oxide layer 324a and the oxide layer 324b is sufficiently thin in the light-emitting element 555, because the electrons have conductivity via tunneling of the oxide layer 324a and oxide layer 324b, the electron injection barrier height between the electron transport layer 24e and the light-emitting layer 24d is effectively the energy difference ΔEc′ between the lower end of the light-emitting layer conduction band and the lower end of the ETL conduction band′. According to the present embodiment, by forming the oxide layers 324a, 324b, 124a, and 124b in this manner, the electron injection barrier height between the second electrode 25 and the electron transport layer 24e and the electron injection barrier height between the electron transport layer 24e and the light-emitting layer 24d is reduced, allowing for more efficient electron injection to the light-emitting layer 24d.

Note that in the present disclosure, the energy difference ΔEc′ indicates the “energy difference between the lower end of the conduction band of the light-emitting layer 24d and the lower end of the conduction band of the electron transport layer 24e after electric dipole formation”. Thus, in the present embodiment, “after electric dipole formation” refers to “after formation of the electric dipoles 71 and 1′”, and “the energy difference between the lower end of the conduction band of the light-emitting layer 24d and the lower end of the conduction band of the electron transport layer 24e after electric dipole formation” refers to “the energy difference between the lower end of the light-emitting layer conduction band and the lower end of the ETL conduction band′ after formation of the electric dipoles 71 and 1” as described above. Also in the present disclosure, the reference sign of the energy difference ΔEc′ is positive (ΔEc′>0) in a case where, after electric dipole formation, the lower end of the conduction band of the light-emitting layer 24d (in the present embodiment, the lower end of the light-emitting layer conduction band) is on a higher energy side (on the upper side in the band diagram) than the lower end of the conduction band of the electron transport layer 24e (in the present embodiment, the lower end of the ETL conduction band′), and is negative (ΔEc′ <0) in a case where, after electric dipole formation, the lower end of the conduction band of the light-emitting layer 24d (in the present embodiment, the lower end of the light-emitting layer conduction band) is on a lower energy side (on the lower side in the band diagram) than the lower end of the conduction band of the electron transport layer 24e (in the present embodiment, the lower end of the ETL conduction band′).

Similarly, in the present disclosure, the energy difference ΔEc indicates the “energy difference between the lower end of the conduction band of the light-emitting layer 24d (in other words, the lower end of the light-emitting layer conduction band) and the lower end of the conduction band of the electron transport layer 24e (in other words, lower end of the ETL conduction band), before formation of the electric dipole (in other words, in a state where there is no vacuum level shift)”. Note that in the present embodiment, “before electric dipole formation” refers to “before forming the electric dipoles 71 and 1′”. Also in the present disclosure, the reference sign of the energy difference ΔEc is positive (ΔEc>0) in a case where, before electric dipole formation, the lower end of the conduction band of the light-emitting layer 24d (in other words, the lower end of the light-emitting layer conduction band) is on a higher energy side (on the upper side in the band diagram) than the lower end of the conduction band of the electron transport layer 24e (in other words, the lower end of the ETL conduction band), and is negative (ΔEc<0) in a case where, before electric dipole formation, the lower end of the conduction band of the light-emitting layer 24d (in other words, the lower end of the light-emitting layer conduction band) is on a lower energy side (on the lower side in the band diagram) than the lower end of the conduction band of the electron transport layer 24e (in other words, the lower end of the ETL conduction band).

In a case where the electron injection barrier height is negative, it means that there is no electron injection barrier present.

Also, in the present disclosure, the energy difference ΔE_{F2}′ indicates the “energy difference between the lower end of the conduction band of the electron transport layer 24e and the Fermi level of the second electrode 25 after electric dipole formation”. Accordingly, in the present embodiment, the energy difference ΔE_{F2}′ indicates the “energy difference between the lower end of the ETL conduction band′ and the Fermi level E_{F2}′ of the second electrode 25 after formation of the electric dipoles 71 and 1′”.

In a similar manner, in the present disclosure, the energy difference ΔE_{F2}′ indicates the “energy difference between the lower end of the conduction band (in other words, the lower end of the ETL conduction band) of the electron transport layer 24e and the Fermi level of the second electrode 25 (in other words, the Fermi level E_{F2} of the second electrode 25) before electric dipole formation (in other words, in a state where there is no vacuum level shift)”. Note that in the present embodiment, “before electric dipole formation” refers to “before forming the electric dipoles 71 and 1′”.

Note that in FIG. 25, an example is given of a case in which the position (position of the lower end of the conduction band and the upper end of the valence band) of the bands of the oxide layers 324a, 324b, 124a, and 124b before the vacuum level shift is caused by the electric dipoles 71 and 1′, indicated by the two-dot chain line, are the same. However, the position of the bands of oxide layers 324a, 324b, 124a, 124b are determined by the material selected for the oxide layers 324a, 324b, 124a, 124b, and thus the positions are not limited to those in example illustrated in FIG. 25. In the example illustrated in FIG. 25, an example is given of a case in which the Fermi level E_{F2}′ of the second electrode 25 after a band shift has been caused by formation of the electric dipoles 71, 1′ is positioned below the lower end of the ETL conduction band. However, the Fermi level E_{F2}′ of the second electrode 25 after the band shift may be positioned above the lower end of the ETL conduction band′ and is more preferably positioned above.

Note that in the present embodiment also, as illustrated in FIG. 25, the energy difference Ed2 (=work function of the second electrode 25) between the vacuum level and the Fermi level E_{F2}′ of the second electrode 25), the electron affinity EA1 of the electron transport layer 24e, the electron affinity EA3 of the oxide layer 124a, and the electron affinity EA4 of the oxide layer 124b have the same relationship as described in the third embodiment.

Furthermore, in the example illustrated in FIG. 25, the electron affinity EA1 of the electron transport layer 24e, the electron affinity EA2 of the light-emitting layer 24d, the electron affinity EA5 of the oxide layer 324a, and the electron affinity EA6 of the oxide layer 324b have a relationship such that (the electron affinity EA1 of the electron transport layer 24e)>(the electron affinity EA2 of the light-emitting layer 24d)>(the electron affinity EA5 of the oxide layer 324a)=(the electron affinity EA6 of the oxide layer 324b).

However, regarding the size relationship of the electron affinity EA1 of the electron transport layer 24e, the electron affinity EA2 of the light-emitting layer 24d, the electron affinity EA5 of the oxide layer 324a, and the electron affinity EA6 of the oxide layer 324b, the electron affinity EA1 of the electron transport layer 24e should be greater than the electron affinity EA2 of the light-emitting layer 24d, and the electron affinity EA2 of the light-emitting layer 24d should be greater than the electron affinity EA5 of the oxide layer 324a and the electron affinity EA6 of the oxide layer 324b. The relationship between the electron affinity EA5 of the oxide layer 324a and the electron affinity EA6 of the oxide layer 324b also varies depending on the material selected. Thus, there is no particular constraint on the size relationship between the electron affinity EA5 of the oxide layer 324a and the electron affinity EA6 of the oxide layer 324b. Accordingly, the electron affinity of each layer may be greater in order of the electron transport layer 24e, the light-emitting layer 24d, the oxide layer 324a, and the oxide layer 324b, and may be greater in order from the electron transport layer 24e, the light-emitting layer 24d, the oxide layer 324b, and the oxide layer 324a. In either case, the electric dipole 71 can reduce the electron injection barrier height between the electron transport layer 24e and the light-emitting layer 24d from the energy difference ΔEc to the energy difference ΔEc′.

Note that in the example illustrated in FIG. 25, (the electron affinity EA3 of the oxide layer 124a)=(the electron affinity EA4 of the oxide layer 124b)=(the electron affinity EA5 of the oxide layer 324a)=(the electron affinity EA6 of the oxide layer 324b) hold true. However, because the size relationship between the electron affinity EA3 of the oxide layer 124a and the electron affinity EA4 of the oxide layer 124b and the electron affinity EA5 of the oxide layer 324a and the electron affinity EA6 of the oxide layer 324b is determined by the material selected, there is no particular restriction on the size relationship of the electron affinities EA3 to EA6.

Also, as illustrated in FIG. 25, in a similar manner to the oxide layer 124a and the oxide layer 124b, the energy difference between the lower end of the conduction band and the upper end of the valence band in the oxide layer 324a and the oxide layer 324b is greater than the energy difference between the upper end of the ETL valence band and the lower end of the ETL conduction band in the electron transport layer 24e. Thus, the carrier density (electron density) of the oxide layer 324a and the oxide layer 324b is less than the carrier density (electron density) of the electron transport layer 24e, and the oxide layer 324a and the oxide layer 324b are better at insulating than the electron transport layer 24e. Note that herein, the energy difference between the lower end of the conduction band and the upper end of the valence band in the oxide layer 324a and the oxide layer 324b refers to the energy difference between the lower end of the conduction band and the upper end of the valence band in the oxide layer 324a and the energy difference between the lower end of the conduction band and the upper end of the valence band in the oxide layer 324b. Note that, in the example illustrated in FIG. 25, the energy difference between the lower end of the conduction band and the upper end of the valence band in the oxide layer 324a is equal to the energy difference between the lower end of the conduction band′ and the upper end of the valence band′ of the oxide layer 324a. However, no such limitation is intended. The size relationship between the energy difference between the lower end of the conduction band and the upper end of the valence band in the oxide layer 324a and the energy difference between the lower end of the conduction band′ and the upper end of the valence band′ of the oxide layer 324a is determined by the materials selected for the oxide layer 324a and the oxide layer 324b, and thus there are no particular restrictions. Also, as described above, the carrier density (electron density) of the oxide layer 324a and the oxide layer 324b is less than the carrier density (electron density) of the electron transport layer 24e. Accordingly, electron conduction by tunneling occurs in the oxide layer 324a and the oxide layer 324b in a similar manner to the oxide layer 124a and the oxide layer 124b.

Note that, of the oxide layers 124a, 124b, 324a, and 324b, the oxide layer 124a and the oxide layer 124b are as described in the third and fourth embodiments. Thus, the description of the oxide layer 124a and the oxide layer 124b will be omitted below. In a similar manner to the oxide layer 124a and the oxide layer 124b, a material similar to that used for the oxide layer 24a and the oxide layer 24b described in the first and second embodiment can be used for the oxide layer 324a and the oxide layer 324b. For example, for the oxides forming the oxide layer 324a and the oxide layer 324b, of the two oxides selected from the inorganic oxides listed in FIG. 5, the oxide with the smaller oxygen atom density should be selected as the oxide to form the oxide layer 324b, and the oxide with the larger oxygen atom density should be selected as the oxide to form the oxide layer 324a. Also, a composite oxide containing multiple cations of the oxides listed in FIG. 5 can be used as the oxides for forming the oxide layer 324a and the oxide layer 324b in a similar manner to the oxide layers 124a and 124b. In addition, by reducing the oxygen composition ratio to the cation, the oxygen atom density of the oxide may be reduced.

By the oxygen atom density of the oxide layer 324b being less than the oxygen atom density of the oxide layer 324a, the electric dipole 71 having a dipole moment including a component oriented in the direction of the oxide layer 324a from the oxide layer 324b is more easily formed, and electron injection efficiency can be improved.

A combination of the oxide forming the oxide layer 324a and the oxide forming the oxide layer 324b can be used in a similar manner to the combinations listed in FIG. 15, for example. In FIG. 15, “oxide layer 124b” and “oxide layer 124a” can be read as “oxide layer 324b” and “oxide layer 324a”, respectively. Note that in FIG. 6, “oxide layer 24a” and “oxide layer 24b” can also be read as “oxide layer 324a” and “oxide layer 324b”, respectively. In a similar manner to the oxide layer 124a and the oxide layer 124b, the oxide layer 324a and the oxide layer 324b may be formed of one type of oxide, or may be formed of a plurality of oxides. That is, the oxide layers 324a, 324b may be formed of a composition formed by mixing a plurality of oxides, or as described above, may be formed of a composite oxide or the like containing two or more types of cations of the exemplified oxide.

Also, the oxide layer 324b (more precisely, the oxide forming the oxide layer 324b) may include cations contained in the oxide layer 324a (in other words, cations contained in the oxide forming the oxide layer 324a), and the oxide layer 324a (more precisely, the oxide forming the oxide layer 324a) may include cations contained in the oxide layer 324b (in other words, cations contained in the oxide forming the oxide layer 324b). In either case, by the oxide layer 324a and the oxide layer 324b including a common cation, a structure that alleviates lattice mismatch between the oxide layer 324a and the oxide layer 324b can be obtained. As a result, defects due to lattice mismatch can be minimized or prevented and the electric dipole 71 having a dipole moment including a component orientated in the direction from the oxide layer 324b to the oxide layer 324a can be more efficiently formed. This allows for more efficient electron injection from the electron transport layer 24e to the light-emitting layer 24d.

The oxygen atom density of the oxide layer 324b is preferably 95% or less, more preferably 90% or less, even more preferably 85% or less, even more preferably 80% or less, even more preferably 75% or less, and even more preferably 70% or less of the oxygen atom density of the oxide layer 324a. Also, the oxygen atom density of the oxide layer 324b is preferably 50% or less of the oxygen atom density of the oxide layer 324a.

The film thickness of the oxide layer 324a and the film thickness of the oxide layer 324b is preferably from 0.2 nm to 5 nm, and the total film thickness of the oxide layer 324a and the oxide layer 324b is preferably is from 0.4 nm to 5 nm.

In this manner, the oxygen atom density of the oxide layer 324a and the oxygen atom density of the oxide layer 324b can be set in a similar manner to the oxygen atom density of the oxide layer 124a and the oxygen atom density of the oxide layer 124b, respectively, of the third embodiment. Also, the film thickness of oxide layer 324a and the film thickness of the oxide layer 324b can be set in a similar manner to the film thickness of the oxide layer 124a and the film thickness of the oxide layer 124b, respectively, of the third embodiment. In other words, in the description of the oxygen atom density of the oxide layer 124a and the oxygen atom density of the oxide layer 124b in the third embodiment, “oxide layer 124a”, “oxide layer 124b”, and “electric dipole 1” can be read as “oxide layer 324a”, “oxide layer 324b”, and “electric dipole 71”, respectively.

Also, thought a detailed description is omitted, the oxide layer 324a may be formed of an amorphous oxide or may be formed with at least a portion of the contact surface with oxide layer 324b formed of a polycrystalline oxide. Also, the oxide layer 324b may also be formed of an amorphous oxide or may be formed with at least a portion of the contact surface with oxide layer 324a formed of a polycrystalline oxide. Also, at least at the contact surface between the oxide layer 324a and the oxide layer 324b, at least one of the oxide layer 324a or the oxide layer 324b may include grains. In addition, at least one layer of the oxide layer 324a or the oxide layer 324b is preferably a continuous film, and at least the layer, from among the oxide layer 324a and the oxide layer 324b, on the upper layer side is more preferably a continuous film.

In other words, in the description of the crystalline state of the oxide layer 24a and the oxide layer 24b and the shape of the oxide layer 24a and oxide layer 24b in the first embodiment, “oxide layer 24a”, “oxide layer 24b”, “electric dipole 1”, “Fermi level E_{F1}′ of the first electrode 22”, “upper end of HTL valence band”, “energy difference ΔE_{F1}′”, “hole”, “light-emitting element 5”, and “FIG. 2” can be read as “oxide layer 324a”, “oxide layer 324b”, “electric dipole 71”, “lower end of the conduction band of the electron transport layer 24e (ETL conduction band)”, “lower end of the conduction band of the light-emitting layer 24d (light-emitting layer conduction band)”, “energy difference ΔEc′”, “electron”, “light-emitting element 555”, and “FIG. 19”, respectively.

In a similar manner to the oxide layer 124a and the oxide layer 124b, the oxide layer on the lower layer side, from among the oxide layer 324a and the oxide layer 324b, may be formed into island shapes.

### Eighth Embodiment

FIG. 26 is an energy band diagram for describing an electron injection barrier between the second electrode 25 (cathode) and the electron transport layer 24e and an electron injection barrier between the electron transport layer 24e and the light-emitting layer 24d in a light-emitting element 655 according to the present embodiment.

A light-emitting device according to the present embodiment includes the light-emitting element 655 illustrated in FIG. 26 as a light-emitting element in the light-emitting device (for example, the display device 2) according to the first embodiment. The light-emitting element 655 according to the present embodiment has the same configuration as the light-emitting element 555 according to the seventh embodiment except that the electron transport layer 24e is formed of an oxide.

In the example described below, the light-emitting element 555 has the same layered structure as the layered structure illustrated in FIG. 23. As illustrated in FIG. 26, the oxide layer 124a and the oxide layer 124b are layered in this order from the electron transport layer 24e side (in other words, the first electrode 22 side) between the electron transport layer 24e and the second electrode 25. Also, the oxide layer 324a and the oxide layer 324b are layered in this order from the light-emitting layer 24d side (in other words, the first electrode 22 side) between the light-emitting layer 24d and the electron transport layer 24e. Note that the oxide layer 324a, the oxide layer 324b, the electron transport layer 24e, the oxide layer 124a, and the oxide layer 124b are layered in this order and in contact with each other. As described above, the oxygen atom density of the oxide layer 124a and the oxygen atom density of the oxide layer 124b are different. Also, the oxygen atom density of the oxide layer 324a and the oxygen atom density of the oxide layer 324b are different. Furthermore, the oxygen atom density of the electron transport layer 24e is different from the oxygen atom density of the oxide layer 324b adjacent to the electron transport layer 24e. Furthermore, the oxygen atom density of the electron transport layer 24e is different from the oxygen atom density of the oxide layer 124a adjacent to the electron transport layer 24e. In this case, oxygen atom movement occurs not only at the interface between the oxide layer 324a and the oxide layer 324b and the interface between the oxide layer 124a and the oxide layer 124b, but also at the interface between the oxide layer 324b and the electron transport layer 24e and the interface between the electron transport layer 24e and the oxide layer 124a, and the electric dipole is easily formed.

In this case, as described in the seventh embodiment, the oxygen atom density of the oxide layer 124b is preferably less than the oxygen atom density of the oxide layer 124a, and the oxygen atom density of the oxide layer 324b is preferably less than the oxygen atom density of the oxide layer 324a. Also, as described in the fourth embodiment, the oxygen atom density of the oxide layer 124a is preferably less than the oxygen atom density of the electron transport layer 24e. Furthermore, the oxygen atom density of the electron transport layer 24e is preferably less than the oxygen atom density of the oxide layer 324b. In the example of the present embodiment described below, (the oxygen atom density of the oxide layer 324a)>(the oxygen atom density of the oxide layer 324b)>(the oxygen atom density of the electron transport layer 24e)>(the oxygen atom density of the oxide layer 124a)>(the oxygen atom density of the oxide layer 124b) holds true.

In this case, as in the seventh embodiment, oxygen atoms easily move from the oxide layer 324a toward the oxide layer 324b at the interface between the oxide layer 324a and the oxide layer 324b, and the oxygen atoms easily move from the oxide layer 124a toward the oxide layer 124b at the interface between the oxide layer 124a and the oxide layer 124b. Furthermore, as in the fourth embodiment, oxygen atoms easily move from the electron transport layer 24e toward the oxide layer 124a at the interface between the electron transport layer 24e and the oxide layer 124a. Also, in the present embodiment, oxygen atoms easily move at the interface between the oxide layer 324b and the electron transport layer 24e from the oxide layer 324b toward the electron transport layer 24e. Thus, as illustrated in FIG. 26, as in the seventh embodiment, the electric dipole 71 having a dipole moment including a component orientated in the direction from the oxide layer 324b to the oxide layer 324a is formed at the interface between the oxide layer 324a and the oxide layer 324b, and the electric dipole 1′ having a dipole moment including a component orientated in the direction from the oxide layer 124b to the oxide layer 124a is formed at the interface between the oxide layer 124a and the oxide layer 124b. Also, as in the fourth embodiment, at the interface between the electron transport layer 24e and the oxide layer 124a, an electric dipole 41 having a dipole moment including a component oriented toward the electron transport layer 24e from the oxide layer 124a is formed. Furthermore, in the present embodiment, at the interface between the oxide layer 324b and the electron transport layer 24e, an electric dipole 81 having a dipole moment including a component orientated from the electron transport layer 24e toward the oxide layer 324b is formed.

Note that in the light-emitting element 655 of the present embodiment, the mechanism by which the oxygen atoms move at the interface between the oxide layer 324b and the electron transport layer 24e adjacent to one another is the same as the mechanism by which the oxygen atoms move at the interface between the oxide layer 24a and the oxide layer 24b as illustrated in (a) of FIG. 4. Thus, in (a) and (b) of FIG. 4, “24a”, “24b”, and “1” can, in this order, be read as “324b”, “24e”, and “81”.

When the electric dipoles 71, 81, 41, and 1′ are formed in this manner, as illustrated in FIG. 26, a vacuum level shift caused by the electric dipole 71, the electric dipole 81, the electric dipole 41, and the electric dipole 1′ occurs at the interface between the oxide layer 324a and the oxide layer 324b, which is the interface where the electric dipole 71 is formed, at the interface between the oxide layer 324b and the electron transport layer 24e, which is the interface where the electric dipole 81 is formed, at the interface between the electron transport layer 24e and the oxide layer 124a, which is the interface where the electric dipole 41 is formed, and at the interface between the oxide layer 124a and the oxide layer 124b, which is the interface where the electric dipole 1′ is formed, respectively. As a result, as illustrated in FIG. 26, the position of the band on the second electrode 25 side moves upward with respect to the position of the band on the first electrode 22 side at the interfaces described above where the electric dipoles 71, 81, 41, and 1′ are formed. That is, in the case of the example illustrated in FIG. 26, the electric dipole 71 causes the position of the band of the oxide layer 324b, the position of the band of the electron transport layer 24e, the position of the band of the oxide layer 124a, the position of the band of the oxide layer 124b, and the position of the band of the second electrode 25 to move upward (band shift) with respect to the position of the band of the light-emitting layer 24d and the position of the band of the oxide layer 324a. Also, the electric dipole 81 causes the position of the band of the electron transport layer 24e, the position of the band of the oxide layer 124a, the position of the band of the oxide layer 124b, and the position of the band of the second electrode 25 to move further upward (band shift) with respect to the position of the band of the light-emitting layer 24d, the position of the band of the oxide layer 324a, and the position of the band of the oxide layer 324b. Also, the electric dipole 41 causes the position of the band of the oxide layer 124a, the position of the band of the oxide layer 124b, and the position of the band of the second electrode 25 to move further upward (band shift) with respect to the position of the band of the light-emitting layer 24d, the position of the band of the oxide layer 324a, the position of the band of the oxide layer 324b, and the position of the band of the electron transport layer 24e. Also, the electric dipole 1′ causes the position of the band of the oxide layer 124b and the position of the band of the second electrode 25 to move further upward (band shift) with respect to the position of the band of the light-emitting layer 24d, the position of the band of the oxide layer 324a, the position of the band of the oxide layer 324b, the position of the band of the electron transport layer 24e, and the position of the band of the oxide layer 324a. Although not illustrated, at this time, obviously the position of the band on the first electrode 22 side includes the position of the band of the layer on the first electrode 22 side of the light-emitting layer 24d. Note that in FIG. 26, the position of the band of the Fermi level E_{F2} of the second electrode 25 before the vacuum level shift due to the electric dipoles 71, 81, 41, and 1′ is indicated by a dot-dash line, and the position of the bands of the oxide layers 324b, 124a, and 124b and the position of the band of the electron transport layer 24e before the vacuum level shift due to the electric dipoles 71, 81, 41, and 1′ is indicated by a two-dot chain line. Also, the vacuum level after the vacuum level shift due to the electric dipoles 71, 81, 41, and 1′ is indicated by a dotted line.

Specifically, when the electric dipoles 71, 81, 41, and 1′ are formed, the Fermi level E_{F2} of the second electrode 25 moves to the Fermi level E_{F2}′ of the second electrode 25, the valence band of the oxide layer 324b moves to the valence band′ of the oxide layer 324b, the ETL valence band moves to the ETL valence band′, the valence band of the oxide layer 124a moves to the valence band′ of the oxide layer 124a, and the valence band of the oxide layer 124b moves to the valence band′ of the oxide layer 124b. Also, the conduction band of the oxide layer 324b moves to the conduction band′ of the oxide layer 324b, the ETL conduction band moves to the ETL conduction band′, the conduction band of the oxide layer 124a moves to the conduction band′ of the oxide layer 124a, and the conduction band of the oxide layer 124b moves to the conduction band′ of the oxide layer 124b.

By this movement, the energy difference ΔE_{F2} between the lower end of the ETL conduction band and the Fermi level E_{F2} of the second electrode 25 becomes the energy difference ΔE_{F2}′ between the lower end of the ETL conduction band and the Fermi level E_{F2}′ of the second electrode 25. As a result, the energy difference ΔE_{F2}′ after formation of the electric dipoles 71, 81, 41, and 1′ (in other words, the electron injection barrier height from the second electrode 25 to the electron transport layer 24e after formation of the electric dipoles 71, 81, 41, and 1′) is less than the energy difference ΔE_{F2} (in other words, the electron injection barrier height from the second electrode 25 to the electron transport layer 24e in a case where the material of the electron transport layer 24e is not an oxide or the oxide layers 324a, 324b, 124a, and 124b are not formed). Furthermore, by this movement, the energy difference ΔEc between the lower end of the light-emitting layer conduction band and the lower end of the ETL conduction band becomes an energy difference ΔEc′ between the lower end of the light-emitting layer conduction band and the lower end of the ETL conduction band′. As a result, the energy difference ΔEc′ after formation of the electric dipoles 71, 81, 41, and 1′ (in other words, the electron injection barrier height from the electron transport layer 24e to the light-emitting layer 24d after formation of the electric dipoles 71, 81, 41, and 1′) is less than the energy difference ΔEc (in other words, the electron injection barrier height from the electron transport layer 24e to the light-emitting layer 24d in a case where the material of the electron transport layer 24e is not an oxide or the oxide layers 324a, 324b, 124a, and 124b are not formed).

In a similar manner to the light-emitting element 555 of the seventh embodiment, in a case where the film thickness of the oxide layer 124a and the oxide layer 124b is sufficiently thin, because the electrons have conductivity via tunneling of the oxide layer 124b and oxide layer 124a, the electron injection barrier height between the second electrode 25 and the electron transport layer 24e is effectively the energy difference ΔE_{F2}′ between the lower end of the conduction band (lower end of the ETL conduction band) of the electron transport layer 24e and the Fermi level E_{F2}′ of the second electrode 25 after electric dipole formation. Also, in a similar manner to the light-emitting element 555 of the seventh embodiment, in a case where the film thickness of the oxide layer 324a and the oxide layer 324b is sufficiently thin, because the electrons have conductivity via tunneling of the oxide layer 324a and oxide layer 324b, the electron injection barrier height between the electron transport layer 24e and the light-emitting layer 24d is effectively the energy difference ΔEc′ between the lower end of the conduction band of the light-emitting layer (lower end of the light-emitting layer conduction band) and the lower end of the conduction band of the electron transport layer 24e (lower end of the ETL conduction band′) after electric dipole formation. According to the present embodiment, by forming the oxide layers 324a, 324b, 124a, and 124b as described above, the electron injection barrier height between the second electrode 25 and the electron transport layer 24e and the electron injection barrier height between the electron transport layer 24e and the light-emitting layer 24d is reduced, allowing for more efficient electron injection to the light-emitting layer 24d.

Note that in the present disclosure, the energy difference ΔEc′ indicates the “energy difference between the lower end of the conduction band of the light-emitting layer 24d and the lower end of the conduction band of the electron transport layer 24e after electric dipole formation”. Thus, in the present embodiment, “after electric dipole formation” refers to “after formation of the electric dipoles 71, 81, 41, and 1′”, and “the energy difference between the lower end of the conduction band of the light-emitting layer 24d and the lower end of the conduction band of the electron transport layer 24e after electric dipole formation” refers to “the energy difference between the lower end of the light-emitting layer conduction band and the lower end of the ETL conduction band′ after formation of the electric dipoles 71, 81, 41, and 1′” as described above.

Similarly, in the present disclosure, the energy difference ΔEc indicates the “energy difference between the lower end of the conduction band of the light-emitting layer 24d (in other words, the lower end of the light-emitting layer conduction band) and the lower end of the conduction band of the electron transport layer 24e (in other words, lower end of the ETL conduction band), before formation of the electric dipole (in other words, in a state where there is no vacuum level shift)”. Note that in the present embodiment, “before electric dipole formation” refers to “before forming the electric dipoles 71, 81, 41, and 1′”.

Also, in the present disclosure, the energy difference ΔE_{F2}′ indicates the “energy difference between the lower end of the conduction band of the electron transport layer 24e and the Fermi level of the second electrode 25 after electric dipole formation”. Accordingly, in the present embodiment, the energy difference ΔE_{F2}′ indicates the “energy difference between the lower end of the ETL conduction band′ and the Fermi level E_{F2}′ of the second electrode 25 after formation of the electric dipoles 71, 81, 41, and 1′”.

In a similar manner, in the present disclosure, the energy difference ΔE_{F2}′ indicates the “energy difference between the lower end of the conduction band (in other words, the lower end of the ETL conduction band) of the electron transport layer 24e and the Fermi level of the second electrode 25 (in other words, the Fermi level E_{F2} of the second electrode 25) before electric dipole formation (in other words, in a state where there is no vacuum level shift)”. Note that in the present embodiment, “before electric dipole formation” refers to “before forming the electric dipoles 71, 81, 41, and 1′”.

Note that in FIG. 26, an example is given of a case in which the position (position of the lower end of the conduction band and the upper end of the valence band) of the bands of the oxide layers 324a, 324b, 124a, and 124b before the vacuum level shift is caused by the electric dipoles 71, 81, 41, and 1′, indicated by the two-dot chain line, are the same. However, the position of the bands of oxide layers 324a, 324b, 124a, 124b are determined by the material selected for the oxide layers 324a, 324b, 124a, 124b, and thus the positions are not limited to those in example illustrated in FIG. 26. In the present embodiment also, the Fermi level E_{F2}′ of the second electrode 25 after the band shift caused by the electric dipoles 71, 81, 41, and 1′ may be positioned above or below the lower end of the ETL conduction band′ and is more preferably positioned above.

Note that in the present embodiment also, the oxide forming the electron transport layer 24e can be selected in the same manner as in the fourth embodiment. However, in the present embodiment, an inorganic oxide having an oxygen atom density that is less than the oxygen atom density of the oxide layer 324b and greater than the oxygen atom density of the oxide layer 124a is selected as the oxide forming the electron transport layer 24e.

Note that in a case where the electron transport layer 24e is formed of an oxide as described above, the oxygen atom density of the electron transport layer 24e is preferably 95% or less, more preferably 90% or less, even more preferably 85% or less, even more preferably 80% or less, even more preferably 75% or less, and even more preferably 70% or less of the oxygen atom density of the oxide layer 324b. Also, the oxygen atom density of the electron transport layer 24e is preferably 50% or less of the oxygen atom density of the oxide layer 324b.

In this manner, the relationship between the oxygen atom density of the oxide layer 324b and the oxygen atom density of the electron transport layer 24e can be set in a similar manner to the relationship between oxygen atom density of the oxide layer 24a and the oxygen atom density of the oxide layer 24b of the first embodiment. In other words, in the description of the oxygen atom density of the oxide layer 24a and the oxygen atom density of the oxide layer 24b in the first embodiment, “oxide layer 24a”, “oxide layer 24b”, and “electric dipole 1” can be read as “oxide layer 324b”, “electron transport layer 24e”, and “electric dipole 81”, respectively.

Note that the relationship between the oxygen atom density of the electron transport layer 24e and the oxygen atom density of the oxide layer 124a in a case where the electron transport layer 24e is formed of an oxide is as described in the fourth embodiment, and the oxygen atom density of the oxide layer 124a is preferably 95% or less, more preferably 90% or less, even more preferably 85% or less, even more preferably 80% or less, even more preferably 75% or less, and even more preferably 70% or less of the oxygen atom density of the electron transport layer 24e. Also, as described in the fourth embodiment, the oxygen atom density of the oxide layer 124a is preferably 50% or greater of the oxygen atom density of the electron transport layer 24e. Note that the relationship between the oxygen atom density of the oxide layer 124a and the oxygen atom density of the oxide layer 124b, and the relationship between the oxygen atom density of the oxide layer 324a and the oxygen atom density of the oxide layer 324b is as described in the seventh embodiment.

### Ninth Embodiment

FIG. 27 is a cross-sectional view schematically illustrating an example of a schematic configuration of a light-emitting element according to the present embodiment.

A light-emitting device according to the present embodiment may include a light-emitting element 755 illustrated in FIG. 27 as a light-emitting element in the light-emitting device (for example, the display device 2) according to the first embodiment.

The light-emitting element 755 of the present embodiment includes the first electrode 22 (hole injection layer: HIL), which is an anode, the hole transport layer 24c (HTL), the light-emitting layer 24d, the electron transport layer (ETL) 24e, and the second electrode 25 (electron injection layer: EIL), which is a cathode, formed in this order from the lower layer side. The oxide layer 24a and the oxide layer 24b that is in contact with the oxide layer 24a are provided in this order from the first electrode 22 side between the first electrode 22 and the hole transport layer 24c. The oxide layer 124a and the oxide layer 124b that is in contact with the oxide layer 124a are provided in this order from the electron transport layer 24e side (in other words, the first electrode 22 side) between the electron transport layer 24e and the second electrode 25. Note that the layering order from the first electrode 22 to the second electrode 25 may be reversed.

The oxide layers 24a and 24b are the same as the oxide layers 24a and 24b in the light-emitting element 5 of the first embodiment. Also, the oxide layers 124a and 124b are the same as the oxide layers 124a and 124b in the light-emitting element 155 of the third embodiment. Furthermore, each layer other than the oxide layers 24a, 24b, 124a, and 124b in the light-emitting element 755 are as described in the first and third embodiments.

Accordingly, it can be said that when the light-emitting element 5 according to the first embodiment is used as a reference for comparison (in other words, a basic configuration), the light-emitting element 755 includes the oxide layer 24a as the first oxide layer and the oxide layer 24b as the second oxide layer, as in the light-emitting element 5 of the first embodiment, as well as the oxide layer 124a and the oxide layer 124b as described in third embodiment as the third oxide layer and the fourth oxide layer respectively. Also, it can be said that when the light-emitting element 155 according to the third embodiment is used as a reference for comparison, the light-emitting element 755 includes the oxide layer 124a as the first oxide layer and the oxide layer 124b as the second oxide layer, as in the light-emitting element 155 of the third embodiment, as well as the oxide layer 24a and the oxide layer 24b as described in first embodiment as the third oxide layer and the fourth oxide layer, respectively. In other words, the light-emitting element 755 has a configuration in which the light-emitting element 5 of the first embodiment and the light-emitting element 155 of the third embodiment are combined.

As described in the first embodiment, in the light-emitting element 755, oxygen atoms move at the interface between the oxide layer 24a and the oxide layer 24b, forming the electric dipole 1, and, as described in the third embodiment, oxygen atoms move at the interface between the oxide layer 124a and the oxide layer 124b, forming the electric dipole 1′ is formed. Accordingly, with the light-emitting element 755 of the present embodiment, electron injection from the second electrode 25 to the electron transport layer 24e is more efficient than with the light-emitting element 5 of the first embodiment, and, as a result, electron injection to the light-emitting layer 24d is more efficient than with the light-emitting element 5 of the first embodiment. Also, with the light-emitting element 755 of the present embodiment, hole injection from the first electrode 22 to the hole transport layer 24c is more efficient than with the light-emitting element 155 of the third embodiment, and, as a result, hole injection to the light-emitting layer 24d is more efficient than with the light-emitting element 155 of the third embodiment.

As described above, the light-emitting element 755 can combine the effects described in the first embodiment and the effects described in the third embodiment, and both hole injection and electron injection to the light-emitting layer 24d can easily occur together, and a better luminous efficiency can be achieved. Description on other points are as in the first and third embodiment, and thus descriptions thereof will be omitted here.

Note that, in the light-emitting element 755, in a case where the hole transport layer 24c is formed of an oxide, the electric dipole 31 can be formed at the interface between the oxide layer 24b and the hole transport layer 24c, as described in the second embodiment. At this time, if the oxygen atom density of the hole transport layer 24c is less than the oxygen atom density of the oxide layer 24b, more efficient hole injection is possible.

Note that, in the light-emitting element 755, in a case where the electron transport layer 24e is formed of an oxide, the electric dipole 41 can be formed at the interface between the electron transport layer 24e and the oxide layer 124a, as described in the fourth embodiment. At this time, if the oxygen atom density of the oxide layer 124a is less than the oxygen atom density of the electron transport layer 24e, more efficient electron injection is possible.

Also, FIG. 28 is a cross-sectional view schematically illustrating an example of a schematic configuration of another light-emitting element according to the present embodiment.

A light-emitting device according to the present embodiment may include a light-emitting element 855 illustrated in FIG. 28 as a light-emitting element in the light-emitting device (for example, the display device 2) according to the first embodiment.

The light-emitting element 855 of the present embodiment includes the first electrode 22 (hole injection layer: HIL), which is an anode, the hole transport layer 24c (HTL), the light-emitting layer 24d, the electron transport layer (ETL) 24e, and the second electrode 25 (electron injection layer: EIL), which is a cathode, formed in this order from the lower layer side. The oxide layer 24a and the oxide layer 24b that is in contact with the oxide layer 24a are provided in this order from the first electrode 22 side between the first electrode 22 and the hole transport layer 24c. The oxide layer 224a and the oxide layer 224b that is in contact with the oxide layer 224a are provided in this order from the hole transport layer 24c side (in other words, the first electrode 22 side) between the hole transport layer 24c and the light-emitting layer 24d. The oxide layer 324a and the oxide layer 324b that is in contact with the oxide layer 324a are provided in this order from the light-emitting layer 24d side (in other words, the first electrode 22 side) between the light-emitting layer 24d and the electron transport layer 24e. The oxide layer 124a and the oxide layer 124b that is in contact with the oxide layer 124a are provided in this order from the electron transport layer 24e side (in other words, the first electrode 22 side) between the electron transport layer 24e and the second electrode 25. Note that the layering order from the first electrode 22 to the second electrode 25 may be reversed.

The oxide layers 24a and 24b are the same as the oxide layers 24a and 24b in the light-emitting element of the first, second, fifth, and sixth embodiments. The oxide layers 124a and 124b are the same as the oxide layers 124a and 124b in the light-emitting element of the third, fourth, seventh, and eighth embodiments. The oxide layers 224a and 224b are the same as the oxide layers 224a and 224b in the light-emitting element of the fifth and sixth embodiments. The oxide layers 324a and 324b are the same as the oxide layers 324a and 324b in the light-emitting element of the seventh and eighth embodiments. Furthermore, each layer other than the oxide layers 24a, 24b, 124a, 124b, 224a, 224b, 324a, and 324b in the light-emitting element 855 are as described in the first to eighth embodiments. Accordingly, a description thereof is omitted. The hole transport layer 24c may be a layer formed of an oxide as described in the second and sixth embodiments, or may be a layer formed of a material other than an oxide. The electron transport layer 24e may be a layer formed of an oxide as described in the fourth and eighth embodiments, or may be a layer formed of a material other than an oxide.

It can be said that when the light-emitting element 755 illustrated in FIG. 27 is used as a reference for comparison, compared to the light-emitting element 755 illustrated in FIG. 27, the light-emitting element 855 further includes the oxide layer 224a and the oxide layer 224b as the fifth oxide layer and the sixth oxide layer respectively, as well as the oxide layer 324a and the oxide layer 324b as the seventh oxide layer and the eighth oxide layer respectively. Also, it can be said that when the light-emitting element 355 of the fifth embodiment or the light-emitting element 455 of the sixth embodiment is used as a reference for comparison, compared to the light-emitting element 355 of the fifth embodiment or the light-emitting element 455 of the sixth embodiment, the light-emitting element 855 further includes the oxide layer 324a and the oxide layer 324b as the fifth oxide layer and the sixth oxide layer respectively, as well as the oxide layer 124a and the oxide layer 124b as the seventh oxide layer and the eighth oxide layer respectively. In addition, the light-emitting element 855 can expressed differently based on comparison of the light-emitting device according to any of embodiments 1 to 4, 7, and 8, for example. Note that in the present disclosure, the first oxide layer to the eighth oxide layer are names for distinguishing the respective oxide layers without using a component number and do not mean the first to eight in terms of ordinal numbers. In other words, as described with the examples of the light-emitting element 755 and 855, the first oxide layer to the eighth oxide layer do not themselves indicate a specific oxide layer, and the ordinal numbers are there to distinguish an oxide layer from an oxide layer described before it.

In addition, regarding the oxide layers 24a, 24b, 124a, 124b, 224a, 224b, 324a, and 324b, of the adjacent pairs of oxide layer 24a and 24b, oxide layer 224a and 224b, oxide layer 324a and 324b, and oxide layer 124a and 124b, one pair of oxide layers or more may be omitted as appropriate. In addition, at least one of the hole transport layer 24c or the electron transport layer 24e may be formed of an oxide or a material other than an oxide. In other words, the first to eighth embodiments may be combined in any way.

As described above, each layer of the light-emitting element according to each of the embodiments can be combined as appropriate, and, depending on the combination, can provide a combination of the effects described in the embodiments in a manner such that the light-emitting element and the display device 2, in which at least one of hole injection or electron injection easily occurs and better luminous efficiency can be achieved, can be provided.

### Tenth Embodiment

In each of the embodiments described above, the description focused on how, in order to form an electric dipole having a dipole moment in a direction which reduces the barrier height of at least one of the hole injection barrier or the electron injection barrier, the density of the oxygen atoms (oxygen atom density) of each layer (the oxide layers 24a, 24b, 124a, 124b, 224a, 224b, 324a, 324b, the hole transport layer 24c, and/or the electron transport layer 24e) formed of an oxide in the light-emitting element is determined so that at least one of the efficiency of hole injection or the electron injection efficiency is improved and the luminous efficiency is enhanced.

However, the embodiments described above are not limited thereto, and the oxygen atom density of each layer formed of oxide described above may be set such that at least one of the electric dipole 1, 1′, 31, 41, 51, 61, 71, or 81 has a dipole moment with the reversed orientation of that in the embodiments described above. Also, at least one of the electric dipole 1, 1′, 31, 41, 51, 61, 71, or 81 may have a dipole moment with a component in the same orientation as in the embodiments described above.

In the light-emitting element, for example, in a case where the energy difference ΔE_{F2}>the energy difference ΔE_{F1} holds true, hole injection tends to be excessive with respect to electron injection. In a similar manner, for example, in a case where the energy difference ΔEc>the energy difference ΔEv holds true, hole injection tends to be excessive with respect to electron injection. In the case of excessive hole injection, for example, in first to ninth embodiment, the orientation of the dipole moment of the electric dipole may be reversed by reversing any of the size relationships of the oxygen atom densities of the layers formed of an oxide described above. For example, in the first embodiment, by reversing the size relationship between the oxygen atom density of the oxide layer 24a and the oxygen atom density of the oxide layer 24b, the orientation of the dipole moment of the electric dipole 1 may be reversed. Note that although the electric dipole 1 of the first embodiment is exemplified here, the same applies to the electric dipole of other embodiments. In this case, the energy difference ΔE_{F1}′>the energy difference ΔE_{F1} and/or the energy difference ΔEv′>the energy difference ΔEv holds true, and excessive hole injection can be suppressed. As a result, unbalance between hole injection and electron injection is suppressed, and long-term reliability is improved. That is, the luminous efficiency after aging is enhanced.

Also, in the light-emitting element, for example, in a case where the energy difference ΔE_{F2}<the energy difference ΔE_{F1} holds true, electron injection tends to be excessive with respect to hole injection. In a similar manner, for example, in a case where the energy difference ΔEc<the energy difference ΔEv holds true, electron injection tends to be excessive with respect to hole injection. In the case of excessive electron injection, for example, in first to ninth embodiment, the orientation of the dipole moment of the electric dipole may be reversed by reversing any of the size relationships of the oxygen atom densities of the layers formed of an oxide described above. In this case, the energy difference ΔE_{F2}′>the energy difference ΔE_{F2} and/or the energy difference ΔEc′>the energy difference ΔEc holds true, and excessive electron injection can be suppressed. As a result, unbalance between hole injection and electron injection is suppressed, and long-term reliability is improved. That is, the luminous efficiency after aging is enhanced.

Also, regarding the plurality of electric dipoles, by reversing the orientation of at least one dipole moment to the opposite to the orientation of the other dipole moment/s, the direction of the shift of the vacuum level caused by the electric dipoles is reversed, and the amount of shift of the vacuum level as a whole can be finely controlled. For example, in the second embodiment, by the electric dipole 1 and the electric dipole 31 having dipole moments of reversed orientation, the direction of the shift of the vacuum level caused by the electric dipole 1 and the direction of the shift of the vacuum level caused by the electric dipole 31 are reversed from one another, and the amount of shift of the vacuum level as a whole can be finely controlled. In this case, the amount of hole injection from the first electrode 22 to the hole transport layer 24c can be finely controlled, and as a result, the amount of hole injection to the light-emitting layer 24d can be finely controlled. Also, for example, in the sixth embodiment, by reversing the orientation of the electric dipole moments of at least one or more of the electric dipole 1, the electric dipole 31, the electric dipole 61, or the electric dipole 51, the amount of shift of the vacuum level as a whole can be further finely controlled. In this case, the amount of hole injection from the first electrode 22 to the light-emitting layer 24d via the hole transport layer 24c can be further finely controlled. Note that although the electric dipoles 1 and 31 of the second embodiment and the electric dipoles 1, 31, 61, and 51 of the sixth embodiment are exemplified here, the same applies to the electric dipoles of other embodiments. Thus, in each embodiment, the size relationship of the oxygen atom density of the layer formed of an oxide layer is partially reversed, and the orientation of at least one dipole moment is reversed to the orientation of the another dipole moment/s. Thus, the direction of the shift of the vacuum level caused by at least one electric dipole can be reversed with respect to the direction of the shift of the vacuum level by another electric dipole/s. As a result, the amount of shift of the vacuum level as a whole can be finely controlled, so the controllability of the energy difference of at least one of the energy differences ΔE_{F1}′, ΔE_{F2}′, ΔEv′, or ΔEc′ is improved and control of the hole injection amount and/or the electron injection amount is facilitated. Thus, balance between hole injection and electron injection is easily obtained, and long-term reliability is improved. That is, the luminous efficiency after aging is enhanced.

Note that a state in which the efficiency of hole injection and the electron injection efficiency are improved and a balance between hole injection and electron injection is obtained is most preferable. In other words, the carrier injection barrier is preferably reduced, and the orientation of the electric dipoles described in the first to ninth embodiments is preferred.

Note that in a case where the energy difference ΔE_{F1}′<the energy difference ΔE_{F1}, and the energy difference ΔEv′<the energy difference ΔEv holds true, efficient hole injection to the light-emitting layer 24d is possible.

Also, in a case where the energy difference ΔE_{F1}′>the energy difference ΔE_{F1}, and the energy difference ΔEv′>the energy difference ΔEv holds true, excessive hole injection to the light-emitting layer 24d can be suppressed. Thus, an unbalance between hole injection and electron injection is suppressed, and long-term reliability is enhanced.

Also, in a case where the energy difference ΔE_{F1}′>the energy difference ΔE_{F2}, and the energy difference ΔEv′<the energy difference ΔEv, or the energy difference ΔE_{F1}′<the energy difference ΔE_{F1}, and the energy difference ΔEv′>the energy difference ΔEv holds true, the amount of hole injection to the light-emitting layer 24d can be finely controlled. Thus, balance between hole injection and electron injection can be easily obtained, and long-term reliability is enhanced.

Note that in a case where the energy difference ΔE_{F2}′<the energy difference ΔE_{F2}, and the energy difference ΔEc′<the energy difference ΔEc holds true, efficient electron injection to the light-emitting layer 24d is possible.

Also, in a case where the energy difference ΔE_{F2}′>the energy difference ΔE_{F2}, and the energy difference ΔEc′>the energy difference ΔEc holds true, excessive electron injection to the light-emitting layer 24d can be suppressed. Thus, an unbalance between hole injection and electron injection is suppressed, and long-term reliability is enhanced.

Also, in a case where the energy difference ΔE_{F2}′>the energy difference ΔE_{F2}, and the energy difference ΔEc′<the energy difference ΔEc, or the energy difference ΔE_{F2}′<the energy difference ΔE_{F2}, and the energy difference ΔEc′>the energy difference ΔEc holds true, the amount of electron injection to the light-emitting layer 24d can be finely controlled. Thus, balance between hole injection and electron injection can be easily obtained, and long-term reliability is enhanced.

As described above, the light-emitting element according to the present disclosure may have any one of the following configurations (1) to (40), as in the first to ninth embodiments. Accordingly, the injection barrier of the holes and/or electrons serving as the carrier can be reduced, and the injection efficiency of the holes and/or electrons can be improved, so it is possible to realize high luminous efficiency. That is, hole injection or electron injection to the light-emitting layer can be effectively controlled, so it is possible to achieve high luminous efficiency.

(1) The first electrode 22, the oxide layer 24a, the oxide layer 24b, the hole transport layer 24c, the light-emitting layer 24d, the electron transport layer 24e, and the second electrode 25 are provided in this order from the upper layer side or the lower layer side, and (the oxygen atom density of the oxide layer 24a)>(the oxygen atom density of the oxide layer 24b).

(2) The first electrode 22, the oxide layer 24a, the oxide layer 24b, the hole transport layer 24c, the light-emitting layer 24d, the electron transport layer 24e, and the second electrode 25 are provided in this order from the upper layer side or the lower layer side, the hole transport layer 24c is formed of an oxide, and (the oxygen atom density of the oxide layer 24a)>(the oxygen atom density of the oxide layer 24b)>(the oxygen atom density of the hole transport layer 24c).

(3) The first electrode 22, the hole transport layer 24c, the light-emitting layer 24d, the electron transport layer 24e, the oxide layer 124a, the oxide layer 124b, and the second electrode 25 are provided in this order from the upper layer side or the lower layer side, and (the oxygen atom density of the oxide layer 124a)>(the oxygen atom density of the oxide layer 124b).

(4) The first electrode 22, the hole transport layer 24c, the light-emitting layer 24d, the electron transport layer 24e, the oxide layer 124a, the oxide layer 124b, and the second electrode 25 are provided in this order from the upper layer side or the lower layer side, the electron transport layer 24e is formed of an oxide, and (the oxygen atom density of the electron transport layer 24e)>(the oxygen atom density of the oxide layer 124a)>(the oxygen atom density of the oxide layer 124b).

(5) The first electrode 22, the oxide layer 24a, the oxide layer 24b, the hole transport layer 24c, the oxide layer 224a, the oxide layer 224b, the light-emitting layer 24d, the electron transport layer 24e, and the second electrode 25 are provided in this order from the upper layer side or the lower layer side, and (the oxygen atom density of the oxide layer 24a)>(the oxygen atom density of the oxide layer 24b), and (the oxygen atom density of the oxide layer 224a)>(the oxygen atom density of the oxide layer 224b).

(6) The first electrode 22, the oxide layer 24a, the oxide layer 24b, the hole transport layer 24c, the oxide layer 224a, the oxide layer 224b, the light-emitting layer 24d, the electron transport layer 24e, and the second electrode 25 are provided in this order from the upper layer side or the lower layer side, the hole transport layer 24c is formed of an oxide, and (the oxygen atom density of the oxide layer 24a)>(the oxygen atom density of the oxide layer 24b)>(the oxygen atom density of the hole transport layer 24c)>(the oxygen atom density of the oxide layer 224a)>(the oxygen atom density of the oxide layer 224b).

(7) The first electrode 22, the hole transport layer 24c, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, and (the oxygen atom density of the oxide layer 324a)>(the oxygen atom density of the oxide layer 324b) and (the oxygen atom density of the oxide layer 124a)>(the oxygen atom density of the oxide layer 124b).

(8) The first electrode 22, the hole transport layer 24c, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the electron transport layer 24e is formed of an oxide, and (the oxygen atom density of the oxide layer 324a)>(the oxygen atom density of the oxide layer 324b)>(the oxygen atom density of the electron transport layer 24e)>(the oxygen atom density of the oxide layer 124a)>(the oxygen atom density of the oxide layer 124b).

(9) The first electrode 22, the oxide layer 24a, the oxide layer 24b, the hole transport layer 24c, the light-emitting layer 24d, the electron transport layer 24e, the oxide layer 124a, the oxide layer 124b, and the second electrode 25 are provided in this order from the upper layer side or the lower layer side, and (the oxygen atom density of the oxide layer 24a)>(the oxygen atom density of the oxide layer 24b) and (the oxygen atom density of the oxide layer 124a)>(the oxygen atom density of the oxide layer 124b).

(10) The first electrode 22, the oxide layer 24a, the oxide layer 24b, the hole transport layer 24c, the light-emitting layer 24d, the electron transport layer 24e, the oxide layer 124a, the oxide layer 124b, and the second electrode 25 are provided in this order from the upper layer side or the lower layer side, the hole transport layer 24c is formed of an oxide, and (the oxygen atom density of the oxide layer 24a)>(the oxygen atom density of the oxide layer 24b)>(the oxygen atom density of the hole transport layer 24c) and (the oxygen atom density of the oxide layer 124a)>(the oxygen atom density of the oxide layer 124b).

(11) The first electrode 22, the oxide layer 24a, the oxide layer 24b, the hole transport layer 24c, the light-emitting layer 24d, the electron transport layer 24e, the oxide layer 124a, the oxide layer 124b, and the second electrode 25 are provided in this order from the upper layer side or the lower layer side, the electron transport layer 24e is formed of an oxide, and (the oxygen atom density of the oxide layer 24a)>(the oxygen atom density of the oxide layer 24b) and (the oxygen atom density of the electron transport layer 24e)>(the oxygen atom density of the oxide layer 124a)>(the oxygen atom density of the oxide layer 124b).

(12) The first electrode 22, the oxide layer 24a, the oxide layer 24b, the hole transport layer 24c, the light-emitting layer 24d, the electron transport layer 24e, the oxide layer 124a, the oxide layer 124b, and the second electrode 25 are provided in this order from the upper layer side or the lower layer side, the hole transport layer 24c and the electron transport layer 24e are formed of an oxide, and (the oxygen atom density of the oxide layer 24a)>(the oxygen atom density of the oxide layer 24b)>(the oxygen atom density of the hole transport layer 24c) and the (oxygen atom density of the electron transport layer 24e)>(the oxygen atom density of the oxide layer 124a)>(the oxygen atom density of the oxide layer 124b).

(13) The first electrode 22, the oxide layer 24a, the oxide layer 24b, the hole transport layer 24c, the light-emitting layer 24d, the oxide layer 324a, the oxide layer 324b, the electron transport layer 24e, and the second electrode 25 are provided in this order from the upper layer side or the lower layer side, and (the oxygen atom density of the oxide layer 24a)>(the oxygen atom density of the oxide layer 24b) and (the oxygen atom density of the oxide layer 324a)>(the oxygen atom density of the oxide layer 324b).

(14) The first electrode 22, the oxide layer 24a, the oxide layer 24b, the hole transport layer 24c, the light-emitting layer 24d, the oxide layer 324a, the oxide layer 324b, the electron transport layer 24e, and the second electrode 25 are provided in this order from the upper layer side or the lower layer side, the hole transport layer 24c is formed of an oxide, and (the oxygen atom density of the oxide layer 24a)>(the oxygen atom density of the oxide layer 24b)>(the oxygen atom density of the hole transport layer 24c) and (the oxygen atom density of the oxide layer 324a)>(the oxygen atom density of the oxide layer 324b).

(15) The first electrode 22, the oxide layer 24a, the oxide layer 24b, the hole transport layer 24c, the light-emitting layer 24d, the oxide layer 324a, the oxide layer 324b, the electron transport layer 24e, and the second electrode 25 are provided in this order from the upper layer side or the lower layer side, the electron transport layer 24e is formed of an oxide, and (the oxygen atom density of the oxide layer 24a)>(the oxygen atom density of the oxide layer 24b) and (the oxygen atom density of the oxide layer 324a)>(the oxygen atom density of the oxide layer 324b)>(the oxygen atom density of the electron transport layer 24e).

(16) The first electrode 22, the oxide layer 24a, the oxide layer 24b, the hole transport layer 24c, the light-emitting layer 24d, the oxide layer 324a, the oxide layer 324b, the electron transport layer 24e, and the second electrode 25 are provided in this order from the upper layer side or the lower layer side, the hole transport layer 24c and the electron transport layer 24e are formed of an oxide, and (the oxygen atom density of the oxide layer 24a)>(the oxygen atom density of the oxide layer 24b)>(the oxygen atom density of the hole transport layer 24c) and (the oxygen atom density of the oxide layer 324a)>(the oxygen atom density of the oxide layer 324b)>(the oxygen atom density of the electron transport layer 24e).

(17) The first electrode 22, the hole transport layer 24c, the oxide layer 224a, the oxide layer 224b, the light-emitting layer 24d, the electron transport layer 24e, the oxide layer 124a, the oxide layer 124b, and the second electrode 25 are provided in this order from the upper layer side or the lower layer side, and (the oxygen atom density of the oxide layer 224a)>(the oxygen atom density of the oxide layer 224b) and (the oxygen atom density of the oxide layer 124a)>(the oxygen atom density of the oxide layer 124b).

(18) The first electrode 22, the hole transport layer 24c, the oxide layer 224a, the oxide layer 224b, the light-emitting layer 24d, the electron transport layer 24e, the oxide layer 124a, the oxide layer 124b, and the second electrode 25 are provided in this order from the upper layer side or the lower layer side, the hole transport layer 24c is formed of an oxide, and (the oxygen atom density of the hole transport layer 24c)>(the oxygen atom density of the oxide layer 224a)>(the oxygen atom density of the oxide layer 224b) and (the oxygen atom density of the oxide layer 124a)>(the oxygen atom density of the oxide layer 124b).

(19) The first electrode 22, the hole transport layer 24c, the oxide layer 224a, the oxide layer 224b, the light-emitting layer 24d, the electron transport layer 24e, the oxide layer 124a, the oxide layer 124b, and the second electrode 25 are provided in this order from the upper layer side or the lower layer side, the electron transport layer 24e is formed of an oxide, and (the oxygen atom density of the oxide layer 224a)>(the oxygen atom density of the oxide layer 224b) and (the oxygen atom density of the electron transport layer 24e)>(the oxygen atom density of the oxide layer 124a)>(the oxygen atom density of the oxide layer 124b).

(20) The first electrode 22, the hole transport layer 24c, the oxide layer 224a, the oxide layer 224b, the light-emitting layer 24d, the electron transport layer 24e, the oxide layer 124a, the oxide layer 124b, and the second electrode 25 are provided in this order from the upper layer side or the lower layer side, the hole transport layer 24c and the electron transport layer 24e is formed of an oxide, and (the oxygen atom density of the hole transport layer 24c)>(the oxygen atom density of the oxide layer 224a)>(the oxygen atom density of the oxide layer 224b) and (the oxygen atom density of the electron transport layer 24e)>(the oxygen atom density of the oxide layer 124a)>(the oxygen atom density of the oxide layer 124b).

(21) The first electrode 22, the oxide layer 24a, the oxide layer 24b, the hole transport layer 24c, the oxide layer 224a, the oxide layer 224b, the light-emitting layer 24d, the electron transport layer 24e, the oxide layer 124a, the oxide layer 124b, and the second electrode 25 are provided in this order from the upper layer side or the lower layer side, and (the oxygen atom density of the oxide layer 24a)>(the oxygen atom density of the oxide layer 24b), (the oxygen atom density of the oxide layer 224a)>(the oxygen atom density of the oxide layer 224b), and (the oxygen atom density of the oxide layer 124a)>(the oxygen atom density of the oxide layer 124b).

(22) The first electrode 22, the oxide layer 24a, the oxide layer 24b, the hole transport layer 24c, the oxide layer 224a, the oxide layer 224b, the light-emitting layer 24d, the electron transport layer 24e, the oxide layer 124a, the oxide layer 124b, and the second electrode 25 are provided in this order from the upper layer side or the lower layer side, the hole transport layer 24c is formed of an oxide, and (the oxygen atom density of the oxide layer 24a)>(the oxygen atom density of the oxide layer 24b)>(the oxygen atom density of the hole transport layer 24c)>(the oxygen atom density of the oxide layer 224a)>(the oxygen atom density of the oxide layer 224b) and (the oxygen atom density of the oxide layer 124a)>(the oxygen atom density of the oxide layer 124b).

(23) The first electrode 22, the oxide layer 24a, the oxide layer 24b, the hole transport layer 24c, the oxide layer 224a, the oxide layer 224b, the light-emitting layer 24d, the electron transport layer 24e, the oxide layer 124a, the oxide layer 124b, and the second electrode 25 are provided in this order from the upper layer side or the lower layer side, the electron transport layer 24e is formed of an oxide, and (the oxygen atom density of the oxide layer 24a)>(the oxygen atom density of the oxide layer 24b), (the oxygen atom density of the oxide layer 224a)>(the oxygen atom density of the oxide layer 224b), and (the oxygen atom density of the electron transport layer 24e)>(the oxygen atom density of the oxide layer 124a)>(the oxygen atom density of the oxide layer 124b).

(24) The first electrode 22, the oxide layer 24a, the oxide layer 24b, the hole transport layer 24c, the oxide layer 224a, the oxide layer 224b, the light-emitting layer 24d, the electron transport layer 24e, the oxide layer 124a, the oxide layer 124b, and the second electrode 25 are provided in this order from the upper layer side or the lower layer side, the hole transport layer 24c and the electron transport layer 24e are formed of an oxide, and (the oxygen atom density of the oxide layer 24a)>(the oxygen atom density of the oxide layer 24b)>(the oxygen atom density of the hole transport layer 24c)>(the oxygen atom density of the oxide layer 224a)>(the oxygen atom density of the oxide layer 224b) and (the oxygen atom density of the electron transport layer 24e)>(the oxygen atom density of the oxide layer 124a)>(the oxygen atom density of the oxide layer 124b).

(25) The first electrode 22, the oxide layer 24a, the oxide layer 24b, the hole transport layer 24c, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, and (the oxygen atom density of the oxide layer 24a)>(the oxygen atom density of the oxide layer 24b), (the oxygen atom density of the oxide layer 324a)>(the oxygen atom density of the oxide layer 324b), and (the oxygen atom density of the oxide layer 124a)>(the oxygen atom density of the oxide layer 124b).

(26) The first electrode 22, the oxide layer 24a, the oxide layer 24b, the hole transport layer 24c, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the hole transport layer 24c is formed of an oxide, and (the oxygen atom density of the oxide layer 24a)>(the oxygen atom density of the oxide layer 24b)>(the oxygen atom density of the hole transport layer 24c), (the oxygen atom density of the oxide layer 324a)>(the oxygen atom density of the oxide layer 324b), and (the oxygen atom density of the oxide layer 124a)>(the oxygen atom density of the oxide layer 124b).

(27) The first electrode 22, the oxide layer 24a, the oxide layer 24b, the hole transport layer 24c, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the electron transport layer 24e is formed of an oxide, and (the oxygen atom density of the oxide layer 24a)>(the oxygen atom density of the oxide layer 24b), (the oxygen atom density of the oxide layer 324a)>(the oxygen atom density of the oxide layer 324b)>(the oxygen atom density of the electron transport layer 24e)>(the oxygen atom density of the oxide layer 124a)>(the oxygen atom density of the oxide layer 124b).

(28) The first electrode 22, the oxide layer 24a, the oxide layer 24b, the hole transport layer 24c, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the hole transport layer 24c and the electron transport layer 24e are formed of an oxide, and (the oxygen atom density of the oxide layer 24a)>(the oxygen atom density of the oxide layer 24b)>(the oxygen atom density of the hole transport layer 24c) and (the oxygen atom density of the oxide layer 324a)>(the oxygen atom density of the oxide layer 324b)>(the oxygen atom density of the electron transport layer 24e)>(the oxygen atom density of the oxide layer 124a)>(the oxygen atom density of the oxide layer 124b).

(29) The first electrode 22, the oxide layer 24a, the oxide layer 24b, the hole transport layer 24c, the oxide layer 224a, the oxide layer 224b, the light-emitting layer 24d, the oxide layer 324a, the oxide layer 324b, the electron transport layer 24e, and the second electrode 25 are provided in this order from the upper layer side or the lower layer side, and (the oxygen atom density of the oxide layer 24a)>(the oxygen atom density of the oxide layer 24b), (the oxygen atom density of the oxide layer 224a)>(the oxygen atom density of the oxide layer 224b), and (the oxygen atom density of the oxide layer 324a)>(the oxygen atom density of the oxide layer 324b).

(30) The first electrode 22, the oxide layer 24a, the oxide layer 24b, the hole transport layer 24c, the oxide layer 224a, the oxide layer 224b, the light-emitting layer 24d, the oxide layer 324a, the oxide layer 324b, the electron transport layer 24e, and the second electrode 25 are provided in this order from the upper layer side or the lower layer side, the hole transport layer 24c is formed of an oxide, and (the oxygen atom density of the oxide layer 24a)>(the oxygen atom density of the oxide layer 24b)>(the oxygen atom density of the hole transport layer 24c)>(the oxygen atom density of the oxide layer 224a)>(the oxygen atom density of the oxide layer 224b) and (the oxygen atom density of the oxide layer 324a)>(the oxygen atom density of the oxide layer 324b).

(31) The first electrode 22, the oxide layer 24a, the oxide layer 24b, the hole transport layer 24c, the oxide layer 224a, the oxide layer 224b, the light-emitting layer 24d, the oxide layer 324a, the oxide layer 324b, the electron transport layer 24e, and the second electrode 25 are provided in this order from the upper layer side or the lower layer side, the electron transport layer 24e is formed of an oxide, and (the oxygen atom density of the oxide layer 24a)>(the oxygen atom density of the oxide layer 24b), (the oxygen atom density of the oxide layer 224a)>(the oxygen atom density of the oxide layer 224b), and (the oxygen atom density of the oxide layer 324a)>(the oxygen atom density of the oxide layer 324b)>(the oxygen atom density of the electron transport layer 24e).

(32) The first electrode 22, the oxide layer 24a, the oxide layer 24b, the hole transport layer 24c, the oxide layer 224a, the oxide layer 224b, the light-emitting layer 24d, the oxide layer 324a, the oxide layer 324b, the electron transport layer 24e, and the second electrode 25 are provided in this order from the upper layer side or the lower layer side, the hole transport layer 24c and the electron transport layer 24e are formed of an oxide, and (the oxygen atom density of the oxide layer 24a)>(the oxygen atom density of the oxide layer 24b)>(the oxygen atom density of the hole transport layer 24c)>(the oxygen atom density of the oxide layer 224a)>(the oxygen atom density of the oxide layer 224b) and (the oxygen atom density of the oxide layer 324a)>(the oxygen atom density of the oxide layer 324b)>(the oxygen atom density of the electron transport layer 24e).

(33) The first electrode 22, the hole transport layer 24c, the oxide layer 224a, the oxide layer 224b, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, and (the oxygen atom density of the oxide layer 224a)>(the oxygen atom density of the oxide layer 224b), (the oxygen atom density of the oxide layer 324a)>(the oxygen atom density of the oxide layer 324b), and (the oxygen atom density of the oxide layer 124a)>(the oxygen atom density of the oxide layer 124b).

(34) The first electrode 22, the hole transport layer 24c, the oxide layer 224a, the oxide layer 224b, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the hole transport layer 24c is formed of an oxide, and the oxygen atom density of the hole transport layer 24c)>(the oxygen atom density of the oxide layer 224a)>(the oxygen atom density of the oxide layer 224b), (the oxygen atom density of the oxide layer 324a)>(the oxygen atom density of the oxide layer 324b), and (the oxygen atom density of the oxide layer 124a)>(the oxygen atom density of the oxide layer 124b).

(35) The first electrode 22, the hole transport layer 24c, the oxide layer 224a, the oxide layer 224b, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the electron transport layer 24e is formed of an oxide, and (the oxygen atom density of the oxide layer 224a)>(the oxygen atom density of the oxide layer 224b), (the oxygen atom density of the oxide layer 324a)>(the oxygen atom density of the oxide layer 324b)>(the oxygen atom density of the electron transport layer 24e)>(the oxygen atom density of the oxide layer 124a)>(the oxygen atom density of the oxide layer 124b).

(36) The first electrode 22, the hole transport layer 24c, the oxide layer 224a, the oxide layer 224b, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the hole transport layer 24c and the electron transport layer 24e are formed of an oxide, and (the oxygen atom density of the hole transport layer 24c)>(the oxygen atom density of the oxide layer 224a)>(the oxygen atom density of the oxide layer 224b), (the oxygen atom density of the oxide layer 324a)>(the oxygen atom density of the oxide layer 324b)>(the oxygen atom density of the electron transport layer 24e)>(the oxygen atom density of the oxide layer 124a)>(the oxygen atom density of the oxide layer 124b).

(37) The first electrode 22, the oxide layer 24a, the oxide layer 24b, the hole transport layer 24c, the oxide layer 224a, the oxide layer 224b, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, and (the oxygen atom density of the oxide layer 24a)>(the oxygen atom density of the oxide layer 24b), (the oxygen atom density of the oxide layer 224a)>(the oxygen atom density of the oxide layer 224b), (the oxygen atom density of the oxide layer 324a)>(the oxygen atom density of the oxide layer 324b), and (the oxygen atom density of the oxide layer 124a)>(the oxygen atom density of the oxide layer 124b).

(38) The first electrode 22, the oxide layer 24a, the oxide layer 24b, the hole transport layer 24c, the oxide layer 224a, the oxide layer 224b, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the hole transport layer 24c is formed of an oxide, and (the oxygen atom density of the oxide layer 24a)>(the oxygen atom density of the oxide layer 24b)>(the oxygen atom density of the hole transport layer 24c)>(the oxygen atom density of the oxide layer 224a)>(the oxygen atom density of the oxide layer 224b), (the oxygen atom density of the oxide layer 324a)>(the oxygen atom density of the oxide layer 324b), and (the oxygen atom density of the oxide layer 124a)>(the oxygen atom density of the oxide layer 124b).

(39) The first electrode 22, the oxide layer 24a, the oxide layer 24b, the hole transport layer 24c, the oxide layer 224a, the oxide layer 224b, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the electron transport layer 24e is formed of an oxide, and (the oxygen atom density of the oxide layer 24a)>(the oxygen atom density of the oxide layer 24b), (the oxygen atom density of the oxide layer 224a)>(the oxygen atom density of the oxide layer 224b), and (the oxygen atom density of the oxide layer 324a)>(the oxygen atom density of the oxide layer 324b)>(the oxygen atom density of the electron transport layer 24e)>(the oxygen atom density of the oxide layer 124a)>(the oxygen atom density of the oxide layer 124b).

(40) The first electrode 22, the oxide layer 24a, the oxide layer 24b, the hole transport layer 24c, the oxide layer 224a, the oxide layer 224b, the light-emitting layer 24d, the oxide layer 324a, the oxide layer 324b, the electron transport layer 24e, the oxide layer 124a, the oxide layer 124b, and the second electrode 25 are provided in this order from the upper layer side or the lower layer side, the hole transport layer 24c and the electron transport layer 24e are formed of an oxide, and (the oxygen atom density of the oxide layer 24a)>(the oxygen atom density of the oxide layer 24b)>(the oxygen atom density of the hole transport layer 24c)>(the oxygen atom density of the oxide layer 224a)>(the oxygen atom density of the oxide layer 224b) and (the oxygen atom density of the oxide layer 324a)>(the oxygen atom density of the oxide layer 324b)>(the oxygen atom density of the electron transport layer 24e)>(the oxygen atom density of the oxide layer 124a)>(the oxygen atom density of the oxide layer 124b).

In addition, the light-emitting element according to the present disclosure may have a configuration in which one or more of the inequality signs “>” are replaced with “<” in the above-described (1) to (40), such as in the tenth embodiment. In this manner, controllability of hole injection or electron injection to the light-emitting layer is improved, allowing an unbalance between hole injection and electron injection to be suppressed and long-term reliability to be improved.

Note that the light-emitting element according to the present disclosure is not limited to the configurations described above. For example, in any one of the configurations (1) to (40), the light-emitting element according to the present disclosure may have a configuration in which all of the inequality signs “>” are replaced with “<”. In this manner, excessive hole injection and excessive electron injection to the light-emitting layer can be suppressed, allowing the long-term reliability to be enhanced.

Note that the oxygen atom density of the oxide layers in the present disclosure is a unique value for the oxide layers and applies to the oxygen atom bulk density of the material forming the oxide layers. For example, for the oxides listed in FIGS. 5, 11, and 17, the oxygen atom densities listed in FIGS. 5, 11, and 17 are applied. The oxygen atom density of a composite oxide can be determined by, for the oxygen atom density of the composite oxide, finding the weighted average by finding the sum of: multiplying the oxygen atom density of the oxide of each cation alone by the composition ratio of each cation to the total cation contained in the composite oxide.

The oxygen atom density MDi of the composite oxide is represented below (Formula A), where, in a composite oxide containing N types of cations Ai (i=1, 2, 3, . . . , N), the oxygen atom density of the oxide containing only the cation Ai as the cation (that is, the oxygen atom density of the oxide of the cation Ai alone) is Di and the ratio of the number density of the cation Ai to the total of the number densities of all cations (that is, the composition ratio of the cation Ai with respect to all cations contained in the composite oxide) is Xi. However, the sum of Xi (i=1, 2, 3, . . . , N) is 1 as shown in Formula B below.

$$\begin{matrix}[ Expression 1 ] & \\ MDi = {\sum }_{i = 1}^{N} Xi \cdot Di & ( Formula A )\end{matrix}$$

$$\begin{matrix}[ Expression 2 ] & \\ {\sum }_{i = 1}^{N} Xi = 1 & ( Formula B )\end{matrix}$$

### Supplement

A light-emitting element according to a first aspect of the present disclosure includes: an anode, a hole transport layer, a light-emitting layer, an electron transport layer, and a cathode in this order; and a first oxide layer and a second oxide layer that is in contact with the first oxide layer disposed in this order from a side closer to the anode between the anode and the hole transport layer or between the electron transport layer and the cathode, wherein a density of oxygen atoms in the second oxide layer is different from a density of oxygen atoms in the first oxide layer.

The light-emitting element according to a second aspect of the present disclosure has the configuration of the first aspect, wherein the density of oxygen atoms in the second oxide layer may be less than the density of oxygen atoms in the first oxide layer.

In other words, a light-emitting element according to a second aspect of the present disclosure includes an anode, a hole transport layer, a light-emitting layer, an electron transport layer, and a cathode in this order; and a first oxide layer and a second oxide layer that is in contact with the first oxide layer disposed in this order from a side closer to the anode between the anode and the hole transport layer or between the electron transport layer and the cathode, wherein a density of oxygen atoms in the second oxide layer may be less than a density of oxygen atoms in the first oxide layer.

The light-emitting element according to a third aspect of the present disclosure has the configuration of the second aspect, wherein the density of oxygen atoms in the second oxide layer may be from 50% to 95% of the density of oxygen atoms in the first oxide layer.

The light-emitting element according to a fourth aspect of the present disclosure has the configuration of the third aspect, wherein the density of oxygen atoms in the second oxide layer may be from 50% to 90% of the density of oxygen atoms in the first oxide layer.

The light-emitting element according to a fifth aspect of the present disclosure has the configuration of the first aspect, wherein the density of oxygen atoms in the first oxide layer may be less than the density of oxygen atoms in the second oxide layer.

In other words, a light-emitting element according to a fifth aspect of the present disclosure includes an anode, a hole transport layer, a light-emitting layer, an electron transport layer, and a cathode in this order; and a first oxide layer and a second oxide layer that is in contact with the first oxide layer disposed in this order from a side closer to the anode between the anode and the hole transport layer or between the electron transport layer and the cathode, wherein a density of oxygen atoms in the first oxide layer may be less than a density of oxygen atoms in the second oxide layer.

The light-emitting element according to a sixth aspect of the present disclosure has the configuration of any one of the first to fifth aspects, wherein an electric dipole may be formed at an interface between the first oxide layer and the second oxide layer.

The light-emitting element according to the seventh aspect of the present disclosure has the configuration of any one of the second to fourth aspects, wherein an electric dipole may be formed at an interface between the first oxide layer and the second oxide layer: and the electric dipole may have a dipole moment including a component orientated from the second oxide layer toward the first oxide layer.

The light-emitting element according to the eighth aspect of the present disclosure has the configuration of the fifth aspect, wherein an electric dipole may be formed at an interface between the first oxide layer and the second oxide layer; and the electric dipole may have a dipole moment including a component orientated from the first oxide layer toward the second oxide layer.

The light-emitting element according to a ninth aspect of the present disclosure has the configuration of any one of the first to eighth aspects, wherein the first oxide layer may be formed of an inorganic oxide.

The light-emitting element according to a tenth aspect of the present disclosure has the configuration of any one of the first to ninth aspects, wherein the second oxide layer may be formed of an inorganic oxide.

The light-emitting element according to an eleventh aspect of the present disclosure has the configuration of any one of the first to tenth aspects, wherein the first oxide layer may be formed of an insulator.

The light-emitting element according to a twelfth aspect of the present disclosure has the configuration of any one of the first to eleventh aspects, wherein the second oxide layer may be formed of an insulator.

The light-emitting element according to a thirteenth aspect of the present disclosure has the configuration of any one of the first to twelfth aspects, wherein the first oxide layer and the second oxide layer may be formed of an amorphous oxide.

The light-emitting element according to a fourteenth aspect of the present disclosure has the configuration of any one of the first to twelfth aspects, wherein at least at a contact surface between the first oxide layer and the second oxide layer, at least one of the first oxide layer or the second oxide layer may include grains.

The light-emitting element according to a fifteenth aspect of the present disclosure has the configuration of any one of the first to twelfth aspects, wherein at least at a contact surface between the first oxide layer and the second oxide layer, at least one of the first oxide layer or the second oxide layer may include a polycrystalline oxide.

A light-emitting element according to a sixteenth aspect of the present disclosure has the configuration of the fourteenth or fifteenth aspect, wherein the anode may be disposed below the cathode, and the first oxide layer and the second oxide layer may be layered in this order from a lower layer side. For example, the light-emitting element according to a sixteenth aspect of the present disclosure has the configuration of the fourteenth or fifteenth aspect and further includes a substrate, wherein the anode may be disposed on the substrate side of the cathode, and the first oxide layer and the second oxide layer may be layered in this order from the substrate side.

The light-emitting element according to a seventeenth aspect of the present disclosure has the configuration of any one of the fourteenth to sixteenth aspects, wherein of the first oxide layer and the second oxide layer, the layer on the upper layer side may be formed of an amorphous oxide.

The light-emitting element according to an eighteenth aspect of the present disclosure has the configuration of any one of the fourteenth to seventeenth aspects, wherein of the first oxide layer and the second oxide layer, the layer on the upper layer side may be formed of a continuous film.

The light-emitting element according to a nineteenth aspect of the present disclosure has the configuration of any one of the fourteenth to seventeenth aspects, wherein of the first oxide layer and the second oxide layer, the layer on the upper layer side may have a porosity of less than 1%.

The light-emitting element according to a twentieth aspect of the present disclosure has the configuration of any one of the first to twelfth aspects, wherein at least a contact surface of the second oxide layer with the first oxide layer may include grains.

The light-emitting element according to a twenty-first aspect of the present disclosure has the configuration of any one of the first to twelfth aspects, wherein at least a contact surface of the second oxide layer with the first oxide layer may include a polycrystalline oxide.

A light-emitting element according to a twenty-second aspect of the present disclosure has the configuration of the twentieth or twenty-first aspect, wherein the cathode may be disposed below the anode, and the second oxide layer and the first oxide layer may be layered in this order from a lower layer side. For example, the light-emitting element according to a twentieth aspect of the present disclosure has the configuration of the eighteenth or nineteenth aspect and further includes a substrate, wherein the cathode may be disposed on the substrate side of the anode, and the second oxide layer and the first oxide layer may be layered in this order from the substrate side.

The light-emitting element according to a twenty-third aspect of the present disclosure has the configuration of the twenty-second aspect, wherein the first oxide layer may be formed of an amorphous oxide.

The light-emitting element according to a twenty-fourth aspect of the present disclosure has the configuration of the twenty-second or twenty-third aspect, wherein the first oxide layer may be formed of a continuous film.

The light-emitting element according to a twenty-fifth aspect of the present disclosure has the configuration of the twenty-second or twenty-third aspect, wherein the first oxide layer may have a porosity of less than 1%.

The light-emitting element according to a twenty-sixth aspect of the present disclosure has the configuration of any one of the first to twenty-fifth aspects, wherein the first oxide layer may be formed of an oxide in which a most abundant element other than oxygen is any one of Al, Ga, Ta, Zr, Hf, Mg, Ge, Si, Y, La, or Sr.

The light-emitting element according to a twenty-seventh aspect of the present disclosure has the configuration of any one of the first to twenty-fifth aspects, wherein the first oxide layer or the second oxide layer may be formed of an oxide in which a most abundant element other than oxygen is any one of Al, Ga, Ta, Zr, Hf, Mg, Ge, Si, Y, La, or Sr.

The light-emitting element according to a twenty-eighth aspect of the present disclosure has the configuration of any one of the first to twenty-fifth aspects, wherein the first oxide layer may include at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide containing two or more types of cations of these oxides.

The light-emitting element according to a twenty-ninth aspect of the present disclosure has the configuration of any one of the first to twenty-fifth aspects, wherein the first oxide layer may include any one of one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide containing two or more types of cations of these oxides.

The light-emitting element according to a thirtieth aspect of the present disclosure has the configuration of any one of the first to twenty-ninth aspects, wherein the first oxide layer may be formed of an oxide in which a most abundant element other than oxygen is any one of Al, Ga, Ta, Zr, Hf, Mg, Ge, Si, Y, La, or Sr.

The light-emitting element according to a thirty-first aspect of the present disclosure has the configuration of any one of the first to twenty-ninth aspects, wherein the second oxide layer may be formed of an oxide in which a most abundant element other than oxygen is any one of Al, Ga, Ta, Zr, Hf, Mg, Ge, Si, Y, La, or Sr.

The light-emitting element according to a thirty-second aspect of the present disclosure has the configuration of any one of the first to twenty-ninth aspects, wherein the second oxide layer may include at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide containing two or more types of cations of these oxides.

The light-emitting element according to a thirty-third aspect of the present disclosure has the configuration of any one of the first to twenty-ninth aspects, wherein the second oxide layer may include any one of one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide containing two or more types of cations of these oxides.

The light-emitting element according to a thirty-fourth aspect of the present disclosure has the configuration of any one of the first to thirty-third aspects, wherein the first oxide layer and the second oxide layer may include a common cation.

The light-emitting element according to a thirty-fifth aspect of the present disclosure has the configuration of any one of the first to thirty-fourth aspects, wherein a film thickness of the first oxide layer may be from 0.2 nm to 5 nm.

The light-emitting element according to a thirty-sixth aspect of the present disclosure has the configuration of the thirty-fifth aspect, wherein a film thickness of the first oxide layer may be from 0.8 nm to less than 3 nm.

The light-emitting element according to a thirty-seventh aspect of the present disclosure has the configuration of any one of the first to thirty-sixth aspects, wherein a film thickness of the second oxide layer may be from 0.2 nm to 5 nm.

The light-emitting element according to a thirty-eighth aspect of the present disclosure has the configuration of the thirty-seventh aspect, wherein a film thickness of the second oxide layer may be from 0.8 nm to less than 3 nm.

The light-emitting element according to a thirty-ninth aspect of the present disclosure has the configuration of any one of the first to thirty-eighth aspects, wherein a total film thickness of the first oxide layer and the second oxide layer may be from 0.4 nm to 5 nm.

The light-emitting element according to a fortieth aspect of the present disclosure has the configuration of the thirty-ninth aspect, wherein a total film thickness of the first oxide layer and the second oxide layer may be from 1.6 nm to less than 4 nm.

The light-emitting element according a forty-first aspect of the present disclosure has the configuration of any one of the first to fortieth aspects, wherein the first oxide layer and the second oxide layer are disposed between the anode and the hole transport layer in this order from the anode side.

The light-emitting element according to a forty-second aspect of the present disclosure has the configuration of the forty-first aspect, wherein a hole density in the first oxide layer and a hole density in the second oxide layer may be less than a hole density in the hole transport layer.

The light-emitting element according to a forty-third aspect of the present disclosure has the configuration of the forty-first or forty-second aspect, wherein a work function of the anode may be less than an ionization potential of the hole transport layer, and the ionization potential of the hole transport layer may be less than an ionization potential of the first oxide layer and the second oxide layer.

The light-emitting element according to a forty-fourth aspect of the present disclosure has the configuration of the forty-third aspect, wherein an ionization potential of the first oxide layer and an ionization potential of the second oxide layer may be equal.

The light-emitting element according to a forty-fifth aspect of the present disclosure has the configuration of the forty-third aspect, wherein the hole transport layer, the second oxide layer, and the first oxide layer may be smaller in terms of ionization potential in this order.

The light-emitting element according to a forty-sixth aspect of the present disclosure has the configuration of the forty-third aspect, wherein the hole transport layer, the first oxide layer, and the second oxide layer may be smaller in terms of ionization potential in this order.

The light-emitting element according to a forty-seventh aspect of the present disclosure has the configuration of any one of the forty-first to forty-sixth aspects, wherein the hole transport layer may be formed of an oxide.

The light-emitting element according to a forty-eighth aspect of the present disclosure has the configuration of the forty-seventh aspect, wherein the hole transport layer is in contact with the second oxide layer, and at least at a contact surface between the hole transport layer and the second oxide layer, at least one of the hole transport layer or the second oxide layer may include grains.

The light-emitting element according to a forty-ninth aspect of the present disclosure has the configuration of the forty-seventh aspect, wherein the hole transport layer is in contact with the second oxide layer, and at least a contact surface of the hole transport layer with the second oxide layer may include grains.

The light-emitting element according to a fiftieth aspect of the present disclosure has the configuration of the forty-seventh aspect, wherein the hole transport layer is in contact with the second oxide layer, and at least a contact surface of the second oxide layer with the hole transport layer may include grains.

The light-emitting element according to a fifty-first aspect of the present disclosure has the configuration of the forty-seventh aspect, wherein the hole transport layer is in contact with the second oxide layer, and at least at a contact surface between the hole transport layer and the second oxide layer, at least one of the hole transport layer or the second oxide layer may include a polycrystalline oxide.

The light-emitting element according to a fifty-second aspect of the present disclosure has the configuration of the forty-seventh aspect, wherein the hole transport layer is in contact with the second oxide layer, and at least a contact surface of the hole transport layer with the second oxide layer may include a polycrystalline oxide.

The light-emitting element according to a fifty-third aspect of the present disclosure has the configuration of the forty-seventh aspect, wherein the hole transport layer is in contact with the second oxide layer, and at least a contact surface of the second oxide layer with the hole transport layer may include a polycrystalline oxide.

The light-emitting element according to a fifty-fourth aspect of the present disclosure has the configuration of any one of the forty-seventh to fifty-third aspects, wherein the hole transport layer is in contact with the second oxide layer, and the density of oxygen atoms in the hole transport layer may be less than the density of oxygen atoms in the second oxide layer.

The light-emitting element according to a fifty-fifth aspect of the present disclosure has the configuration of the fifty-fourth aspect, wherein the density of oxygen atoms in the hole transport layer may be from 50% to 95% of the density of oxygen atoms in the second oxide layer.

The light-emitting element according to a fifty-sixth aspect of the present disclosure has the configuration of the fifty-fifth aspect, wherein the density of oxygen atoms in the hole transport layer may be from 50% to 90% of the density of oxygen atoms in the second oxide layer.

The light-emitting element according to a fifty-seventh aspect of the present disclosure has the configuration of any one of the forty-seventh to fifty-third aspects, wherein the hole transport layer is in contact with the second oxide layer, and the density of oxygen atoms in the hole transport layer may be greater than the density of oxygen atoms in the second oxide layer.

The light-emitting element according a fifty-eighth aspect of the present disclosure has the configuration of any one of the first to fortieth aspects, wherein the first oxide layer and the second oxide layer are disposed between the electron transport layer and the cathode in this order from the anode side.

The light-emitting element according to a fifty-ninth aspect of the present disclosure has the configuration of the fifty-seventh aspect, wherein an electron density of the first oxide layer and an electron density of the second oxide layer may be less than an electron density of the electron transport layer.

The light-emitting element according to a sixtieth aspect of the present disclosure has the configuration of the fifty-eighth or fifty-ninth aspects, wherein a work function of the cathode may be greater than an electron affinity of the electron transport layer, and the electron affinity of the electron transport layer may be greater than an electron affinity of the first oxide layer and the second oxide layer.

The light-emitting element according to a sixty-first aspect of the present disclosure has the configuration of the sixtieth aspect, wherein an electron affinity of the first oxide layer and an electron affinity of the second oxide layer may be equal.

The light-emitting element according to a sixty-second aspect of the present disclosure has the configuration of the sixtieth aspect, wherein the electron transport layer, the light-emitting layer, the second oxide layer, and the first oxide layer may be greater in terms of electron affinity in this order.

The light-emitting element according to a sixty-third aspect of the present disclosure has the configuration of the sixtieth aspect, wherein the electron transport layer, the light-emitting layer, the first oxide layer, and the second oxide layer may be greater in terms of electron affinity in this order.

The light-emitting element according to a sixty-fourth aspect of the present disclosure has the configuration of any one of the fifty-eighth to sixty-third aspects, wherein the electron transport layer may be formed of an oxide.

The light-emitting element according to a sixty-fifth aspect of the present disclosure has the configuration of the sixty-fourth aspect, wherein the electron transport layer is in contact with the first oxide layer, and at least at a contact surface between the electron transport layer and the first oxide layer, at least one of the electron transport layer or the first oxide layer may include grains.

The light-emitting element according to a sixty-sixth aspect of the present disclosure has the configuration of the sixty-fourth aspect, wherein the electron transport layer is in contact with the first oxide layer, and at least at a contact surface between the electron transport layer and the first oxide layer, at least one of the electron transport layer or the first oxide layer may include a polycrystalline oxide.

The light-emitting element according to a sixty-seventh aspect of the present disclosure has the configuration of the sixty-fourth aspect, wherein the electron transport layer is in contact with the first oxide layer, and at least a contact surface of the first oxide layer with the electron transport layer may include grains.

The light-emitting element according to a sixty-eighth aspect of the present disclosure has the configuration of the sixty-fourth aspect, wherein the electron transport layer is in contact with the first oxide layer, and at least a contact surface of the first oxide layer with the electron transport layer may include a polycrystalline oxide.

The light-emitting element according to a sixty-ninth aspect of the present disclosure has the configuration of any one of the sixty-fourth to sixty-eighth aspects, wherein the electron transport layer is in contact with the first oxide layer, and the density of oxygen atoms in the first oxide layer may be less than the density of oxygen atoms in the electron transport layer.

The light-emitting element according to a seventieth aspect of the present disclosure has the configuration of the sixty-ninth aspect, wherein the density of oxygen atoms in the first oxide layer may be from 50% to 95% of the density of oxygen atoms in the electron transport layer.

The light-emitting element according to a seventy-first aspect of the present disclosure has the configuration of the seventieth aspect, wherein the density of oxygen atoms in the first oxide layer may be from 50% to 90% of the density of oxygen atoms in the electron transport layer.

The light-emitting element according to a seventy-second aspect of the present disclosure has the configuration of any one of the sixty-fourth to sixty-eighth aspects, wherein the electron transport layer is in contact with the first oxide layer, the electron transport layer is formed of an oxide, and the density of oxygen atoms in the first oxide layer may be greater than the density of oxygen atoms in the electron transport layer.

The light-emitting element according to a seventy-third aspect of the present disclosure has the configuration of any one of the first to seventy-second aspects and may further include a third oxide layer and a fourth oxide layer that is in contact with the third oxide layer disposed in this order from a side closer to the anode not between the anode and the hole transport layer and not between the electron transport layer and the cathode, wherein a density of oxygen atoms in the third oxide layer may be different from a density of oxygen atoms in the fourth oxide layer.

The light-emitting element according to a seventy-fourth aspect of the present disclosure has the configuration of the seventy-third aspect and may further include a fifth oxide layer and a sixth oxide layer that is in contact with the fifth oxide layer disposed in this order from a side closer to the anode between the hole transport layer and the light-emitting layer or between the light-emitting layer and the electron transport layer, wherein a density of oxygen atoms in the sixth oxide layer may be different from a density of oxygen atoms in the fifth oxide layer.

The light-emitting element according to a seventy-fifth aspect of the present disclosure has the configuration of the seventy-fourth aspect and may further include a seventh oxide layer and an eighth oxide layer that is in contact with the seventh oxide layer disposed in this order from a side closer to the anode not between the hole transport layer and the light-emitting layer and not between the light-emitting layer and the electron transport layer, wherein a density of oxygen atoms in the eighth oxide layer may be different from a density of oxygen atoms in the seventh oxide layer.

The light-emitting element according to a seventy-sixth aspect of the present disclosure has the configuration of any one of the first to seventy-second aspects and may further include a third oxide layer and a fourth oxide layer that is in contact with the third oxide layer disposed in this order from a side closer to the anode not between the anode and the hole transport layer and not between the electron transport layer and the cathode, wherein a density of oxygen atoms in the fourth oxide layer may be less than a density of oxygen atoms in the third oxide layer.

The light-emitting element according to a seventy-seventh aspect of the present disclosure has the configuration of any one of the first to seventy-second aspects and may further include a third oxide layer and a fourth oxide layer that is in contact with the third oxide layer disposed in this order from a side closer to the anode not between the anode and the hole transport layer and not between the electron transport layer and the cathode, wherein a density of oxygen atoms in the third oxide layer is less than a density of oxygen atoms in the fourth oxide layer.

The light-emitting element according to a seventy-eighth aspect of the present disclosure has the configuration of the seventy-sixth or seventy-seventh aspect and may further include a fifth oxide layer and a sixth oxide layer that is in contact with the fifth oxide layer disposed in this order from a side closer to the anode between the hole transport layer and the light-emitting layer or between the light-emitting layer and the electron transport layer, wherein a density of oxygen atoms in the sixth oxide layer may be less than a density of oxygen atoms in the fifth oxide layer.

The light-emitting element according a seventy-ninth aspect of the present disclosure has the configuration of the seventy-seventh aspect, wherein the fifth oxide layer and the sixth oxide layer may be disposed between the hole transport layer and the light-emitting layer in this order from the anode side, and the density of the oxygen atoms in the sixth oxide layer may be less than the density of the oxygen atoms in the fifth oxide layer.

The light-emitting element according an eightieth aspect of the present disclosure has the configuration of the seventy-eighth aspect, wherein the fifth oxide layer and the sixth oxide layer may be disposed between the light-emitting layer and the electron transport layer in this order from the anode side, and the density of the oxygen atoms in the sixth oxide layer may be less than the density of the oxygen atoms in the fifth oxide layer.

The light-emitting element according to an eighty-first aspect of the present disclosure has the configuration of the seventy-eighth aspect and may further include a seventh oxide layer and an eighth oxide layer that is in contact with the seventh oxide layer disposed in this order from a side closer to the anode not between the hole transport layer and the light-emitting layer and not between the light-emitting layer and the electron transport layer, wherein the density of oxygen atoms in the eighth oxide layer may be less than the density of oxygen atoms in the seventh oxide layer.

Note that this may be paraphrased as the light-emitting element according to an eighty-first aspect of the present disclosure has the configuration of the seventy-ninth aspect and may further include a seventh oxide layer and an eighth oxide layer that is in contact with the seventh oxide layer disposed in this order from a side closer to the anode between the light-emitting layer and the electron transport layer, wherein the density of oxygen atoms in the eighth oxide layer may be less than the density of oxygen atoms in the seventh oxide layer. Also, this may be paraphrased as the light-emitting element according to a seventy-ninth aspect of the present disclosure has the configuration of the seventy-eighth aspect and may further include a seventh oxide layer and an eighth oxide layer that is in contact with the seventh oxide layer disposed in this order from a side closer to the anode between the hole transport layer and the light-emitting layer, wherein the density of oxygen atoms in the eighth oxide layer may be less than the density of oxygen atoms in the seventh oxide layer.

The light-emitting element according to an eighty-second aspect of the present disclosure has the configuration of the seventy-sixth or seventy-seventh aspect and may further include a fifth oxide layer and a sixth oxide layer that is in contact with the fifth oxide layer disposed in this order from a side closer to the anode between the hole transport layer and the light-emitting layer or between the light-emitting layer and the electron transport layer, wherein the density of oxygen atoms in the fifth oxide layer may be less than the density of oxygen atoms in the sixth oxide layer.

The light-emitting element according an eighty-third aspect of the present disclosure has the configuration of the eighty-second aspect, wherein the fifth oxide layer and the sixth oxide layer may be disposed between the hole transport layer and the light-emitting layer in this order from the anode side, and the density of the oxygen atoms in the fifth oxide layer may be less than the density of the oxygen atoms in the sixth oxide layer.

The light-emitting element according an eighty-fourth aspect of the present disclosure has the configuration of the eighty-second aspect, wherein the fifth oxide layer and the sixth oxide layer may be disposed between the light-emitting layer and the electron transport layer in this order from the anode side, and the density of the oxygen atoms in the fifth oxide layer may be less than the density of the oxygen atoms in the sixth oxide layer.

The light-emitting element according to an eighty-fifth aspect of the present disclosure has the configuration of the eighty-second aspect and may further include a seventh oxide layer and an eighth oxide layer that is in contact with the seventh oxide layer disposed in this order from a side closer to the anode not between the hole transport layer and the light-emitting layer and not between the light-emitting layer and the electron transport layer, wherein the density of oxygen atoms in the seventh oxide layer may be less than the density of oxygen atoms in the eighth oxide layer.

Note that this may be paraphrased as the light-emitting element according to an eighty-fifth aspect of the present disclosure has the configuration of the eighty-third aspect and may further include a seventh oxide layer and an eighth oxide layer that is in contact with the seventh oxide layer disposed in this order from a side closer to the anode between the light-emitting layer and the electron transport layer, wherein the density of oxygen atoms in the seventh oxide layer may be less than the density of oxygen atoms in the eighth oxide layer. Also, this may be paraphrased as the light-emitting element according to an eighty-third aspect of the present disclosure has the configuration of the eighty-second aspect and may further include a seventh oxide layer and an eighth oxide layer that is in contact with the seventh oxide layer disposed in this order from a side closer to the anode between the hole transport layer and the light-emitting layer, wherein the density of oxygen atoms in the seventh oxide layer may be less than the density of oxygen atoms in the eighth oxide layer.

The light-emitting element according to an eighty-sixth aspect of the present disclosure has the configuration of any one of the first to seventy-second aspects and may further include a third oxide layer and a fourth oxide layer that is in contact with the third oxide layer disposed in this order from a side closer to the anode between the hole transport layer and the light-emitting layer or between the light-emitting layer and the electron transport layer, wherein the density of oxygen atoms in the fourth oxide layer may be different from the density of oxygen atoms in the third oxide layer.

The light-emitting element according to an eighty-seventh aspect of the present disclosure has the configuration of any one of the first to seventy-second aspects and may further include a third oxide layer and a fourth oxide layer that is in contact with the third oxide layer disposed in this order from a side closer to the anode between the hole transport layer and the light-emitting layer or between the light-emitting layer and the electron transport layer, wherein the density of oxygen atoms in the fourth oxide layer may be less than the density of oxygen atoms in the third oxide layer.

The light-emitting element according to an eighty-eighth aspect of the present disclosure has the configuration of any one of the first to seventy-second aspects and may further include a third oxide layer and a fourth oxide layer that is in contact with the third oxide layer disposed in this order from a side closer to the anode between the hole transport layer and the light-emitting layer or between the light-emitting layer and the electron transport layer, wherein the density of oxygen atoms in the third oxide layer may be less than the density of oxygen atoms in the fourth oxide layer.

The light-emitting element according to an eighty-ninth aspect of the present disclosure has the configuration of any one of the forty-first to fifty-seventh aspects and may further include a third oxide layer and a fourth oxide layer that is in contact with the third oxide layer disposed in this order from a side closer to the anode between the hole transport layer and the light-emitting layer, wherein the density of oxygen atoms in the fourth oxide layer may be less than the density of oxygen atoms in the third oxide layer.

The light-emitting element according to a ninetieth aspect of the present disclosure has the configuration of any one of the forty-first to fifty-seventh aspects and may further include a third oxide layer and a fourth oxide layer that is in contact with the third oxide layer disposed in this order from a side closer to the anode between the hole transport layer and the light-emitting layer, wherein the density of oxygen atoms in the third oxide layer may be less than the density of oxygen atoms in the fourth oxide layer.

The light-emitting element according to a ninety-first aspect of the present disclosure has the configuration of any one of the fifty-eighth to seventy-second aspects and may further include a third oxide layer and a fourth oxide layer that is in contact with the third oxide layer disposed in this order from a side closer to the anode between the light-emitting layer and the electron transport layer, wherein the density of oxygen atoms in the fourth oxide layer may be less than the density of oxygen atoms in the third oxide layer.

The light-emitting element according to a ninety-second aspect of the present disclosure has the configuration of any one of the fifty-eighth to seventy-second aspects and may further include a third oxide layer and a fourth oxide layer that is in contact with the third oxide layer disposed in this order from a side closer to the anode between the light-emitting layer and the electron transport layer, wherein the density of oxygen atoms in the third oxide layer may be less than the density of oxygen atoms in the fourth oxide layer.

The light-emitting element according to a ninety-third aspect of the present disclosure has the configuration of any one of the forty-first to fifty-seventh aspects and may further include a third oxide layer and a fourth oxide layer that is in contact with the third oxide layer disposed in this order from a side closer to the anode between the light-emitting layer and the electron transport layer, wherein the density of oxygen atoms in the fourth oxide layer may be less than the density of oxygen atoms in the third oxide layer.

The light-emitting element according to a ninety-fourth aspect of the present disclosure has the configuration of any one of the forty-first to fifty-seventh aspects and may further include a third oxide layer and a fourth oxide layer that is in contact with the third oxide layer disposed in this order from a side closer to the anode between the light-emitting layer and the electron transport layer, wherein the density of oxygen atoms in the third oxide layer may be less than the density of oxygen atoms in the fourth oxide layer.

The light-emitting element according to a ninety-fifth aspect of the present disclosure has the configuration of any one of the fifty-eighth to seventy-second aspects and may further include a third oxide layer and a fourth oxide layer that is in contact with the third oxide layer disposed in this order from a side closer to the anode between the hole transport layer and the light-emitting layer, wherein the density of oxygen atoms in the fourth oxide layer may be less than the density of oxygen atoms in the third oxide layer.

The light-emitting element according to a ninety-sixth aspect of the present disclosure has the configuration of any one of the fifty-eighth to seventy-second aspects and may further include a third oxide layer and a fourth oxide layer that is in contact with the third oxide layer disposed in this order from a side closer to the anode between the hole transport layer and the light-emitting layer, wherein the density of oxygen atoms in the third oxide layer may be less than the density of oxygen atoms in the fourth oxide layer.

The light-emitting element according to a ninety-seventh aspect of the present disclosure has the configuration of any one of the first to seventy-second aspects and may further include a third oxide layer and a fourth oxide layer that is in contact with the third oxide layer disposed in this order from a side closer to the anode between the hole transport layer and the light-emitting layer and a fifth oxide layer and a sixth oxide layer that is in contact with the fifth oxide layer disposed in this order from a side closer to the anode between the light-emitting layer and the electron transport layer, wherein the density of oxygen atoms in the third oxide layer may be different from the density of oxygen atoms in the fourth oxide layer, and the density of the oxygen atoms in the fifth oxide layer may be different from the density of the oxygen atoms in the sixth oxide layer.

The light-emitting element according to a ninety-eighth aspect of the present disclosure has the configuration of any one of the first to seventy-second aspects and may further include a third oxide layer and a fourth oxide layer that is in contact with the third oxide layer disposed in this order from a side closer to the anode between the hole transport layer and the light-emitting layer and a fifth oxide layer and a sixth oxide layer that is in contact with the fifth oxide layer disposed in this order from a side closer to the anode between the light-emitting layer and the electron transport layer, wherein the density of oxygen atoms in the third oxide layer may be less than the density of oxygen atoms in the fourth oxide layer, and the density of the oxygen atoms in the fifth oxide layer may be less than the density of the oxygen atoms in the sixth oxide layer.

The light-emitting element according to a ninety-ninth aspect of the present disclosure has the configuration of any one of the first to seventy-second aspects and may further include a third oxide layer and a fourth oxide layer that is in contact with the third oxide layer disposed in this order from a side closer to the anode between the hole transport layer and the light-emitting layer and a fifth oxide layer and a sixth oxide layer that is in contact with the fifth oxide layer disposed in this order from a side closer to the anode between the light-emitting layer and the electron transport layer, wherein the density of oxygen atoms in the fourth oxide layer may be less than the density of oxygen atoms in the third oxide layer, and the density of the oxygen atoms in the sixth oxide layer may be less than the density of the oxygen atoms in the fifth oxide layer.

The light-emitting element according to a ninety-ninth aspect of the present disclosure has the configuration of any one of the first to seventy-second aspects and may further include a third oxide layer and a fourth oxide layer that is in contact with the third oxide layer disposed in this order from a side closer to the anode between the hole transport layer and the light-emitting layer and a fifth oxide layer and a sixth oxide layer that is in contact with the fifth oxide layer disposed in this order from a side closer to the anode between the light-emitting layer and the electron transport layer, wherein the density of oxygen atoms in the fourth oxide layer may be less than the density of oxygen atoms in the third oxide layer, and the density of the oxygen atoms in the fifth oxide layer may be less than the density of the oxygen atoms in the sixth oxide layer.

The light-emitting element according to a one hundredth aspect of the present disclosure has the configuration of any one of the first to seventy-second aspects and may further include a third oxide layer and a fourth oxide layer that is in contact with the third oxide layer disposed in this order from a side closer to the anode between the hole transport layer and the light-emitting layer and a fifth oxide layer and a sixth oxide layer that is in contact with the fifth oxide layer disposed in this order from a side closer to the anode between the light-emitting layer and the electron transport layer, wherein the density of oxygen atoms in the third oxide layer may be less than the density of oxygen atoms in the fourth oxide layer, and the density of the oxygen atoms in the sixth oxide layer may be less than the density of the oxygen atoms in the fifth oxide layer.

The light-emitting element according to a one hundred and first aspect of the present disclosure has the configuration of the eighty-ninth or ninetieth aspect and may further include a fifth oxide layer and a sixth oxide layer that is in contact with the fifth oxide layer disposed in this order from a side closer to the anode between the light-emitting layer and the electron transport layer, wherein the density of oxygen atoms in the sixth oxide layer may be less than the density of oxygen atoms in the fifth oxide layer.

The light-emitting element according to a one hundred and second aspect of the present disclosure has the configuration of the eighty-ninth or ninetieth aspect and may further include a fifth oxide layer and a sixth oxide layer that is in contact with the fifth oxide layer disposed in this order from a side closer to the anode between the light-emitting layer and the electron transport layer, wherein the density of oxygen atoms in the fifth oxide layer may be less than the density of oxygen atoms in the sixth oxide layer.

The light-emitting element according to a one hundred and third aspect of the present disclosure has the configuration of the ninety-first or ninety-second aspect and may further include a fifth oxide layer and a sixth oxide layer that is in contact with the fifth oxide layer disposed in this order from a side closer to the anode between the hole transport layer and the light-emitting layer, wherein the density of oxygen atoms in the sixth oxide layer may be less than the density of oxygen atoms in the fifth oxide layer.

The light-emitting element according to a one hundred and fourth aspect of the present disclosure has the configuration of the ninety-first or ninety-second aspect and may further include a fifth oxide layer and a sixth oxide layer that is in contact with the fifth oxide layer disposed in this order from a side closer to the anode between the hole transport layer and the light-emitting layer, wherein the density of oxygen atoms in the fifth oxide layer may be less than the density of oxygen atoms in the sixth oxide layer.

Note that, as described above, in the present disclosure, the first oxide layer and the second oxide layer can, in order, be read as the third oxide layer the fourth oxide layer, the fifth oxide layer and the sixth oxide layer, or the seventh oxide layer and the eighth oxide layer. Accordingly, the third oxide layer and the fourth oxide layer, the fifth oxide layer and the sixth oxide layer, or the seventh oxide layer and the eighth oxide layer may each have the same configuration as the first oxide layer and the second oxide layer.

The light-emitting element according to a one hundred and fifth aspect of the present disclosure has the configuration of any one of the first to one hundred and forth aspects, wherein the light-emitting layer may include a quantum dot phosphor.

The light-emitting device according to a one hundred and sixth aspect of the present disclosure includes the light-emitting element according to any one of the first to one hundred and fifth aspects.

The light-emitting device according to a one hundred and seventh aspect of the present disclosure has the configuration of the one hundred and sixth aspect, wherein the light-emitting element may be provided on a substrate.

The light-emitting device according to a one hundred and eighth aspect of the present disclosure has the configuration of the one hundred and sixth or the one hundred and seventh aspect and may be a display device.

The light-emitting device according to a one hundred and ninth aspect of the present disclosure has the configuration of the one hundred and sixth or the one hundred and seventh aspect and may be an illumination device.

Note that the combinations of aspects described above are examples of the present disclosure, and the present disclosure is not limited to the combinations described above. Also, the present disclosure is not limited to the embodiments described above, and various modifications may be made within the scope of the claims and the summary described above. Embodiments obtained by appropriately combining technical approaches disclosed in the different embodiments also fall within the technical scope of the present disclosure. Furthermore, novel technical features can be formed by combining the technical approaches disclosed in each of the embodiments.

### REFERENCE SIGNS LIST

1, 1′, 31, 41, 51, 61, 71 81 Electric dipole
2 Display device (light-emitting device)
5, 5R, 5G, 5B, 55, 155, 255, 155, 255, 555, 655, 755, 855 Light-emitting element
22 First electrode (anode)
24a, 24b 124a, 124b, 244a, 244b, 324a, 324b Oxide layer
24c Hole transport layer
24d, 24Rd, 24Gd, 24Bd Light-emitting layer
24e Electron transport layer
25 Second electrode (cathode)
IP1 to IP6 Ionization potential
EA1 to EA6 Electron affinity
Ed1 Energy difference between vacuum level and Fermi level of first electrode (work function of first electrode)
Ed2 Energy difference between vacuum level and Fermi level of second electrode (work function of second electrode)

1. A light-emitting element, comprising:
an anode, a hole transport layer, a light-emitting layer, an electron transport layer, and a cathode in this order; and
a first oxide layer and a second oxide layer that is in contact with the first oxide layer disposed in this order from a side closer to the anode between the anode and the hole transport layer or between the electron transport layer and the cathode,
wherein a density of oxygen atoms in the second oxide layer is different from a density of oxygen atoms in the first oxide layer.

2. The light-emitting element according to claim 1,
wherein the density of oxygen atoms in the second oxide layer is less than the density of oxygen atoms in the first oxide layer.

3-10. (canceled)

11. The light-emitting element according to claim 2,
wherein at least one of the first oxide layer or the second oxide layer includes a polycrystalline oxide at a contact surface between the first oxide layer and the second oxide layer.

12-13. (canceled)

14. The light-emitting element according to claim 2,
wherein the first oxide layer or the second oxide layer is formed of an oxide in which a most abundant element other than oxygen is any one of Al, Ga, Ta, Zr, Hf, Mg, Ge, Si, Y, La, or Sr.

15-19. (canceled)

20. The light-emitting element according to claim 1,
wherein a total film thickness of the first oxide layer and the second oxide layer is from 0.4 nm to 5 nm.

21. (canceled)

22. The light-emitting element according to claim 12,
wherein the first oxide layer and the second oxide layer are disposed between the anode and the hole transport layer in this order from the anode side.

23-28. (canceled)

29. The light-emitting element according to claim 22,
wherein the hole transport layer is formed of an oxide, and
the hole transport layer is in contact with the second oxide layer, and at least at a contact surface between the hole transport layer and the second oxide layer, at least one of the hole transport layer or the second oxide layer includes a polycrystalline oxide.

30. The light-emitting element according to claim 22,
wherein the hole transport layer is formed of an oxide, and
the hole transport layer is in contact with the second oxide layer, and a density of oxygen atoms in the hole transport layer is less than the density of oxygen atoms in the second oxide layer.

31. The light-emitting element according to claim 30,
wherein the density of oxygen atoms in the hole transport layer is from 50% to 95% of the density of oxygen atoms in the second oxide layer.

32. (canceled)

33. The light-emitting element according to claim 22,
wherein the hole transport layer is formed of an oxide, and
the hole transport layer is in contact with the second oxide layer, and a density of oxygen atoms in the hole transport layer is greater than the density of oxygen atoms in the second oxide layer.

34. The light-emitting element according to claim 12,
wherein the first oxide layer and the second oxide layer are disposed between the electron transport layer and the cathode in this order from the anode side.

35-40. (canceled)

41. The light-emitting element according to claim 34,
wherein the electron transport layer is formed of an oxide, and
the electron transport layer is in contact with the first oxide layer, and at least at a contact surface between the electron transport layer and the first oxide layer, at least one of the electron transport layer or the first oxide layer includes a polycrystalline oxide.

42. The light-emitting element according to claim 34,
wherein the electron transport layer is formed of an oxide, and
wherein the electron transport layer is in contact with the first oxide layer, and a density of oxygen atoms in the first oxide layer is less than a density of oxygen atoms in the electron transport layer.

43. The light-emitting element according to claim 42,
wherein the density of oxygen atoms in the first oxide layer is from 50% to 95% of the density of oxygen atoms in the electron transport layer.

44. (canceled)

45. The light-emitting element according to claim 34,
wherein the electron transport layer is in contact with the first oxide layer, the electron transport layer is formed of an oxide, and the density of oxygen atoms in the first oxide layer is greater than the density of oxygen atoms in the electron transport layer.

46. The light-emitting element according to claim 12,
wherein the density of oxygen atoms in the second oxide layer is from 50% to 95% of the density of oxygen atoms in the first oxide layer.

47. (canceled)

48. The light-emitting element according to claim 12, further comprising:
a third oxide layer and a fourth oxide layer that is in contact with the third oxide layer disposed in this order from a side closer to the anode not between the anode and the hole transport layer and not between the electron transport layer and the cathode,
wherein a density of oxygen atoms in the fourth oxide layer is different from a density of oxygen atoms in the third oxide layer.

49. The light-emitting element according to claim 12, further comprising:
a third oxide layer and a fourth oxide layer that is in contact with the third oxide layer disposed in this order from a side closer to the anode between the hole transport layer and the light-emitting layer or between the light-emitting layer and the electron transport layer,
wherein a density of oxygen atoms in the fourth oxide layer is different from a density of oxygen atoms in the third oxide layer.

50. The light-emitting element according to claim 1,
wherein the density of oxygen atoms in the first oxide layer is less than the density of oxygen atoms in the second oxide layer.

51. (canceled)

52. A light-emitting device, comprising:
the light-emitting element according to claim 1.
